(19) United States
(12) Patent Application Publication
(10) Pub. No.: US 2009/0117692 A1
(43) Pub. Date: May 7, 2009

(54) MANUFACTURING METHOD OF SEMICONDUCTOR DEVICE

(75) Inventors: Masaki Koyama, Atsugi (JP); Fumito Isaka, Zama (JP); Akihisa Shimomura, Isehara (JP); Junpei Momo, Sagamihara (JP); Shunpei Yamazaki, Tokyo (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 12/261,832

(22) Filed: Oct. 30, 2008

(30) Foreign Application Priority Data
Nov. 1, 2007 (JP) 2007-285589

(51) Int. Cl. H01L 21/336

(52) U.S. Cl. 438/164; 257/E21.415

(57) ABSTRACT

A single crystal semiconductor substrate bonded over a supporting substrate with a buffer layer interposed therebetween and having a separation layer is heated to separate the single crystal semiconductor substrate using the separation layer or a region near the separation layer as a separation plane, thereby forming a single crystal semiconductor layer over the supporting substrate. The single crystal semiconductor layer is irradiated with a laser beam to re-single-crystallize the single crystal semiconductor layer through melting. An impurity element is selectively added into the single crystal semiconductor layer to form a pair of impurity regions and a channel formation region between the pair of impurity regions. The single crystal semiconductor layer is heated at temperature which is equal to or higher than 400° C. and equal to or lower than a strain point of the supporting substrate and which does not cause melting of the single crystal semiconductor layer.

### BACKGROUND OF THE INVENTION

1. Field of the Invention

The present invention relates to a semiconductor device which is manufactured using a semiconductor substrate including a single crystal semiconductor layer formed over an insulating surface, and a manufacturing method thereof.

Note that a semiconductor device in this specification refers to all types of devices which can function by utilizing semiconductor characteristics, and electro-optic devices (including EL display devices and liquid crystal display devices), semiconductor circuits, and electronic devices are all included in the category of the semiconductor device.

2. Description of the Related Art

With development of VLSI technology, lower power consumption and higher speed operation over the scaling law which can be realized by bulk single crystal silicon have been demanded. In order to improve such characteristics, an SOI (silicon on insulator) structure has been attracting attention these days. In this technology, an active region (channel formation region) of a field-effect transistor (FET), which is conventionally formed with bulk single crystal silicon, is formed with a single crystal silicon thin film. It is known that a field-effect transistor manufactured using an SOI structure has lower parasitic capacitance than a field effect transistor manufactured using a bulk single crystal silicon substrate, which is advantageous in increasing operation speed and reducing power consumption.

As an SOI substrate, a SIMOX substrate or a bonded substrate is known. For example, an SOI structure of a SIMOX substrate is formed in the following manner: oxygen ions are implanted into a single crystal silicon substrate and heat treatment at 1300° C. or higher is performed to form a buried oxide (BOX) layer, so that a single crystal silicon thin film is formed on the surface of the buried oxide layer.

An SOI structure of a bonded substrate is formed in the following manner: two single crystal silicon substrates (a base substrate and a bond substrate) are bonded to each other with an oxide film interposed therebetween and one of the two single crystal silicon substrates (the bond substrate) is thinned from its rear side (the surface which is opposite to a surface used for bonding), so that a single crystal silicon thin film is formed. Meanwhile, there is proposed a technique called Smart Cut (registered trademark) which employs hydrogen ion implantation (e.g., Reference 1: Japanese Published Patent Application No. H5-211128), because it is difficult to form a uniform and thin single crystal silicon thin film by grinding or polishing.

A manufacturing method of an SOI substrate using Smart cut (registered trademark) will be described briefly. Hydrogen ions are implanted into a silicon wafer to form an ion-implanted layer at a predetermined depth from the surface. Then, another silicon wafer which serves as a base substrate is oxidized to form a silicon oxide layer. After that, the silicon wafer into which the hydrogen ions are implanted is bonded to the silicon oxide layer of the other silicon wafer which serves as the base substrate, so that the two silicon wafers are bonded. By heat treatment, the silicon wafer into which hydrogen ions are implanted is cleaved at the ion-implanted layer as a cleavage plane, and thus a substrate in which a thin single crystal silicon layer is attached to the base substrate is formed.

In addition, there is a known method of forming an SOI substrate in which a single crystal silicon layer is attached to a glass substrate (e.g., Reference 2: Japanese Published Patent Application No. H11-097379). In Reference 2, a separation plane is mechanically polished in order to remove a defective layer formed by hydrogen ion implantation or steps with several nanometers to several tens of nanometers in the separation plane.

In Reference 3 (Reference 3: Japanese Published Patent Application No. H11-163363) and Reference 4 (Japanese Published Patent Application No. 2000-012864), manufacturing methods of a semiconductor device utilizing Smart Cut (registered trademark), in which a highly heat-resistant substrate is used as a supporting substrate, are disclosed. In Reference 5 (Reference 5: Japanese Published Patent Application No. 2000-150905), a manufacturing method of a semiconductor device utilizing Smart Cut (registered trademark), in which a light-transmitting substrate is used as a supporting substrate, is disclosed.

### SUMMARY OF THE INVENTION

Glass substrates can be larger and can be obtained at lower cost than silicon wafers. Thus, by using a glass substrate as a supporting substrate, a large-area SOI substrate can be manufactured at low cost. However, the strain point of the glass substrate is equal to or lower than 700° C., and thus the glass substrate has low heat resistance. Therefore, the glass substrate cannot be heated at a temperature which exceeds the strain point of the glass substrate, and the process temperature is limited to 700° C. or lower. That is, there is a limitation on a process temperature in a step of reducing a crystal defect at a cleavage plane and a step of planarizing a surface.

In a conventional manner, a crystal defect of a single crystal semiconductor layer formed using a silicon wafer can be reduced by heating at a temperature of 1000° C. or higher; however, such a high-temperature process cannot be utilized for reducing a crystal defect of a single crystal semiconductor layer that is formed using a glass substrate having a strain point of 700° C. or lower. That is, a re-single-crystallization method in which crystallinity of a single crystal semiconductor layer that is formed using a glass substrate having a strain point of 700° C. or lower is recovered to be the same as or substantially the same as that of a single crystal semiconductor substrate before forming a SOI substrate, has not been established yet.

The glass substrate is bent more easily than a silicon wafer and has an undulated surface. In particular, it is difficult to perform mechanical polishing on a large-area glass substrate having a side that is longer than 30 cm. Accordingly, from the viewpoint of processing accuracy, yield, and the like, mechanical polishing on a cleavage plane is not recommended as planarization treatment of a semiconductor layer that is fixed to a supporting substrate. Meanwhile, it is required to suppress unevenness on the surface of the cleavage plane to manufacture high-performance semiconductor elements. In the case where transistors are manufactured using an SOI substrate, a gate electrode is formed over a semiconductor layer with a gate insulating layer interposed therebetween. Therefore, if there is large unevenness of the semiconductor layer, it is difficult to form a thin gate insulating layer with high withstand voltage. Therefore, a thick gate insulating layer is needed in order to increase the withstand voltage. Furthermore, large unevenness on the surface of the semiconductor layer leads to an increase of interface state density with the gate insulating layer or the like, which causes a degradation of electric characteristics of semiconductor elements such as a decrease in carrier mobility or an increase in threshold voltage.

In this manner, when a substrate such as a glass substrate, which has low heat resistance and is easily bent, is used for a supporting substrate, there is a problem in that it is difficult to reduce surface unevenness of a semiconductor layer that is separated from a silicon wafer so that the semiconductor layer is fixed to a supporting substrate.

In view of such problems, an object of the present invention is to provide a manufacturing method of a semiconductor substrate with which a high-performance semiconductor device can be formed even when a substrate having low heat resistance is used as a supporting substrate, and a manufacturing method of a semiconductor device using the semiconductor substrate.

One aspect of the present invention is a manufacturing method of a semiconductor device which is formed using a semiconductor substrate in which a single crystal semiconductor layer is bonded over an insulating surface. The semiconductor substrate is manufactured by bonding the single crystal semiconductor layer which is obtained by separation of a single crystal semiconductor substrate to a supporting substrate. A separation plane of the single crystal semiconductor layer separated from the single crystal semiconductor substrate is irradiated with a laser beam; accordingly, the single crystal semiconductor layer is melted and then re-single-crystallized.

Here, the term “single crystal” means a crystal in which, when certain crystal axes are focused, the direction of the crystal axes are oriented in the same direction in any portion of a sample crystal and which has no grain boundaries in the crystal. In this specification, the “single crystal” includes a crystal in which directions of crystal axes are uniform as described above and which has no grain boundary even when including a crystal defect or a dangling bond. In addition, “re-single-crystallization of a single crystal semiconductor layer” means that a semiconductor layer returns to have a single crystal structure through a different state from the single crystal structure (e.g., a liquid-phase state). In addition, it can be said that “re-single-crystallization of a single crystal semiconductor layer” means that a crystal semiconductor layer is recrystallized to form a single crystal semiconductor layer.

A semiconductor device is manufactured using the semiconductor substrate including the re-single-crystallized semiconductor layer as described above. One aspect of the present invention is that in a manufacturing process of a semiconductor device, heat treatment is performed at a temperature which does not cause melting of a single crystal semiconductor layer and which is equal to or higher than 400° C. and equal to or lower than a strain point of a supporting substrate. This heat treatment is performed after addition of an impurity element into the semiconductor layer. The impurity element is added in order to form a source region or a drain region or an LDD region in the semiconductor layer. Further, addition of the impurity element into the semiconductor layer is, in some cases, performed in order to control the threshold voltage.

According to a manufacturing method of a semiconductor device which is one aspect of the present invention, a single crystal semiconductor substrate which is bonded over a supporting substrate with a buffer layer interposed therebetween and in which a separation layer is formed in a region at a predetermined depth is heated to separate the single crystal semiconductor substrate at the separation layer or a region near the separation layer as a cleavage plane, thereby forming a single crystal semiconductor layer over the supporting substrate. Then, a surface of the single crystal semiconductor layer is irradiated with a laser beam to re-single-crystallize the surface of the single crystal semiconductor layer through melting, and the re-single-crystallized single crystal semiconductor layer is selectively etched to be separated into an island shape. An impurity element is selectively added into the single crystal semiconductor layer to form a pair of impurity regions and a channel formation region between the pair of impurity regions. Then, the single crystal semiconductor layer is heated at a process temperature which is equal to or higher than 400° C. and equal to or lower than a strain point of the supporting substrate and which does not cause melting of the single crystal semiconductor layer.

Note that the “cleavage” in this specification means separation of a single crystal semiconductor substrate at a separation layer formed in a region at a predetermined depth of the single crystal semiconductor substrate or near the separation layer. In addition, the “cleavage plane” means a separation plane which is a plane formed by separating the single crystal semiconductor substrate at the separation layer or near the separation layer.

According to a manufacturing method of a semiconductor device which is one aspect of the present invention, a single crystal semiconductor substrate which is bonded over a supporting substrate with a buffer layer interposed therebetween and in which a separation layer is formed in a region at a predetermined depth is heated to separate the single crystal semiconductor substrate at the separation layer or a region near the separation layer as a separation plane, thereby forming a single crystal semiconductor layer over the supporting substrate. Then, a surface of the single crystal semiconductor layer is irradiated with a laser beam to re-single-crystallize the surface of the single crystal semiconductor layer through melting, and the re-single-crystallized single crystal semiconductor layer is selectively etched to be separated into an island shape. Then, a gate electrode is formed over the single crystal semiconductor layer with a gate insulating layer interposed therebetween, and an impurity element is added using the gate electrode as a mask to form a pair of impurity regions and a channel formation region between the pair of impurity regions in the single crystal semiconductor layer. Then, the single crystal semiconductor layer is heated at a process temperature which is equal to or higher than 400° C. and equal to or lower than a strain point of the supporting substrate and which does not cause melting of the single crystal semiconductor layer.

In the above-described structures, a substrate having a strain point of 650° C. or higher and 690° C. or lower is preferably used as the supporting substrate.

Heating after formation of the impurity regions in the single crystal semiconductor layer is preferably performed at a process temperature of 450° C. or higher and 650° C. or lower.

The separation layer at which the single crystal semiconductor substrate is separated is preferably formed by irradiation with H₃⁺ ions, which are generated using a source gas containing hydrogen, with an ion doping apparatus.

By employing the present invention, a high-performance semiconductor device with favorable electric characteristics can be manufactured. Even when a semiconductor substrate which includes a single crystal semiconductor layer fixed to a supporting substrate having low heat resistance is used, the high-performance semiconductor device can be manufactured.

### BRIEF DESCRIPTION OF THE DRAWINGS

In the accompanying drawings:

FIGS. 1A to 1E illustrate an example of a manufacturing method of a semiconductor substrate;

FIGS. 2A to 2F illustrate an example of a manufacturing method of a semiconductor device;

FIGS. 3A to 3C illustrate an example of a manufacturing method of a semiconductor device;

FIGS. 4A to 4E illustrate an example of a manufacturing method of a semiconductor device;

FIGS. 5A to 5D illustrate an example of a manufacturing method of a semiconductor device;

FIGS. 6A to 6C illustrate an example of a manufacturing method of a semiconductor device;

FIGS. 7A to 7D illustrate an example of a manufacturing method of a semiconductor device;

FIGS. 8A to 8C illustrate an example of a manufacturing method of a semiconductor device;

FIGS. 9A and 9B illustrate an example of a manufacturing method of a semiconductor device;

FIG. 10 is a block diagram illustrating an example of a structure of a microprocessor;

FIG. 11 is a block diagram illustrating an example of a structure of an RFCPU;

FIGS. 12A and 12B are a plan view and a cross-sectional view, respectively, of a pixel of a liquid crystal display device;

FIGS. 13A and 13B are a plan view and a cross-sectional view, respectively, of a pixel of an electroluminescent display device;

FIGS. 14A to 14C are external views each illustrating an example of an electronic device;

FIGS. 15A to 15C are external views of a cellular phone;

FIGS. 16A and 16B illustrate structural examples of a semiconductor substrate;

FIG. 17 is an energy diagram of hydrogen molecules (H₂), H⁺ ions, H₂⁺ ions, and H₃⁺ ions;

FIG. 18 is a diagram showing the results of ion mass spectrometry;

FIG. 19 is a diagram showing the results of ion mass spectrometry;

FIG. 20 is a diagram showing the profile (measured values and calculated values) of hydrogen in the depth direction when the accelerating voltage is 80 kV;

FIG. 21 is a diagram showing the profile (measured values, calculated values, and fitting function) of hydrogen in the depth direction when the accelerating voltage is 80 kV;

FIG. 22 is a diagram showing the profile (measured values, calculated values, and fitting function) of hydrogen in the depth direction when the accelerating voltage is 60 kV;

FIG. 23 is a diagram showing the profile (measured values, calculated values, and fitting function) of hydrogen in the depth direction when the accelerating voltage is 40 kV;

FIG. 24 is a list of ratios of fitting parameters (hydrogen atom ratios and hydrogen ion species ratios);

FIGS. 25A to 25D illustrate a manufacturing method of a semiconductor substrate which is used as a sample;

FIG. 26A is a graph showing variation of Raman shift with respect to the irradiation energy density of the laser beam, and FIG. 26B is a graph showing variation of full width at half maximum of Raman spectra with respect to the irradiation energy density of the laser beam;

FIGS. 27A to 27C show EBSP data;

FIGS. 28A to 28C are graphs showing surface roughness of a single crystal semiconductor layer, which is obtained by calculation based on DFM images;

FIGS. 29A to 29C illustrate a manufacturing method of a semiconductor substrate which is used as a sample;

FIG. 30 is a graph from which lifetimes of single crystal silicon layers are evaluated; and

FIG. 31A is a graph plotting the peak wavenumbers of Raman shift of single crystal silicon layers, and FIG. 31B is a graph plotting the full widths at half maximum of Raman spectra of the single crystal silicon layers.

### DETAILED DESCRIPTION OF THE INVENTION

Embodiment modes and embodiments of the present invention will be described with reference to the drawings. The present invention is not limited to the following description, and it is easily understood by those skilled in the art that modes and details disclosed herein can be modified in various ways without departing from the spirit and the scope of the present invention. Therefore, the present invention is not to be construed with limitation to what is described in the embodiment modes and embodiments. Note that in some cases, the same portions or portions having a similar function are denoted by the same reference numeral through different drawings in a structure of the present invention described hereinafter.

### Embodiment Mode 1

In Embodiment Mode 1, a manufacturing method of a semiconductor device which uses a semiconductor substrate in which a single crystal semiconductor layer is fixed to a supporting substrate with a buffer layer interposed therebetween, will be described.

First, a method of forming a single crystal semiconductor layer over a supporting substrate will be described.

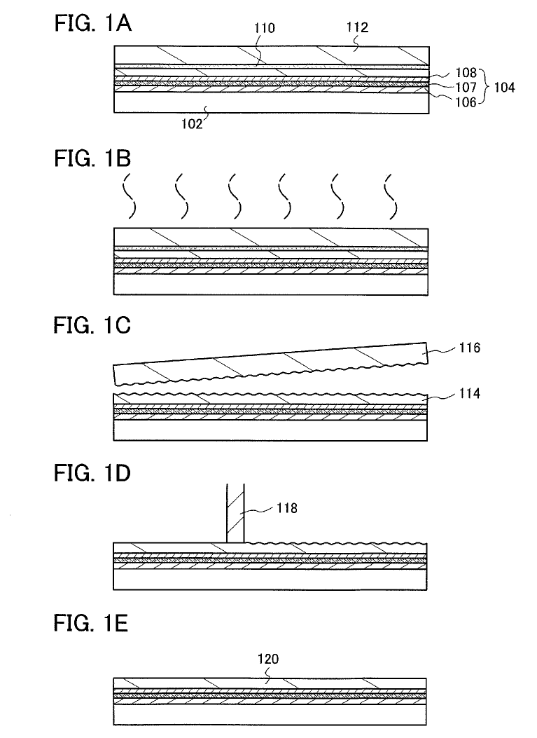

A single crystal semiconductor substrate 112 in which a separation layer 110 is formed in a region at a predetermined depth and a supporting substrate 102 are attached with a buffer layer 104 interposed therebetween so as to be bonded to each other (see FIG. 1A).

As the single crystal semiconductor substrate 112, a semiconductor substrate of silicon, germanium, or the like, a compound semiconductor substrate of gallium arsenide, indium phosphide, or the like, or the like can be used. As for a single crystal silicon substrate which is a typical example of the single crystal semiconductor substrate, circular wafers which are 5 inches in diameter (125 mm), 6 inches in diameter (150 mm), 8 inches in diameter (200 mm), and 12 inches in diameter (300 mm) are available. In addition, a circular wafer which is 18 inches (450 mm) in diameter is realized recently. Note that the shape of the wafer is not limited to a circular shape; and the wafer may be processed to be a rectangular shape. The rectangular wafer can be formed by cutting a commercial circular wafer. The commercial circular wafer can be cut with a cutting apparatus such as a dicer or a wire saw, a laser, plasma, an electronic beam, or any other cutting means. In addition, a rectangular single crystal semiconductor substrate can be formed in such a way that an ingot for manufacturing a semiconductor substrate is processed into a rectangular solid ingot so as to have a rectangular cross section and this rectangular solid ingot is sliced.

The thickness of the single crystal semiconductor substrate is not particularly limited and, for example, may be a thickness which satisfies SEMI standards. For example, the thickness of a single crystal silicon substrate is 625 μm in the case of 6 inches in diameter, 725 μm in the case of 8 inches in diameter, and 775 μm in the case of 12 inches in diameter (each having a thickness tolerance of ±25 μm). The thickness of the single crystal semiconductor substrate is not limited to that regulated by the SEMI standards, and the single crystal semiconductor substrate can be controlled to be thin or thick as appropriate at the time of being cut out from an ingot. Note that, when the thickness of the single crystal semiconductor substrate is set to be larger, the number of semiconductor substrates cut out from one ingot decreases but a material loss corresponding to a cutting margin can be reduced. Note that the wafer size is selected to satisfy the specifications or the like of the apparatus used in a manufacturing process of a semiconductor substrate. When the single crystal semiconductor substrate from which a single crystal semiconductor layer is separated is reused, it is preferable that the initial thickness of the single crystal semiconductor substrate be large because more semiconductor layers can be obtained from one single crystal semiconductor substrate.

As the supporting substrate 102, a substrate having an insulating surface is used, and specifically, any of various glass substrates which are used in the electronics industry such as an aluminosilicate glass substrate, an aluminoborosilicate glass substrate, and a barium borosilicate glass substrate; a quartz substrate; a ceramic substrate; a sapphire substrate; or the like can be used. A glass substrate is preferably used as the supporting substrate 102. It is preferable to use a glass substrate having a coefficient of thermal expansion of equal to or higher than 25×10⁻⁷/° C. and equal to or lower than 50×10⁻⁷/° C. (more preferably, equal to or higher than 30×10⁻⁷/° C. and equal to or lower than 40×10⁻⁷/° C.) and a strain point of equal to higher than 580° C. and equal to or lower than 700° C. (more preferably, equal to or higher than 650° C. and equal to or lower than 690° C.). Furthermore, in order to suppress contamination of a semiconductor device due to a metal impurity or the like, a non-alkali glass substrate is preferably used as the glass substrate. Materials of non-alkali glass substrates include glass materials such as aluminosilicate glass, aluminoborosilicate glass, and barium borosilicate glass. For example, it is preferable that a non-alkali glass substrate (product name: AN100), a non-alkali glass substrate (product name: EAGLE2000 (registered trademark)), or a non-alkali glass substrate (product name: EAGLE XG (registered trademark)) be used as the supporting substrate 102.

In the case any of various glass substrates for the electronics industry such as an aluminosilicate glass substrate, an aluminoborosilicate glass substrate, and a barium borosilicate glass substrate is used as the supporting substrate 102, the surface of the glass substrate is preferably a polished surface with favorable planarity. This is because, by using the polished surface of the glass substrate as a bonding plane in bonding the supporting substrate 102 to the single crystal semiconductor substrate 112, a defective bonding can be reduced. Note that the polishing of the glass substrate can be performed with cerium oxide or the like.

The separation layer 110 is formed in a region at a predetermined depth from a surface of the single crystal semiconductor substrate 112. In the separation layer 110, the crystal structure is impaired and microvoids are formed; thus, the separation layer 110 has a porous structure.

For example, hydrogen ions (H⁺ ions) or cluster ions such as H₂⁺ ions or H₃⁺ ions are accelerated by voltage and the surface of the single crystal semiconductor substrate 112 is irradiated with the ions; accordingly, the separation layer 110 can be formed in a region at a predetermined depth of the single crystal semiconductor substrate 112. Cluster ions are preferably used, and more preferably, H₃⁺ ions are used. This is because by using H₃⁺ ions for the irradiation, irradiation efficiency of hydrogen is improved as compared to the case of irradiation with H⁺ ions or H₂⁺ ions. Accordingly, takt time to form the separation layer 110 is shortened, so that productivity and throughput can be improved. In this embodiment mode, an example of forming the separation layer 110 using ions produced with a source gas containing hydrogen will be described.

A specific doping method using cluster ions according to the present invention is as follows: hydrogen plasma is produced from a source gas containing hydrogen, cluster ions produced in the hydrogen plasma are accelerated by voltage, and a surface of the single crystal semiconductor substrate 112 is irradiated with the cluster ions. Typical cluster ions produced in the hydrogen plasma are H₂⁺ ions and H₃⁺ ions. In addition, H⁺ ions that are hydrogen ions are also produced.

The doping to form the separation layer 110 is preferably performed with an ion doping apparatus. The ion doping apparatus is an apparatus with no mass separation, by which an object disposed in a chamber is irradiated with all kinds of ions produced by plasma excitation of a source gas.

Main components of the ion doping apparatus are an ion source for producing a desired ion and an accelerating mechanism for irradiating an object with ions. The ion source includes a gas supply system for supplying a source gas from which a desired kind of ions is produced, an electrode for producing plasma, and the like. As the electrode for producing plasma, a filament or an electrode for capacitively coupled radio-frequency discharge is used. The accelerating mechanism includes a power source; an electrode such as an extraction electrode, an accelerating electrode, a decelerating electrode, or an earth electrode; or the like. The electrode included in the accelerating mechanism is provided with a number of openings or slits, through which ions produced at the ion source pass and are accelerated. Note that the structure of the ion doping apparatus is not limited to the one described above, and a mechanism according to need can be provided.

In the case of forming the separation layer 110 by irradiating the single crystal semiconductor substrate 112 with hydrogen, a gas containing hydrogen, for example, an H₂ gas is supplied as a source gas. In the ion doping apparatus in which an H₂ gas is supplied as a source gas, hydrogen plasma is produced, and H⁺ ions that are hydrogen ions and cluster ions such as H₂⁺ ions and H₃⁺ ions are produced in the hydrogen plasma. At this time, it is preferable that H₃⁺ ions be contained at a proportion of equal to or greater than 50% in the total amount of ion species of H⁺ ions, H₂^{+l ions, and H}₃⁺ ions. It is more preferable that H₃⁺ ions be contained at a proportion of equal to or greater than 80% in the total amount of ion species of H⁺ ions, H₂⁺ ions, and H₃⁺ ions. In the case of employing the ion doping apparatus for the ion irradiation, irradiation with H⁺ ions and H₂⁺ ions can be performed as well as irradiation with H⁺ ions.

The doping with cluster ions can also be performed with an ion implantation apparatus; however, it is hard to produce H₃⁺ ions with the ion implantation apparatus. The ion implantation apparatus is an apparatus with mass separation, by which an object disposed in a chamber is irradiated with a certain ion species after mass separation is performed on a plural kinds of ion species which are produced by plasma excitation of a source gas.

Hereinafter, an ion irradiation method is considered below.

In this embodiment mode, in formation of the separation layer 110, the single crystal semiconductor substrate 112 is irradiated with ions that are derived from hydrogen (H) (hereafter referred to as “hydrogen ion species”). More specifically, a hydrogen gas or a gas which contains hydrogen in its composition is used as a source gas; hydrogen plasma is generated; and the single crystal semiconductor substrate 112 is irradiated with the hydrogen ion species in the hydrogen plasma.

### (Ions in Hydrogen Plasma)

In such hydrogen plasma as described above, hydrogen ion species such as H⁺ ions, H₂⁺ ions, and H₃⁺ ions are present. Here are listed reaction equations for reaction processes (formation processes, destruction processes) of the hydrogen ion species.

e+H→e+H⁺+e (1)

e+H₂→e+H₂⁺+e (2)

e+H₂→e+(H₂)*→e+H+H (3)

e+H₂⁺→e+(H₂⁺)*→e+H⁺+H (4)

H₂⁺+H₂→H₃⁺+H (5)

H₂⁺+H₂→H⁺+H+H₂ (6)

e+H₃⁺→e+H⁺+H+H (7)

e+H₃⁺→H₂+H (8)

e+H₃⁺→H+H+H (9)

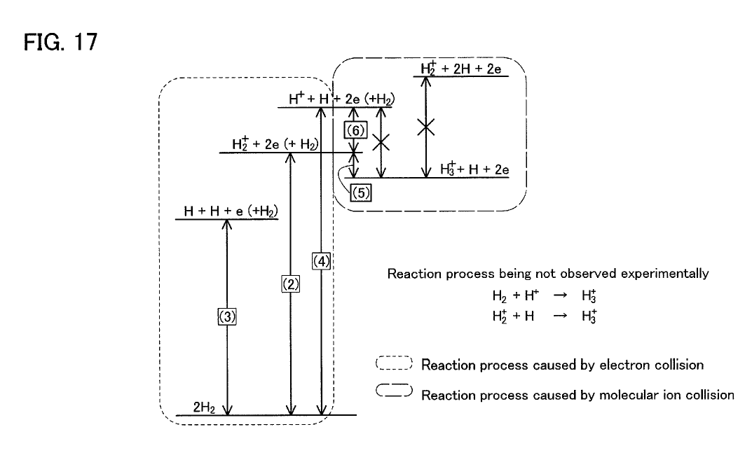

FIG. 17 is an energy diagram which schematically shows some of the above reactions. Note that the energy diagram shown in FIG. 17 is merely a schematic diagram and does not depict the relationships of energies of the reactions exactly.

### (H₃⁺ Ion Formation Process)

As shown above, H₃⁺ ions are mainly produced through the reaction process that is represented by the reaction equation (5). On the other hand, as a reaction that competes with the reaction equation (5), there is the reaction process represented by the reaction equation (6). For increasing in H₃⁺ ions, at the least, it is necessary that a reaction frequency of the reaction equation (5) is higher than that of the reaction equation (6) (note that, because there are also other reactions, (7), (8), and (9), through which the amount of H₃⁺ ions is decreased, the amount of H₃⁺ ions is not necessarily increased even if the reaction frequency of the reaction equation (5) is higher than that of the reaction equation (6)). In contrast, when the reaction frequency of the reaction equation (5) is lower than that of the reaction equation (6), the proportion of H₃⁺ ions in a plasma is decreased.

The amount of increase in the product on the right-hand side (rightmost side) reaction of each reaction equation given above depends on the density of a source material on the left-hand side (leftmost side) reaction of the reaction equation, the rate coefficient of the reaction, and the like. Here, it is experimentally confirmed that, when the kinetic energy of H₂⁺ ions is lower than about 11 eV, the reaction of the reaction equation (5) is dominant (that is, the rate coefficient of the reaction equation (5) is sufficiently higher than that of the reaction equation (6)) and that, when the kinetic energy of H₂⁺ ions is higher than about 11 eV, the reaction of the reaction equation (6) is dominant.

A charged particle receives Coulomb force due to an electric field, and the charged particle gains kinetic energy. The kinetic energy corresponds to the amount of decrease in potential energy due to an electric field. For example, the amount of kinetic energy which a given charged particle gains before colliding with another particle is equal to the amount of decrease in potential energy of the charged particle while the charged particle moves to another particle. That is, in a situation where a charged particle can travel a long distance in an electric field without colliding with another particle, the kinetic energy (or the average thereof) of the charged particle tends to be higher than that in a situation where the charged particle cannot. Such a tendency toward an increase in kinetic energy of a charged particle can be shown in a situation where mean free path of a particle is long, that is, in a situation where pressure of reaction gas is low.

Even in a situation where mean free path of a charged particle is short, depending on the situation, the charged particle can gain high kinetic energy before collision with other particle. That is, it can be said that, even in the situation where the mean free path is short, the charged particle can gain high kinetic energy if the charged particle is in high electric field.

This situation is applied to H₂⁺ ions. Assuming that an electric field is present as in a plasma generation chamber, the kinetic energy of H₂⁺ ions is high in a situation where the pressure in the chamber is low, and the kinetic energy of H₂⁺ ions is low in a situation where the pressure in the chamber is high. That is, because the reaction of the reaction equation (6) is dominant in the situation where the pressure in the chamber is low, the amount of H₃⁺ ions tends to be decreased, and because the reaction of the reaction equation (5) is dominant in the situation where the pressure in the chamber is high, the amount of H₃⁺ ions tends to be increased. In addition, in a situation where an electric field in a plasma generation region is high, that is, in a situation where the potential difference between given two points is large, the kinetic energy of H₂⁺ ions is high, and in the opposite situation, the kinetic energy of H₂⁺ ions is low. That is, because the reaction of the reaction equation (6) is dominant in the situation where the electric field is high, the amount of H₃⁺ ions tends to be decreased, and because the reaction of the reaction equation (5) is dominant in a situation where the electric field is low, the amount of H₃⁺ ions tends to be increased.

### (Differences Depending on Ion Source)

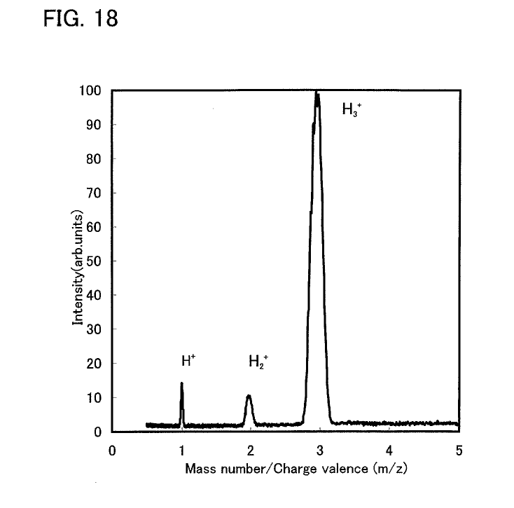

Here, an example, in which the proportions of hydrogen ion species (particularly, the proportion of H₃⁺ ions) are different, is described. FIG. 18 shows the results of mass spectrometry of ions that are generated from a 100% hydrogen gas (with the pressure of an ion source of 4.7×10⁻² Pa). Note that this mass spectrometry was performed by measurement of ions that were extracted from the ion source. The mass number was estimated from the peak position of the spectrum, and three ion species having mass numbers of, approximately, 1, 2, and 3 were detected. Due to the detection structure of the apparatus, H₂⁺ ions were detected as ions with a mass number of 2 and H₃⁺ ions were detected as ions with a mass number of 3. The mass number 1 peak, the mass number 2 peak, and the mass number 3 peak correspond to H⁺ ions, H₂⁺ ions, and H₃⁺ ions, respectively. The horizontal axis in FIG. 18 represents a value of the mass number divided by the charge valence, and the vertical axis in FIG. 18 represents the intensity of the spectrum, which corresponds to the number of ions. In FIG. 18, the number of ions is expressed as a relative proportion where the number of H₃⁺ ions is defined as 100. It can be seen from FIG. 18 that the ratio between ion species that are generated from the ion source, i.e., the ratio between H⁺ ions, H₂⁺ ions, and H₃⁺ ions, is about 1:1:8. Note that ions at such a ratio can also be generated by an ion doping apparatus which has a plasma source portion (ion source) that generates plasma, an extraction electrode that extracts an ion beam from the plasma, and the like.

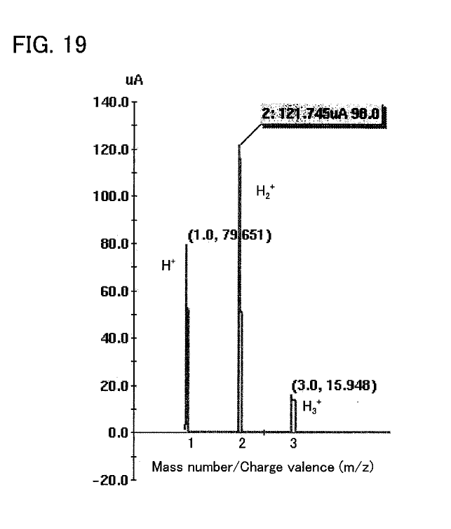

FIG. 19 shows the results of mass spectrometry of ions that are generated from PH₃ when an ion source different from that for the case of FIG. 18 is used and the pressure of the ion source is about 3×10⁻³ Pa. The results of this mass spectrometry focus on the hydrogen ion species. In addition, the mass spectrometry was performed by measurement of ions that were extracted from the ion source. As in FIG. 18, the horizontal axis in FIG. 19 represents a value of the mass number divided by the charge valence, and the mass number 1 peak, the mass number 2 peak, and the mass number 3 peak correspond to H⁺ ions, H₂⁺ ions, and H₃⁺ ions, respectively. The vertical axis in FIG. 19 represents the intensity of a spectrum corresponding to the number of ions. It can be seen from FIG. 19 that the ratio between ion species in a plasma, i.e., the ratio between H⁺ ions, H₂⁺ ions, and H₃⁺ ions, is about 37:56:7. Note that FIG. 19 shows the data obtained when the source gas is PH₃ and the ratio between the hydrogen ion species is about the same when a 100% hydrogen gas is used as a source gas, as well.

In the case of the ion source to which the data shown in FIG. 19 is attributed, H₃⁺ ions, of H⁺ ions, H₂⁺ ions, and H₃⁺ ions, is generated at a proportion of only about 7%. On the other hand, in the case of the ion source to which the data shown in FIG. 18 is attributed, the proportion of H₃⁺ ions can be up to 50% or higher (under the aforementioned conditions, about 80%). This is thought to result from the pressure and electric field in a chamber, which is clearly shown in the above consideration.

### (H₃⁺ Ion Irradiation Mechanism)

When plasma that contains a plurality of ion species as shown in FIG. 18 is generated and a single crystal semiconductor substrate is irradiated with the generated ion species without any mass separation, the surface of the single crystal semiconductor substrate is irradiated with each of H⁺ ions, H₂⁺ ions, and H₃⁺ ions. In order to reproduce the mechanism, from the irradiation with ions to the formation of an ion-introduced region, the following five types of models are considered.

Model 1, where the hydrogen ion species used for irradiation are H⁺ ions, which are still H⁺ ions (or H) after the irradiation.

Model 2, where the hydrogen ion species used for irradiation are H₂⁺ ions, which are still H₂⁺ ions (or H₂) after the irradiation.

Model 3, where the hydrogen ion species used for irradiation are H₂⁺ ions, each of which splits into two H atoms (or H⁺ ions) after the irradiation.

Model 4, where the hydrogen ion species used for irradiation are H₃⁺ ions, which are still H₃⁺ ions (or H₃) after the irradiation.

Model 5, where the hydrogen ion species used for irradiation are H⁺ ions, each of which splits into three H atoms (or H⁺ ions) after the irradiation.

(Comparison of Simulation Results with Measured Values)

Based on the above models, the irradiation of a silicon substrate with hydrogen ion species was simulated. As simulation software, SRIM (the Stopping and Range of Ions in Matter) was used. The SRIM is simulation software for ion introduction processes using a Monte Carlo method and is an improved version of TRIM (the Transport of Ions in Matter). Note that, for the calculation, a calculation based on Model 2 was performed with an H₂⁺ ion replaced by an H⁺ ion that has twice the mass number. In addition, a calculation based on Model 4 was performed with an H₃⁺ replaced by an H⁺ ion that has three times the mass number. Furthermore, a calculation based on Model 3 was performed with an H₂⁺ ion replaced by an H⁺ ion that has half the kinetic energy, and a calculation based on Model 5, with an H₃⁺ ion replaced by an H⁺ ion that has one-third the kinetic energy.

Note that SRIM is software intended for amorphous structures, but SRIM can be applied to a crystal structure in the cases where irradiation with the hydrogen ion species is performed with high energy at a high dose. This is because the crystal structure of a silicon substrate changes into a non-single-crystal structure due to the collision of the hydrogen ion species with Si atoms.

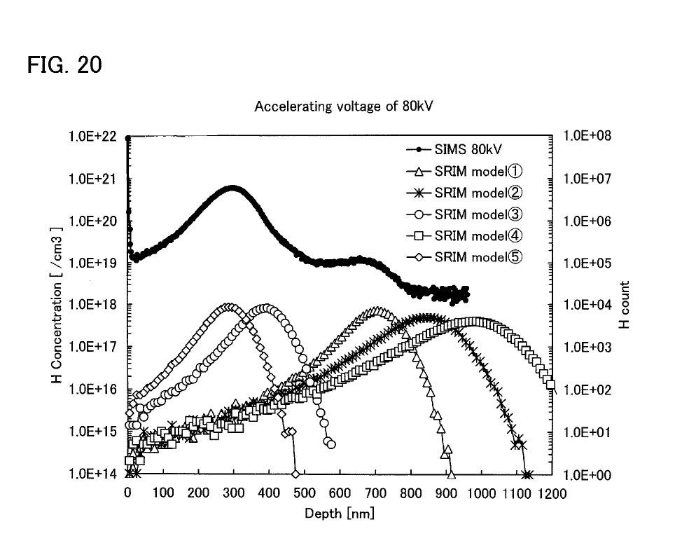

FIG. 20 shows the calculation results obtained when irradiation with the hydrogen ion species (irradiation with 100,000 atoms for H) is performed using Models 1 to 5. FIG. 20 also shows the hydrogen concentration (secondary ion mass spectrometry (SIMS) data) in a silicon substrate irradiated with the hydrogen ion species of FIG. 18. The results of calculations performed using Models 1 to 5 are expressed on the vertical axis (right axis) as the number of hydrogen atoms, and the SIMS data is expressed on the vertical axis (left axis) as the concentration of hydrogen atoms. The horizontal axis represents depth from the surface of a silicon substrate. Comparing the experimental SIMS data with the calculation results, Models 2 and 4 obviously do not fit the peaks of the SIMS data and a peak corresponding to Model 3 cannot be observed in the SIMS data. This result shows that the contribution of each of Models 2 to 4 is relatively small. Considering that the kinetic energy of ions is on the order of kiloelectron volts whereas the H—H bond energy is only about several electron volts, it is thought that the contribution of each of Models 2 and 4 is small because H₂⁺ ions and H₃⁺ ions mostly split into H⁺ ions or H by colliding with Si atoms.

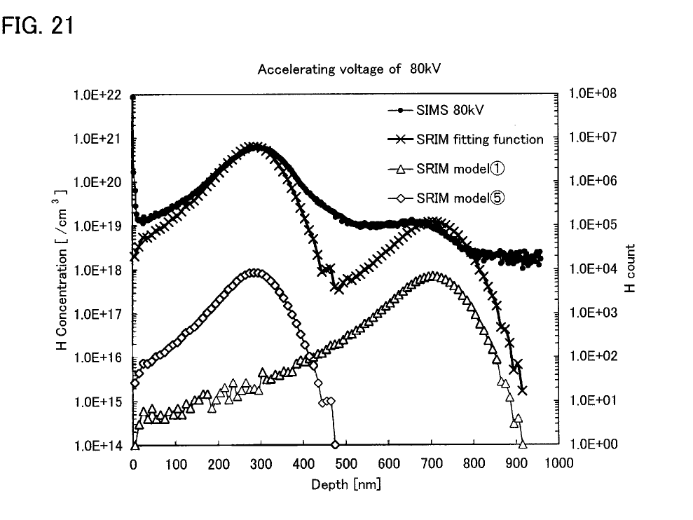

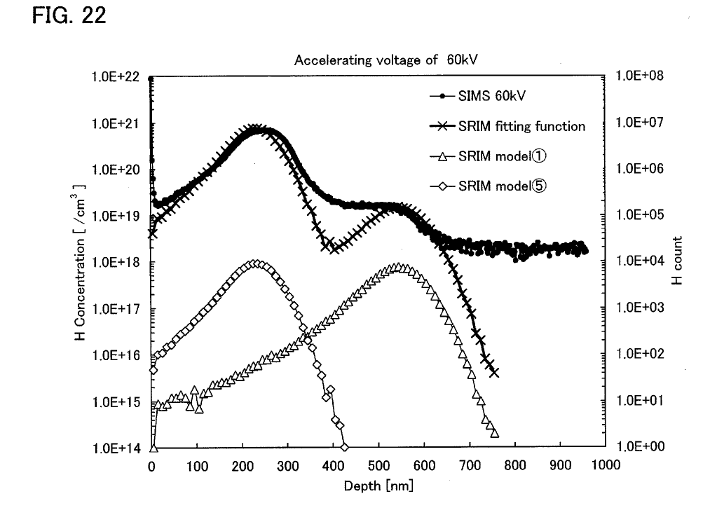

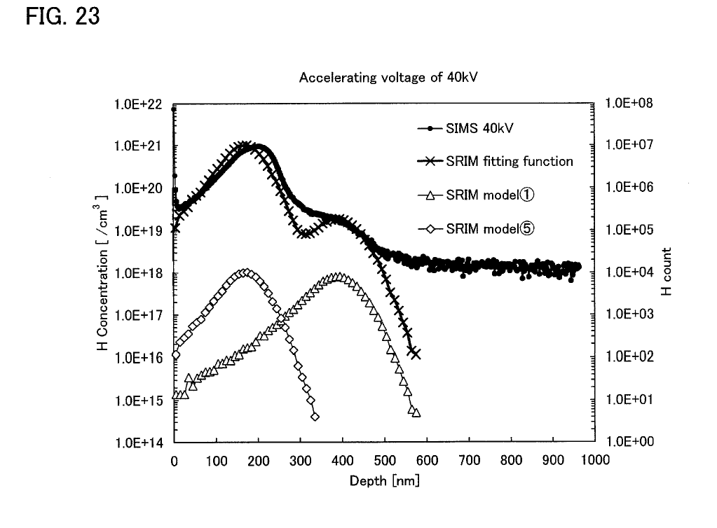

Accordingly, Models 2 to 4 will not be considered hereinafter. FIGS. 21 to 23 each show the calculation results obtained when irradiation with the hydrogen ion species (irradiation with 100,000 atoms for H) is performed using Models 1 and 5. FIGS. 21 to 23 also each show the hydrogen concentration (SIMS data) in an Si substrate irradiated with the hydrogen ion species of FIG. 18, and the simulation results fitted to the SIMS data (hereinafter referred to as a fitting function). Here, FIG. 21 shows the case where the accelerating voltage is 80 kV; FIG. 22, the case where the accelerating voltage is 60 kV; and FIG. 23, the case where the accelerating voltage is 40 kV. Note that the results of calculations performed using Models 1 and 5 are expressed on the vertical axis (right axis) as the number of hydrogen atoms, and the SIMS data and the fitting function are expressed on the vertical axis (left axis) as the concentration of hydrogen atoms. The horizontal axis represents depth from the surface of a silicon substrate.

The fitting function is obtained using the calculation formula given below, in consideration of Models 1 and 5. Note that, in the calculation formula, X and Y represent fitting parameters and V represents volume.

(Fitting Function)=X/V×(Data of Model 1)+Y/V×(Data of Model 5)

In consideration of the ratio between hydrogen ion species used for actual irradiation (H⁺ ions:H₂⁺ ions:H₃⁺ ions is about 1:1:8), the contribution of H₂⁺ ions (i.e., Model 3) should also be considered; however, Model 3 is excluded from the consideration given here for the following reasons:
Because the amount of hydrogen introduced through the irradiation process represented by Model 3 is lower than that introduced through the irradiation process of Model 5, there is no significant influence even if Model 3 is excluded from the consideration (no peak appears in the SIMS data either).

The peak position of Model 3, which is close to that of Model 5, is likely to be overlapped with the peak position of Model 5 because of channeling (a phenomenon in which an irradiated atom passes through a space in a crystal lattice, due to crystal lattice structure) that occurs in Model 5. That is, it is difficult to estimate fitting parameters for Model 3. This is because this simulation is performed on the assumption of amorphous silicon and the influence of crystallinity on this simulation is not considered.

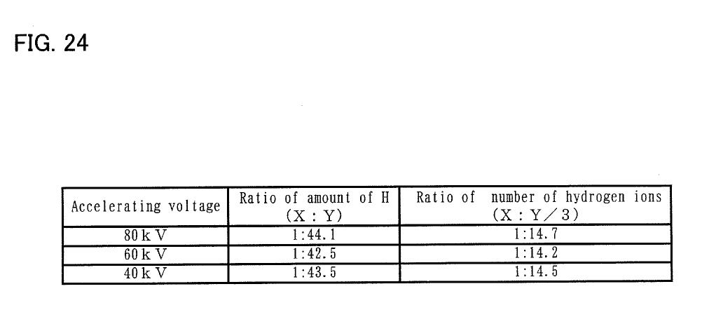

FIG. 24 lists the aforementioned fitting parameters. At any of the accelerating voltages, the ratio of the amount of H introduced according to Model 1 to that introduced according to Model 5 is about 1:42 to 1:45 (when the amount of H in Model 1 is defined as 1, the amount of H in Model 5 is about 42 to 45), and the ratio of the number of hydrogen ions used for irradiation, H⁺ ions (Model 1) to that of H₃⁺ ions (Model 5) is about 1:14 to 1:15 (when the amount of H⁺ ions in Model 1 is defined as 1, the amount of H₃⁺ ions in Model 5 is about 14 to 15). Considering that Model 3 is not included and the calculation is performed on the assumption of amorphous silicon, it can be said that values close to the ratio between hydrogen ion species used for actual irradiation (H⁺ ions:H₂⁺ ions:H₃⁺ ions is about 1:1:8) is obtained.

### (Effects of Use of H₃⁺ Ions)

A plurality of benefits resulting from use of H₃⁺ ions can be obtained by irradiation of a single crystal semiconductor substrate with hydrogen ion species with a higher proportion of H₃⁺ ions as shown in FIG. 18. For example, because an H₃⁺ ion dissolves into an H⁺ ion, H, or the like to be introduced into a substrate, hydrogen irradiation efficiency can be improved compared with the case of irradiation mainly with H⁺ ions or H₂⁺ ions. Use of H₃⁺ ions leads to an improvement in production efficiency of a semiconductor substrate in which a single crystal semiconductor layer is formed over an insulating surface. In addition, because the kinetic energy of an H⁺ ion or H which is generated after H₃⁺ ion dissolves tends to be low, an H₃⁺ ion is also suitable for manufacture of thin single crystal semiconductor layers.

Note that, it is preferable to use an ion doping apparatus that is capable of irradiation with the hydrogen ion species as shown in FIG. 18 in order to efficiently perform irradiation with H₃⁺ ions. This is because ion doping apparatuses are inexpensive and excellent for use in large-area treatment. Therefore, by irradiation with H₃⁺ ions by use of such an ion doping apparatus, significant effects such as an increase in an area to be irradiated, a reduction in costs, and an improvement in production efficiency can be obtained. On the other hand, if H₃⁺ ions are irradiated mainly, the present invention is not limited to the use of an ion doping apparatus.

It is preferable that the separation layer 110 illustrated in FIG. 1A contains hydrogen at 5×10²⁰ atoms/cm³ or more. When an irradiation region with hydrogen at high concentration is locally formed in the single crystal semiconductor substrate, the crystal structure is destroyed and microvoids are formed, thus, the separation layer 110 has a porous structure. Therefore, the microvoids formed in the separation layer 110 is changed in volume by heat treatment at a relatively low temperature (700° C. or lower), so that the single crystal semiconductor substrate 112 can be separated along the separation layer 110. Note that the hydrogen concentration in the separation layer 110 is controlled by a dosage of the ions, an accelerating voltage, or the like.

Further, the depth of the separation layer 110 formed in the single crystal semiconductor substrate 112 is controlled by an accelerating voltage of the ions used for the irradiation, and an irradiation angle of the ions. The depth of the separation layer 110 formed in the single crystal semiconductor substrate 112 determines the thickness of a single crystal semiconductor layer which is bonded to a supporting substrate 102 later. Therefore, the accelerating voltage and the irradiation angle of the ions are adjusted in consideration of the thickness of the single crystal semiconductor layer which is to be bonded. The desired thickness of the single crystal semiconductor layer depends on the usage. In this embodiment mode, the single crystal semiconductor layer is used as a semiconductor layer for forming a channel of a transistor, and is formed to have a thickness of 5 nm to 500 nm, and preferably 10 nm to 200 nm.

Although when the separation layer 110 is formed in a shallow region, the accelerating voltage needs to be low, irradiation with hydrogen can be efficiently performed and throughput can be improved by using cluster ions, typically, H₃⁺ ions. The H₃⁺ ions collide with atoms included in the single crystal semiconductor substrate 112 (in the case of irradiating an insulating layer, atoms included in the insulating layer) in irradiating the single crystal semiconductor substrate, so that the H₃⁺ ions are dissolved into three species including hydrogen atoms (H) and hydrogen ions (H⁺ ions), and the kinetic energy of each of the three species is about one third of the kinetic energy of the H₃⁺ ion obtained by acceleration by voltage. That is, it can be considered that by irradiating with H₃⁺ ions, the accelerating voltage of H₃⁺ ions can be approximately three times as large as that of H⁺ ions. Increase in the accelerating voltage enables the reduction of takt time taken to form the separation layer 110, which might be a rate-controlling factor; accordingly, productivity and throughput can be improved. Note that, the mode in which the H₃⁺ ion dissolves into three species is exemplified by, the separation into three ‘hydrogen atoms’, three ‘H⁺ ions’, two ‘hydrogen atoms’ and one ‘H⁺ ion’, or one ‘hydrogen atom’ and two ‘H⁺ ions’.

Further, in irradiation with ions to form the separation layer, it is preferable that the single crystal semiconductor substrate 112 be inclined at about 6°±4° with respect to the horizontal direction. By irradiating the single crystal semiconductor substrate 112 which is inclined with respect to the horizontal direction with ions, increase in distribution of ion concentration in the separation layer 110 can be suppressed. In addition, the separation layer 110 can be formed easily even in a region at a small depth from the surface of the single crystal semiconductor substrate 112.

The buffer layer 104 may have a single-layer structure or a stacked structure of two or more layers and includes a layer serving as a bonding plane which is preferably a layer having smoothness. More preferably, the surface of the buffer layer 104 which has smoothness and can form a hydrophilic surface is formed, so that the buffer layer 104 can favorably serve as a bonding layer which forms a bonding plane. Further, an insulating layer containing nitrogen is preferably formed as at least one layer included in the buffer layer 104. In the case where a substrate containing a small amount of metal impurities, such as a glass substrate, is used as the supporting substrate 102, the metal impurities might diffuse into the single crystal semiconductor substrate (or single crystal semiconductor layer) side. The insulating layer containing nitrogen has an effect of blocking metal impurities; therefore, even when metal impurities are contained in the supporting substrate 102, the insulating layer can prevent the metal impurities from diffusing into the single crystal semiconductor substrate. As the layer which has smoothness and can form a hydrophilic surface, an insulating layer containing nitrogen can be formed. The insulating layer containing nitrogen can serve as both a bonding layer and a blocking layer.

As a layer in contact with the single crystal semiconductor substrate, of the buffer layer 104, an oxide film such as a silicon oxide layer or a silicon oxynitride layer is preferably formed. This is because formation of a silicon nitride layer or a silicon nitride oxide layer which is in direct contact with the single crystal semiconductor substrate 112 may cause degradation of the interface characteristics between the layer and the single crystal semiconductor substrate due to formation of trap levels at the interface. When the buffer layer 104 is formed to have a stacked structure in which an oxide film, an insulating layer containing nitrogen, and a bonding layer are formed in this order from the single crystal semiconductor substrate, the single crystal semiconductor layer can be prevented from being contaminated with metal impurities and electric characteristics at the interface can be improved. In addition, strong bonding to a supporting substrate can be obtained in the following process.

For example, as the buffer layer 104, a silicon oxynitride layer (or a silicon oxide layer), a silicon nitride oxide layer (or a silicon nitride layer), and a bonding layer are formed in this order from the single crystal semiconductor substrate 112. Alternatively, a silicon oxide layer (or a silicon oxynitride layer) and a silicon nitride oxide layer (or a silicon nitride layer) are formed in this order from the single crystal semiconductor substrate 112. In the latter case, the silicon nitride oxide layer (or the silicon nitride layer) also serves as a bonding layer. In the case where an insulating layer containing nitrogen and an insulating layer serving as a bonding layer are separately provided, the buffer layer can have a three-layer structure. In the case where an insulating layer containing nitrogen is made to serve as a bonding layer as well, the buffer layer can have a two-layer structure.

In this embodiment mode, as an example, the buffer layer 104 has a three-layer structure which includes an insulating layer 108, an insulating layer 107, and an insulating layer 106 from the single crystal semiconductor substrate 112. In addition, an oxide film (a silicon oxide layer, a silicon oxynitride layer, or the like) is formed as the insulating layer 108, an insulating layer containing nitrogen is formed as the insulating layer 107, and a layer which has smoothness and can function as a bonding layer is formed as the insulating layer 106.

For the insulating layer which has smoothness and can form a hydrophilic surface, silicon oxide, silicon nitride, silicon oxynitride, silicon nitride oxide, or the like can be used. Note that a silicon oxynitride layer in this specification means a layer which contains more oxygen than nitrogen and includes oxygen, nitrogen, silicon, and hydrogen at concentrations ranging from 50 at. % to 70 at. %, 0.5 at. % to 15 at. %, 25 at. % to 35 at. %, and 0.1 at. % to 10 at. %, respectively. Further, a silicon nitride oxide layer means a layer that contains more nitrogen than oxygen and includes oxygen, nitrogen, silicon, and hydrogen at concentrations ranging from 5 at. % to 30 at. %, 20 at. % to 55 at. %, 25 at. % to 35 at. %, and 10 at. % to 30 at. %, respectively. These concentrations can be measured using Rutherford backscattering spectrometry (RBS) and hydrogen forward scattering (HFS).

For example, it is preferable that silicon oxide formed by a CVD method using organosilane as a process gas be used for the insulating layer which has smoothness and can form a hydrophilic surface. This is because, by using the silicon oxide layer formed by a plasma CVD method using organosilane as a process gas, the bonding strength between the supporting substrate 102 and the single crystal semiconductor layer to be formed in the following process can be increased. As organosilane, the following silicon-containing compound can be used: tetraethoxysilane (TEOS) (chemical formula: Si(OC₂H₅)₄); tetramethylsilane (TMS) (chemical formula: Si(CH₃)₄); trimethylsilane (chemical formula: (CH₃)₃SiH); tetramethylcyclotetrasiloxane (TMCTS); octamethylcyclotetrasiloxane (OMCTS); hexamethyldisilazane (HMDS); triethoxysilane (chemical formula: SiH(OC₂H₅)₃); trisdimethylaminosilane (chemical formula: SiH(N(CH₃)₂)₃); or the like.

Alternatively, a silicon oxide layer, a silicon oxynitride layer, a silicon nitride layer, or a silicon nitride oxide layer, which is formed by a CVD method using inorganic silane such as monosilane, disilane, or trisilane as a process gas can be used. Note that, in the case where a silicon oxide layer is formed by a CVD method using organosilane or inorganic silane as a process gas, a gas which provides oxygen is preferably mixed in the process gas. Further, in the case where a silicon nitride layer is formed by a CVD method using organosilane or inorganic silane as a process gas, a gas which provides nitrogen is mixed the process gas. As the gas which provides oxygen, oxygen, nitrogen oxide, or the like can be used. Further, as the gas which provides nitrogen, nitrogen oxide, ammonia, or the like can be used. In addition, an inert gas such as argon, helium, or nitrogen or a hydrogen gas may be mixed in the gas.

Note that, in this specification, the CVD (chemical vapor deposition) method includes, in its category, a plasma CVD method, a thermal CVD method, and a photo CVD method. Further, the thermal CVD method includes a low-pressure CVD method and an atmospheric pressure CVD method in its category.

Alternatively, a silicon oxide layer which grows by reaction of oxygen radicals, a chemically oxidized layer which is formed with an oxidizing chemical agent, or an insulating layer having a siloxane (Si—O—Si) bond can be used as the layer having smoothness. Note that the insulating layer having a siloxane bond in this specification refers to a layer in which a bond of silicon (Si) and oxygen (O) is included in a skeletal structure. Siloxane has a substituent. An organic group (e.g., an alkyl group or an aromatic hydrocarbon) or a fluoro group can be given as the substituent. The organic group may include a fluoro group. Note that the insulating layer having a siloxane bond can be formed by an application method such as a spin coating method.

As the insulating layer containing nitrogen used as the insulating layer 107 or the insulating layer 106, a silicon nitride layer, a silicon nitride oxide layer, a silicon oxynitride layer, or the like can be given. These insulating layers may be formed by a CVD method, a sputtering method, or an atomic layer epitaxy (ALE) method.

As the oxide film formed as the insulating layer 108, a silicon oxide layer, a silicon oxynitride layer, or the like can be given. These insulating layers can be formed by a CVD method, a sputtering method, or an atomic layer epitaxy (ALE) method. As the insulating layer 108, a thermal oxide film may be formed by a thermal oxidation method. The thermal oxide film formed by a thermal oxidation method has smoothness and can form a hydrophilic surface. In the case where the insulating layer containing nitrogen is made to serve as a bonding layer as well, a layer having smoothness is preferably formed as the insulating layer 108 which is in contact with the single crystal semiconductor substrate 112. By forming the insulating layer containing nitrogen which serves as a bonding layer over a layer having smoothness, the smoothness of the insulating layer containing nitrogen can be improved as well.

There is no limitation on the formation order of the separation layer 110 and the buffer layer 104. In the case where the buffer layer 104 has the structure illustrated in FIG. 1A, there can be the following formation orders, for example: (1) the insulating layer 108 is formed over the single crystal semiconductor substrate 112, the single crystal semiconductor substrate 112 is irradiated with ions (e.g., H₃⁺ ions) from the surface over which the insulating layer 108 is formed to form the separation layer 110, and the insulating layer 107 and the insulating layer 106 are formed over the insulating layer 108; (2) the insulating layer 108 and the insulating layer 107 are formed over the single crystal semiconductor substrate 112, the single crystal semiconductor substrate 112 is irradiated with ions (e.g., H₃⁺ ions) from the surface over which the insulating layer 108 and the insulating layer 107 are formed to form the separation layer 110, and the insulating layer 106 is formed over the insulating layer 107; (3) the insulating layer 108, the insulating layer 107, and the insulating layer 106 are formed over the single crystal semiconductor substrate 112, and the single crystal semiconductor substrate 112 is irradiated with ions (e.g., H₃⁺ ions) from the surface over which the insulating layer 108, the insulating layer 107, and the insulating layer 106 are formed to form the separation layer 110; and (4) a protective layer is formed over a surface of the single crystal semiconductor substrate 112, the single crystal semiconductor substrate 112 is irradiated with ions (e.g., H₃⁺ ions) from the surface over which the protective layer is formed to form the separation layer 110, the protective layer is removed, and the insulating layer 108, the insulating layer 107, and the insulating layer 106 are sequentially formed over the surface of the single crystal semiconductor substrate 112, from which the protective layer is removed.

In the case where an oxide film is formed as the insulating layer 108 and an insulating layer containing nitrogen which serves as a bonding layer is formed as the insulating layer 107, there can be the following formation orders, for example: (5) the insulating layer 108 is formed over the single crystal semiconductor substrate 112, the single crystal semiconductor substrate 112 is irradiated with ions (e.g., H₃⁺ ions) from the surface over which the insulating layer 108 is formed to form the separation layer 110, and the insulating layer 107 is formed over the insulating layer 108; (6) the insulating layer 108 and the insulating layer 107 are stacked over the single crystal semiconductor substrate 112, and the single crystal semiconductor substrate 112 is irradiated with ions (e.g., H₃⁺ ions) from the surface over which the insulating layer 108 and the insulating layer 107 are formed to form the separation layer 110; and (7) a protective layer is formed over the single crystal semiconductor substrate 112, the single crystal semiconductor substrate 112 is irradiated with ions (e.g., H₃⁺ ions) from the surface over which the protective layer is formed to form the separation layer 110, the protective layer is removed, and the insulating layer 108 and the insulating layer 107 are formed over the surface from which the protective layer is removed.

In the case where the insulating layer 106, the insulating layer 107, or the insulating layer 108 is formed after formation of the separation layer 110, the insulating layer is formed at a film formation temperature which does not cause degassing of the separation layer 110. For example, a film formation temperature of 350° C. or lower is preferable. Further, the buffer layer may be provided on the supporting substrate 102.

The one surface of the single crystal semiconductor substrate 112 and the one surface of the supporting substrate 102 are attached with the buffer layer interposed therebetween so as to be bonded to each other. In this embodiment mode, the insulating layer 108, the insulating layer 107, and the insulating layer 106 are formed on the single crystal semiconductor substrate 112 as the buffer layer 104, and the single crystal semiconductor substrate 112 and the supporting substrate 102 are bonded with the buffer layer 104 interposed therebetween. The bonding planes are one surface of the insulating layer 106 and the one surface of the supporting substrate 102.

Before the single crystal semiconductor substrate 112 and the supporting substrate 102 are bonded to each other, the bonding planes are sufficiently cleaned in advance. In this embodiment mode, the one surface of the insulating layer 106 which is formed over the single crystal semiconductor substrate 112 and the one surface of the supporting substrate 102 are cleaned in advance. Then, the insulating layer 106 formed over the single crystal semiconductor substrate 112 and the supporting substrate 102 are made in close contact with each other, thereby forming a bond. It is considered that Van der Waals force acts on the bonding at an early stage and a strong bond due to hydrogen bonding can be formed by pressure bonding of the insulating layer 106 formed over the single crystal semiconductor substrate 112 and the substrate having an insulating surface.

In order to favorably perform bonding between the insulating layer 106 formed over the single crystal semiconductor substrate 112 and the supporting substrate 102, the bonding planes may be activated in advance. For example, one or both of the bonding planes are irradiated with an atomic beam or an ion beam. When an atomic beam or an ion beam is used, an inert gas neutral atomic beam or inert gas ion beam of argon or the like can be used. It is also possible to activate the bonding planes by plasma irradiation or radical treatment. Such surface treatment facilitates formation of bonding between different materials even at a temperature of 400° C. or lower. The bonding planes may be cleaned with ozone-containing water, oxygen-containing water, hydrogen-containing water, pure water, or the like. By such cleaning treatment, the bonding planes can become hydrophilic and the number of OH groups on the bonding planes can be increased. As a result, a hydrogen bond between the insulating layer 106 and the supporting substrate 102 can be further strengthened.

Note that heat treatment or pressure treatment is preferably performed after the single crystal semiconductor substrate 112 is bonded to the supporting substrate 102. Heat treatment or pressure treatment makes it possible to increase the bonding strength. If the heat treatment is performed, the temperature of the heat treatment is set at a temperature which is equal to or lower than the strain point of the supporting substrate 102 and does not cause change in volume of the separation layer 110 formed in the single crystal semiconductor substrate 112, preferably at a temperature equal to or higher than room temperature and equal to or lower than 400° C. The pressure treatment is performed so that pressure is applied in a perpendicular direction to the bonding planes, in consideration of the pressure resistance of the supporting substrate 102 and the single crystal semiconductor substrate 112.

Heat treatment is performed (see FIG. 1B) so that the single crystal semiconductor substrate 112 is separated from the supporting substrate 102 by using the separation layer 110 or a region near the separation layer 110 as a separation plane (see FIG. 1C). A single crystal semiconductor layer 114 which is separated from the single crystal semiconductor substrate 112 remains over the supporting substrate 102. In addition, a separation substrate 116 from which the single crystal semiconductor layer 114 is separated is obtained.

By performing heat treatment as illustrated in FIG. 1B, the volume of the microvoids formed in the separation layer 110 is changed; thus, the single crystal semiconductor substrate can be separated along the separation layer 110 or the region near the separation layer 110. The heat treatment is preferably performed at a temperature of equal to or higher than 400° C. and equal to or lower than the strain point of the supporting substrate 102. Further, the heat treatment is preferably performed at a temperature of equal to or higher than the film formation temperature of the insulating layer 106 which serves as a bonding plane. For example, heat treatment is performed at a temperature in the range of 400° C. or higher and 650° C. or lower, so that separation along the separation layer 110 or the region near the separation layer 110 is caused. The insulating layer 106 is bonded to the supporting substrate 102, and the single crystal semiconductor layer 114 having almost the same crystallinity as the single crystal semiconductor substrate 112 remains over the supporting substrate 102 with the buffer layer 104 interposed therebetween. The separation substrate 116 is obtained by separation of the single crystal semiconductor layer 114 from the single crystal semiconductor substrate 112.

For the heat treatment by which the single crystal semiconductor substrate 112 is separated, a heat treatment apparatus such as a furnace, a rapid thermal anneal (RTA) apparatus, a microwave heating apparatus, or the like can be used. As a heating method of the heat treatment apparatus, a resistance heating method, a lamp heating method, a gas heating method, a radio wave heating method, or the like can be given. The RTA apparatus is one kind of rapid thermal processing (RTP) apparatus.

Generally, the furnace is outer-heating type, and with the furnace, the inside of the chamber and an object (e.g., substrate) are heated under thermal equilibrium condition.

On the other hand, the RTA apparatus performs rapid heating, and with the RTA apparatus, the thermal energy is directly provided to an object so that the inside of the chamber and the object are heated under thermal nonequilibrium condition. As the RTA apparatus, an RTA apparatus employing a lamp heating method (lamp rapid thermal anneal (LRTA) apparatus), an RTA apparatus employing a gas heating method which uses a heated gas (gas rapid thermal anneal (GRTA) apparatus), an RTA apparatus employing both a lamp heating method and a gas heating method, and the like can be given. An LRTA apparatus is an apparatus for heating an object by radiation of light emitted from a lamp such as a halogen lamp, a metal halide lamp, a xenon arc lamp, a carbon arc lamp, a high pressure sodium lamp, or a high pressure mercury lamp. A GRTA apparatus is an apparatus for heating an object by heat radiation with light emitted from any of the aforementioned lamps and by heat conduction from a gas which is heated with light emitted from any of the aforementioned lamps. As the gas, an inert gas, like nitrogen or a noble gas such as argon, which does not react with an object through heat treatment is used. An LRTA apparatus or a GRTA apparatus may have not only a lamp but also a device for heating an object by heat conduction or heat radiation from a heater such as a resistance heater.

A microwave heating apparatus is an apparatus for heating an object by radiation of a microwave. A microwave heating apparatus may have a device for heating an object by heat conduction or heat radiation from a heater such as a resistance heater. Further, heat treatment using laser beam irradiation may be performed. It is preferable that the temperature of the supporting substrate 102 to which the single crystal semiconductor layer 114 is fixed be increased to 550° C. or higher and 650° C. or lower by this heat treatment.

When a GRTA apparatus is used, the treatment temperature can be set at 550° C. or higher and 650° C. or lower, and the treatment time can be set at 0.5 minutes or more and 60 minutes or less. When a furnace is used, the treatment temperature can be set at 200° C. or higher and 650° C. or lower, and the treatment time can be set at one hour or more and four hours or less. In the case where a microwave heating apparatus is used, irradiation can be, for example, performed with microwaves having a frequency of 2.45 GHz and the treatment time can be set at 10 minutes or more and 20 minutes or less.

A specific treatment method of heat treatment using a vertical furnace with resistance heating will be described. The supporting substrate 102 to which the single crystal semiconductor substrate 112 is bonded is placed in a boat for the vertical furnace. The boat is carried into a chamber of the vertical furnace. In order to suppress oxidation of the single crystal semiconductor substrate 112, the chamber is first evacuated to a vacuum state. The degree of vacuum is approximately 5×10⁻³ Pa. After the vacuum state is obtained, nitrogen is supplied to the chamber so that the chamber has a nitrogen atmosphere under atmospheric pressure. Meanwhile, the temperature is increased to 200° C.

After the chamber is supplied with a nitrogen atmosphere under atmospheric pressure, heating is performed at 200° C. for two hours. Then, the temperature is increased to 400° C. in one hour. After the heating temperature of 400° C. becomes steady, the temperature is increased to 600° C. in one hour. After the heating temperature of 600° C. becomes steady, heat treatment is performed at 600° C. for two hours. Then, the heating temperature is decreased to 400° C. in one hour, and after 10 minutes to 30 minutes, the boat is carried out from the chamber. In an air atmosphere, the separation substrate 116 and the supporting substrate 102 to which the single crystal semiconductor layer 114 is bonded are cooled on the boat.

In the above-mentioned heat treatment using a vertical furnace with resistance heating, heat treatment to increase bonding force between the insulating layer 106 serving as a bonding layer and the supporting substrate 102, and heat treatment to cause separation at the separation layer 110 or near the separation layer 110 can be performed in succession. These two heat treatments can be performed in different apparatuses and, for example, heat treatment is performed at 200° C. for two hours in a furnace and then the supporting substrate 102 and the single crystal semiconductor substrate 112 which are bonded to each other are carried out from the furnace. Then, heat treatment is performed at a treatment temperature of equal to or higher than 600° C. and equal to or lower than 700° C. for 1 minute to 30 minutes with an RTA apparatus, so that the single crystal semiconductor substrate 112 can be separated at the separation layer 110.

The separation substrate 116 which is formed by separation of the single crystal semiconductor layer 114 from the single crystal semiconductor substrate 112 has a problem when it is reused as a single crystal semiconductor substrate to be bonded as it is because planarity of the separation plane of the separation substrate 116 is damaged. In addition, there are some cases where the separation substrate 116 includes a separation layer or a crystal defect at the separation plane or near the separation plane, or where a portion which is not bonded to the supporting substrate 102 is left in the separation substrate 116. Therefore, the separation substrate 116 has to be subjected to reprocessing treatment so as to be reused as the single crystal semiconductor substrate 112 to be bonded.

As the reprocessing treatment of the separation substrate 116, polishing treatment, etching treatment, thermal treatment, laser beam irradiation, or the like can be used. It is preferable to employ polishing treatment capable of mirror-like finishing. By polishing treatment, the substrate can be made to have a surface with superior planarity. For the polishing treatment, a chemical mechanical polishing (CMP) method, a mechanical polishing method, a liquid jet polishing method, or the like can be used.

For example, after performing wet etching to remove the buffer layer or the separation layer left over the separation substrate 116, the surface can be planarized by CMP treatment. As an etchant for wet etching, a hydrofluoric acid can be used in the case of removing the buffer layer left over the separation substrate 116, and a tetramethylammonium hydroxide (TMAH) aqueous solution or the like can be used in the case of removing the separation layer or a projection portion.

After the separation substrate 116 is subjected to etching treatment, the surface thereof is polished to be planarized. For example, CMP or mechanical polishing can be used as the polishing treatment. In order to make the separation substrate 116 have a smooth surface, polishing of about 1 μm to 10 μm is preferably performed. After the polishing, cleaning with a hydrofluoric acid or RCA cleaning is preferably performed because abrasive particles or the like are left over the surface of the separation substrate 116.

Through the above-described process, the separation substrate 116 can be reprocessed as a single crystal semiconductor substrate to be bonded. The reprocessed single crystal semiconductor substrate can be used as a substrate which is a base of a single crystal silicon layer, and thus an SOI substrate can be newly manufactured. The reprocessed single crystal semiconductor substrate may be used for other applications. By reusing the separation substrate in this manner, it is not necessary to prepare a new single crystal semiconductor substrate which is a raw material; accordingly, cost can be reduced and resources can be utilized efficiently.

The separation plane of the single crystal semiconductor layer 114 which is bonded to the supporting substrate 102 also has damaged planarity. The single crystal semiconductor layer 114 has a crystal defect due to formation of the separation layer 110 or the separation step. In a transistor to be described in this embodiment mode, an active layer including a channel formation region, a source region, and a drain region is formed using a single crystal semiconductor layer which is bonded over a supporting substrate. If the surface of the single crystal semiconductor layer is rough, it is difficult to form a thin gate insulating layer with high withstand voltage thereover. Further, if a crystal defect is formed in the single crystal semiconductor layer, variation of characteristics or the like of formed transistors with the single crystal semiconductor layer occurs and quality or reliability of the transistors is degraded. Further, a crystal defect existing in the single crystal semiconductor layer in which a channel is formed adversely affects electric characteristics such as mobility and a subthreshold swing value. Therefore, surface planarization and reduction in crystal defects of the single crystal semiconductor layer bonded over the supporting substrate 102 are preferably performed to improve quality of the single crystal semiconductor layer. One feature of the present invention is that the single crystal semiconductor layer 114 separated from the single crystal semiconductor substrate 112 is irradiated with a laser beam in order to planarize the single crystal semiconductor layer and improve quality of the single crystal semiconductor layer.

The single crystal semiconductor layer 114 is irradiated with a laser beam 118 (see FIG. 1D). Specifically, the separation plane of the single crystal semiconductor layer 114 is irradiated with the laser beam 118. Part of the single crystal semiconductor layer 114 is melted by the irradiation with the laser beam 118 and then re-single-crystallized to form a single crystal semiconductor layer 120 (see FIG. 1E).

When the single crystal semiconductor layer 114 is partially melted by irradiation with the laser beam 118, the surface of the single crystal semiconductor layer 120 which is re-single-crystallized can have improved planarity by the effect of surface tension. When the surface of the single crystal semiconductor layer has improved planarity, a gate insulating layer formed thereover can be thinned. Accordingly, a transistor with a suppressed gate voltage and a high ON current can be formed. In addition, improvement in planarity of the single crystal semiconductor layer by irradiation with the laser beam 118 can be observed using an atomic force microscope (AFM) or the like.

By partially melting the surface of the single crystal semiconductor layer 114 by irradiation with the laser beam 118, the surface can be re-single-crystallized to have improved crystallinity. Improvement in crystallinity of the single crystal semiconductor layer in which a channel is formed enables high carrier mobility, thereby manufacturing a high-performance field-effect transistor. Note that improvement in crystallinity of the single crystal semiconductor layer due to irradiation with the laser beam 118 can be observed by a Raman shift obtained from a Raman spectrum which can be measured by Raman spectroscopy, a full width at half maximum, or the like.

In other words, using a semiconductor substrate in which a single crystal semiconductor layer is fixed to a supporting substrate and which is manufactured through re-single-crystallization of the single crystal semiconductor layer, a transistor with a high ON current and a high carrier mobility can be manufactured. Further, since irradiation with the laser beam 118 is employed for the re-single-crystallization process of the single crystal semiconductor layer, the re-single-crystallized single crystal semiconductor layer can be formed without application of force which damages the supporting substrate 102 and without heating the supporting substrate 102 at a temperature exceeding the strain point of the supporting substrate.

The surface of the single crystal semiconductor layer 114 irradiated with the laser beam 118 is planarized, and the arithmetical mean roughness of unevenness on the surface can be 1 nm or more and 7 nm or less. The root-mean-square roughness of the unevenness can be 1 nm or more and 10 nm or less. The maximum difference in height of the unevenness can be 5 nm or more and 250 nm or less. That is, the planarized surface of the single crystal semiconductor layer 114 can be obtained by the irradiation process with the laser beam 118.

Chemical mechanical polishing (CMP) is known as planarization treatment. However, it is difficult to perform planarization treatment of the single crystal semiconductor layer 114 by CMP in the case where a mother glass substrate is used as the supporting substrate 102, since the mother glass substrate has a large area and undulation. In this embodiment mode, this planarization treatment is performed by the irradiation process with the laser beam 118; therefore, the single crystal semiconductor layer 114 can be planarized without applying force that damages the supporting substrate 102 and without heating the supporting substrate 102 at a temperature exceeding its strain point.

In irradiation with the laser beam 118, assistant heat treatment may be performed at a temperature which does not cause melting of the single crystal semiconductor layer and is equal to or lower than the strain point of the supporting substrate 102. For example, when irradiation with the laser beam 118 is performed, the single crystal semiconductor layer 114 which is fixed to the supporting substrate 102 is heated or a heated gas is sprayed on the single crystal semiconductor layer 114, whereby the temperature of the single crystal semiconductor layer 114 fixed over the supporting substrate 102 can be increased. By irradiating the single crystal semiconductor layer 114 with the laser beam 118 while the temperature of the single crystal semiconductor layer 114 is increased, the irradiation energy density of the laser beam 118 can be reduced by the assistance effect of the heat treatment. Accordingly, takt time can be shortened and productivity can be increased.

As a laser that emits the laser beam 118, a laser of which emission wavelength is in the range from the ultraviolet region to the visible light region is selected. The wavelength of the laser beam 118 is a wavelength that is absorbed by the single crystal semiconductor layer 114. The wavelength is determined in consideration of the skin depth of the laser beam, and the like. For example, the wavelength of the laser beam 118 can be in the range of equal to or greater than 250 nm and equal to or less than 700 nm.

As the laser that emits the laser beam 118, a continuous wave laser, a quasi continuous wave laser, or a pulsed laser is preferably used. In the case of using the pulsed laser, a repetition rate of 1 MHz or less, and a pulse width of 10 nanoseconds or more and 500 nanoseconds or less are preferable. A typical pulsed laser is an excimer laser that emits a beam having a wavelength of 400 nm or less. For example, as the laser that emits the laser beam 118, a XeCl excimer laser having a repetition rate of 10 Hz to 300 Hz, a pulse width of 25 nanoseconds, and a wavelength of 308 nm can be used.

The energy of the laser beam 118 is determined in consideration of the wavelength of the laser beam 118, the skin depth of the laser beam 118, the thickness of the single crystal semiconductor layer 114, and the like. The irradiation energy density of the laser beam 118 can be set, for example, in the range of 300 mJ/cm² to 800 mJ/cm² inclusive. For example, the irradiation energy density of the laser beam 118 can be 600 mJ/cm² to 700 mJ/cm² in the case where the thickness of the single crystal semiconductor layer 114 is approximately 120 nm, a pulsed laser is used as a laser, and the wavelength of the laser beam 118 is 308 nm.

It is found that the atmosphere in irradiation with the laser beam 118 is effective for planarization of the single crystal semiconductor layer either in the atmosphere without any control or in a nitrogen gas atmosphere that contains a small amount of oxygen. It is also found that a nitrogen atmosphere is more preferable than the air atmosphere. A nitrogen atmosphere and a vacuum state are more effective than the air atmosphere in improving planarity of the single crystal semiconductor layer. In addition, these atmospheres are more effective than the air atmosphere in suppressing surface roughness; therefore, the energy of the laser beam 118 can be selected from a wider range. The oxygen concentration in a nitrogen atmosphere is preferably 30 ppm or less and more preferably 10 ppm or less. In addition, it is preferable that the water (H₂O) concentration in the nitrogen atmosphere be 30 ppm or less. Desirably, the oxygen concentration in the nitrogen atmosphere is 30 ppm or less and the water concentration is 30 ppm or less. For example, in the case where laser beam irradiation is performed in a nitrogen atmosphere whose oxygen concentration is more than 30 ppm, there is a high possibility that reactivity between the single crystal semiconductor layer and oxygen is increased in the vicinity of the laser beam irradiation region and a thin oxide film is formed on a surface of the single crystal semiconductor layer. Since this thin oxide film is preferably removed, a removal step is added. Therefore, when laser beam irradiation is performed in a nitrogen atmosphere in which the oxygen concentration is 30 ppm or less and the water concentration is 30 ppm or less, formation of an unnecessary oxide film can be prevented.

It is preferable that the laser beam 118 pass through an optical system to make energy distribution of the laser beam 118 uniform. Further, it is preferable that a cross section of the laser beam 118 be linear. Accordingly, irradiation with the laser beam 118 can be performed uniformly with high throughput.

Before the single crystal semiconductor layer 114 is irradiated with the laser beam 118, it is preferable that an oxide film, such as a film that is naturally oxidized, which is formed on the surface of the single crystal semiconductor layer 114 be removed. This is because a sufficient planarization effect cannot be obtained when an oxide film remains on the surface of the single crystal semiconductor layer 114. The oxide film can be removed by cleaning the surface of the single crystal semiconductor layer 114 with a hydrofluoric acid. Treatment with a hydrofluoric acid is performed until the surface of the single crystal semiconductor layer 114 becomes water repellent. When the single crystal semiconductor layer 114 has water repellency, it can be checked that the oxide film is removed from the single crystal semiconductor layer 114.

An example of the irradiation step with the laser beam 118 will be described below. First, the single crystal semiconductor layer 114 is treated with a hydrofluoric acid which is diluted at a rate of 1:100 (=hydrofluoric acid: water) for 110 seconds to remove the oxide film on the surface. Next, irradiation with the laser beam 118 is performed. As a laser that emits the laser beam 118, a XeCl excimer laser (with a wavelength of 308 nm, a pulse width of 25 nanoseconds, and a repetition rate of 30 Hz) is used. Through an optical system, a section of the laser beam 118 is formed into a linear shape of 126 mm×0.34 mm. The single crystal semiconductor layer 114 is irradiated with the laser beam 118 under the condition that the scanning speed of the laser beam 118 is 1.0 mm/second, the scanning pitch is 33 μm, and the number of beam shots is approximately 10 shots.

As the treatment for planarization of the single crystal semiconductor layer and reduction of crystal defects thereof, etching treatment may be performed in addition to the laser beam irradiation. For example, etching treatment can be performed before or after the irradiation with the laser beam 118 or both before and after the irradiation with the laser beam 118.

The etching treatment can be performed by one or both of dry etching and wet etching. In the case of dry etching, as the etching gas, a chlorine-based gas such as chlorine, boron chloride, silicon chloride, or carbon tetrachloride; a fluorine-based gas such as fluorine, carbon fluoride, sulfur fluoride, or nitrogen fluoride; a bromine-based gas such as hydrogen bromide; or the like can be used as appropriate. Further, an oxygen gas can also be added as an assistant gas. In the case of wet etching, a TMAH solution or the like can be used as an etchant.

For example, the single crystal semiconductor layer 114 is etched before irradiation of the single crystal semiconductor layer 114 with the laser beam 118. By this etching, a damage layer or separation layer existing on the separation plane of the single crystal semiconductor layer 114 is preferably removed. Specifically, the single crystal semiconductor layer 114 is preferably etched about 20 nm deep in the thickness direction from the surface thereof. Etching of an upper part of the single crystal semiconductor layer 114 before irradiation with the laser beam 118 can enhance the effect of planarizing the surface by following irradiation with the laser beam 118 and the effect of reducing a crystal defect thereof.

Alternatively, after irradiating the single crystal semiconductor layer 114 with the laser beam 118, the re-single-crystallized single crystal semiconductor layer 120 is etched. It is preferable to thin the single crystal semiconductor layer 120 by this etching in accordance with characteristics of the element formed using the single crystal semiconductor layer 120. In order to form a thin gate insulating layer with favorable step coverage on the surface of the single crystal semiconductor layer 120 which is fixed over the supporting substrate 102, the single crystal semiconductor layer 120 preferably has a thickness of 60 nm or less and, specifically, equal to or greater than 5 nm and equal to or less than 60 nm.

In the above-described manner, a semiconductor substrate in which a single crystal semiconductor layer is fixed over a supporting substrate can be obtained.

Since the steps described above can be performed at temperatures of equal to or lower than 700° C., a glass substrate having an allowable temperature limit of 700° C. or lower can be used as the supporting substrate 102. Since an inexpensive glass substrate can be used, the material cost of the semiconductor substrate can be reduced.

Next, a formation method of a semiconductor device using the obtained semiconductor substrate will be described. In this embodiment mode, a manufacturing method of thin film transistors (TFTs) as an example of semiconductor devices will be described. By combining a plurality of thin film transistors, various semiconductor devices can be manufactured. Here, an example of manufacturing an n-channel transistor and a p-channel transistor at the same time will be described.

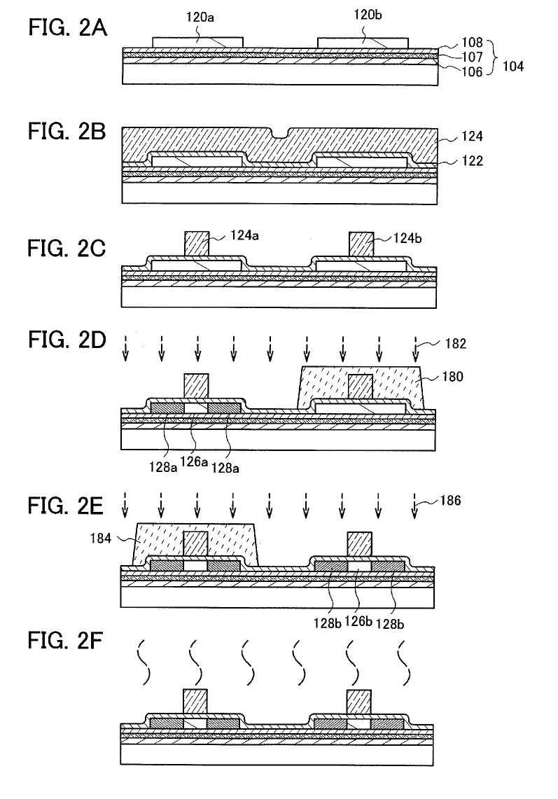

First, the single crystal semiconductor layer 120 is selectively etched to form a single crystal semiconductor layer 120a and a single crystal semiconductor layer 120b which are isolated into island shapes in accordance with arrangement of semiconductor elements (see FIG. 2A). In this embodiment mode, an n-channel transistor is formed using the single crystal semiconductor layer 120a, and a p-channel transistor is formed using the single crystal semiconductor layer 120b. Note that, although element isolation is performed by etching the single crystal semiconductor layer 120 in this embodiment mode for example, the element isolation can also be performed by embedding an insulating layer between single crystal semiconductor layers in accordance with arrangement of semiconductor elements.

Next, a gate insulating layer 122 and a conductive layer 124 for forming gate electrodes are formed in order over the single crystal semiconductor layer 120a and the single crystal semiconductor layer 120b.

The gate insulating layer 122 is formed to have a single-layer structure or a stacked structure using an insulating layer such as a silicon oxide layer, a silicon oxynitride layer, a silicon nitride layer, or a silicon nitride oxide layer by a CVD method, a sputtering method, an ALE method, or the like.

Alternatively, the gate insulating layer 122 may be formed as follows: plasma treatment is performed on the single crystal semiconductor layers 120a and 120b to oxidize or nitride the surfaces thereof. The plasma treatment in this case includes plasma treatment with plasma excited using microwaves (typically, with a frequency of 2.45 GHz). For example, treatment with plasma that is excited by microwaves and has an electron density of 1×10¹¹/cm³ to 1×10¹³/cm³ inclusive and an electron temperature of 0.5 eV to 1.5 eV inclusive is also included. Oxidation treatment or nitridation treatment of the surface of the semiconductor layer with such plasma treatment makes it possible to form a thin and dense film. In addition, because the surface of the single crystal semiconductor layer is directly oxidized or nitrized, an insulating film with good interface characteristics can be obtained. Further alternatively, the gate insulating layer may be formed by performing plasma treatment with microwaves on an insulating film formed by a CVD method, a sputtering method, or an ALE method.

Since the gate insulating layer 122 forms the interface at which channels are formed with the single crystal semiconductor layers, a silicon oxide layer or a silicon oxynitride layer is preferably used for the gate insulating layer 122. This is because, in the case where an insulating film in which the amount of nitrogen is higher than that of oxygen such as a silicon nitride layer or a silicon nitride oxide layer is formed, trap levels might be generated in the interface and the interface characteristics might be degraded.

The conductive layer for forming gate electrodes can be formed using an element selected from tantalum, tungsten, titanium, molybdenum, aluminum, copper, chromium, niobium, or the like, or an alloy material or compound material which contains any of these elements as its main component. As the compound material containing any of the elements as its main component, a nitride is given and, for example, tantalum nitride, tungsten nitride, titanium nitride, molybdenum nitride, aluminum nitride, or the like can be given. Moreover, the conductive layer can also be formed using a semiconductor material typified by polycrystalline silicon doped with an impurity element such as phosphorus. The conductive layer for forming gate electrodes is formed to have a single-layer structure or a stacked structure using any of these materials by a CVD method or a sputtering method. When the conductive layer is formed to have a stacked structure, it can be formed using different conductive materials or can be formed using the same conductive material. In this embodiment mode, an example of forming the conductive layer 124 with a single-layer structure will be described.

Next, the conductive layer 124 is selectively etched to form a gate electrode 124a and a gate electrode 124b. The gate electrode 124a and the gate electrode 124b are formed over the single crystal semiconductor layer 120a and the single crystal semiconductor layer 120b, respectively, with the gate insulating layer 122 interposed therebetween.

Then, in order to form impurity regions which serve as source and drain regions of the n-channel transistor, a resist mask 180 is formed to cover the single crystal semiconductor layer 120b. An impurity element 182 is added into the single crystal semiconductor layer 120a, using the gate electrode 124a and the resist mask 180 as masks. In the single crystal semiconductor layer 120a, a pair of impurity regions 128a and a channel formation region 126a placed between the pair of impurity regions 128a are formed in a self-aligning manner, using the gate electrode 124a as a mask. The impurity regions 128a serve as a source region and a drain region (see FIG. 2D).

As the impurity element 182, an n-type impurity element such as phosphorus or arsenic is added. Here, phosphorus, which is an n-type impurity element, is added to the impurity regions 128a at a concentration of about 5×10¹⁹ atoms/cm³ to 5×10²⁰ atoms/cm³ inclusive.

Then, in order to form impurity regions which serve as source and drain regions of the p-channel transistor, a resist mask 184 is formed to cover the single crystal semiconductor layer 120a. An impurity element 186 is added into the single crystal semiconductor layer 120b, using the gate electrode 124b and the resist mask 184 as masks. In the single crystal semiconductor layer 120b, a pair of impurity regions 128b and a channel formation region 126b placed between the pair of impurity regions 128b are formed in a self-aligning manner, using the gate electrode 124b as a mask. The impurity regions 128b serve as a source region and a drain region (see FIG. 2E).

As the impurity element 186, a p-type impurity element such as boron, aluminum, or gallium is added. Here, boron, which is a p-type impurity element, is added to the impurity regions 128b at a concentration of about 1×10²⁰ atoms/cm³ to 5×10²¹ atoms/cm³ inclusive.

Heat treatment is performed on the single crystal semiconductor layer 120a and the single crystal semiconductor layer 120b (see FIG. 2F). One feature of the present invention is that since removal of crystal defects in the single crystal semiconductor layers and activation of the impurity elements added to the single crystal semiconductor layers are performed at a time, heat treatment is performed at a process temperature which does not cause melting of the single crystal semiconductor layers and which is equal to or higher than 400° C. and equal to or lower than the strain point of the supporting substrate 102. Preferably, the heat treatment is performed at a process temperature of equal to or higher than 450° C. and equal to or lower than 650° C.

By performing heat treatment at a process temperature which does not cause melting of the single crystal semiconductor layers and which is equal to or higher than 400° C. and equal to or lower than the strain point of the supporting substrate 102, carrier lifetime of manufactured transistors can be made longer compared to the case of not performing heat treatment. It is considered that by the heat treatment at a process temperature which does not cause melting of the single crystal semiconductor layers and which is equal to or higher than 400° C. and equal to or lower than the strain point of the supporting substrate 102, defects such as dangling bonds and the interface state of the single crystal semiconductor layers, which cannot be removed by re-single-crystallization which is caused by partially melting the single crystal semiconductor layer by irradiation with the laser beam 118, are removed.

By this heat treatment, the impurity elements added into the single crystal semiconductor layer 120a and the single crystal semiconductor layer 120b are activated. Specifically, dopants contained in the impurity regions 128a and 128b which serve as source regions and drain regions are activated. Activation of the impurity elements added into the single crystal semiconductor layers is an important process to lower resistance of the regions which serve as source regions and drain regions. Note that the above-described heat treatment can remove a crystal defect in the source regions or drain regions, which is generated by addition of the impurity elements to form the impurity regions 128a and 128b.

Here, “lifetime” means average time, from generation of carriers in a semiconductor to decay of the carriers caused by recombination. For example, by irradiating a semiconductor (silicon) with light, electrons and holes (carriers) are generated in the semiconductor. The generated electrons and holes recombine to decay each other in time. In this manner, the average time from generation of carriers to decay of the carriers caused by recombination is called “lifetime.” Note that the “lifetime” is also called “recombination lifetime” or “carrier lifetime.”

The lifetime is shortened by the existence of a macro crystal defect such as lattice distortion or a lattice defect in a semiconductor, a micro crystal defect such as dangling bonds or traps at an interface, a metal impurity, and the like which serve as recombination center of carriers. That is, improvement in lifetime means improvement in carrier mobility, and can improve electric characteristics (high-speed operation or the like) of a manufactured transistor.

Thus, by performing heat treatment at a process temperature which does not cause melting of the single crystal semiconductor layers and which is equal to or higher than 400° C. and equal to or lower than the strain point of the supporting substrate 102 as in the present invention, lifetime of single crystal semiconductor layers in which channels are formed is improved and, furthermore, resistance of the single crystal semiconductor layers in which source regions and drain regions are formed can be lowered and a crystal defect caused by impurity addition in the source regions and the drain regions can be removed. Accordingly, transistors with excellent electric characteristics can be manufactured.

By performing heat treatment at a process temperature which does not cause melting of single crystal semiconductor layers and which is equal to or higher than 400° C. and equal to or lower than the strain point of the supporting substrate 102 after formation of impurity regions serving as source regions and drain regions as in the present invention, recovery of characteristics of channel formation regions and activation of the impurity regions can be performed by the single heat treatment step. Accordingly, the process can be simplified, thereby improving throughput.

Furthermore, by performing heat treatment after single crystal semiconductor layers are selectively etched to be patterned in accordance with arrangement of desired semiconductor elements as in the present invention, the area and volume of the single crystal semiconductor layers are reduced; accordingly, stress, particularly stress such as thermal stress, applied to each of the single crystal semiconductor layers can be reduced. In other words, film stress applied on the single crystal semiconductor layer can be relaxed when the single crystal semiconductor layer is patterned into, for example, island shapes to be segmented. Therefore, damage of the single crystal semiconductor layers due to film stress can be prevented, and field-effect transistors having favorable electric characteristics can be manufactured with high yield.

In the case where the gate electrodes 124a and 124b are formed using a material which is easily oxidized, it is preferable to perform heat treatment illustrated in FIG. 2F after formation of an insulating layer which covers the gate electrodes 124a and 124b.

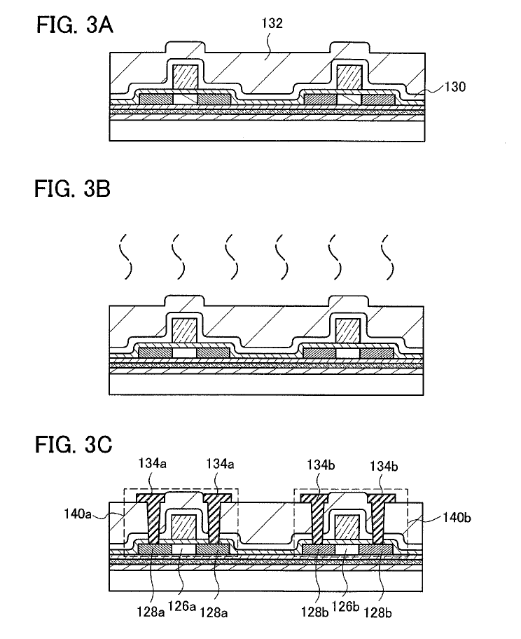

Next, an interlayer insulating layer is formed (see FIG. 3A). The interlayer insulating layer can be formed to have a single-layer structure or a stacked structure of two or more layers. Here, an example where the interlayer insulating layer has a two-layer structure of a first interlayer insulating layer 130 and a second interlayer insulating layer 132 as illustrated in FIG. 3A will be described.

As the interlayer insulating layer, a silicon oxide layer, a silicon oxynitride layer, a silicon nitride layer, a silicon nitride oxide layer, or the like can be formed by a CVD method or a sputtering method. Further, the interlayer insulating layer can also be formed by an application method such as a spin coating method, using an organic material such as polyimide, polyamide, polyvinylphenol, benzocyclobutene, acrylic, or epoxy, a siloxane material such as a siloxane resin, an oxazole resin, or the like. A siloxane material is a material including a Si—O—Si bond. Siloxane has a skeletal structure formed from a bond of silicon (Si) and oxygen (O). An organic group (e.g., an alkyl group or an aromatic hydrocarbon) or a fluoro group can be given as the substituent. The organic group may include a fluoro group. An oxazole resin is a photosensitive polybenzoxazole or the like, for example. Photosensitive polybenzoxazole is a material which has a low dielectric constant (a dielectric constant of 2.9 at 1 MHz at room temperature), high heat resistance (according to results of thermogravimetry-differential thermal analysis (TG-DTA), it has a thermal decomposition temperature of 550° C. at a rate of temperature increase of 5° C./min), and a low water absorption coefficient (0.3 wt % at room temperature for 24 hours). Since an oxazole resin has a lower dielectric constant (approximately 2.9) as compared to a dielectric constant of polyimide (approximately 3.2 to 3.4) or the like, the generation of parasitic capacitance can be suppressed and operation at high speed is possible.

After forming an insulating layer containing hydrogen as the interlayer insulating layer, heat treatment is preferably performed to hydrogenate the single crystal semiconductor layers (see FIG. 3B).

In this embodiment mode, as the first interlayer insulating layer 130 stacked over the gate insulating layer 122, an insulating layer containing hydrogen is formed. The insulating layer containing hydrogen can be formed by a plasma CVD method using a process gas which contains hydrogen. After forming the insulating layer containing hydrogen, heat treatment is performed at 350° C. or higher and 450° C. or lower, and preferably 400° C. or higher and 430° C. or lower; accordingly, dangling bonds in the single crystal semiconductor layer 120a and the single crystal semiconductor layer 120b can be terminated with hydrogen. Specifically, hydrogen contained in the first interlayer insulating layer 130 is thermally excited by the heat treatment and diffused; accordingly, the hydrogen passes through the gate insulating layer 122 and reaches the single crystal semiconductor layer 120a and the single crystal semiconductor layer 120b. Then, dangling bonds in the single crystal semiconductor layer 120a and the single crystal semiconductor layer 120b are terminated with the hydrogen. Thus, electric characteristics of transistors can be improved.

The heat treatment which causes hydrogen termination utilizing the first interlayer insulating layer 130 (insulating layer containing hydrogen) can be performed after formation of the second interlayer insulating layer 132. In such a case, the second interlayer insulating layer 132 is preferably formed at a temperature which does not cause dehydrogenation of the first interlayer insulating layer 130.

For example, as the first interlayer insulating layer 130, a silicon nitride oxide layer is formed by a plasma CVD method using monosilane, ammonia, hydrogen, and nitrogen oxide for a process gas, and as the second interlayer insulating layer 132, a silicon oxynitride layer is formed. At this time, the first interlayer insulating layer 130 and the second interlayer insulating layer 132 are formed at process temperatures in the range of equal to or higher than 200° C. and equal to or lower than 300° C. Then, heat treatment is performed at 410° C. in a nitrogen atmosphere for one hour after formation of the second interlayer insulating layer 132, which causes diffusion of hydrogen contained in the silicon nitride oxide layer; accordingly, the single crystal semiconductor layers can be terminated with hydrogen.

Next, contact holes are formed in the interlayer insulating layer (in this embodiment mode, the first interlayer insulating layer 130 and the second interlayer insulating layer 132) and then, a conductive layer 134a and a conductive layer 134b are formed in the contact holes (see FIG. 3C).

In the interlayer insulating layer, the contact holes which reach the source regions and drain regions formed in the single crystal semiconductor layers are formed. Here, contact holes which reach the impurity regions 128a formed in the single crystal semiconductor layer 120a and contact holes which reach the impurity regions 128b formed in the single crystal semiconductor layer 120b are formed. The conductive layer 134a functions as a source electrode and a drain electrode and is electrically connected to the impurity regions 128a formed in the single crystal semiconductor layer 120a through the contact holes formed in the first interlayer insulating layer 130 and the second interlayer insulating layer 132. Similarly, the conductive layer 134b functions as a source electrode and a drain electrode and is electrically connected to the impurity regions 128b formed in the single crystal semiconductor layer 120b through the contact holes formed in the first interlayer insulating layer 130 and the second interlayer insulating layer 132.

The conductive layer 134a and the conductive layer 134b can be formed using an element selected from aluminum, tungsten, titanium, tantalum, molybdenum, nickel, neodymium, or the like, or an alloy material or compound material which contains any of these elements. As the alloy material containing any of the elements, an aluminum alloy, an aluminum alloy containing silicon, an aluminum alloy containing titanium, an aluminum alloy containing neodymium, or the like can be used. As the compound material containing any of the elements, a nitride of any of the elements, specifically, titanium nitride, tungsten nitride, tantalum nitride, molybdenum nitride, or the like can be given. The conductive layer 134a and the conductive layer 134b which function as the source electrodes and the drain electrodes may be formed over the entire surface by forming a layer using the aforementioned material by a sputtering method or a CVD method and then may be formed into a desired shape by selective etching. The conductive layer 134a and the conductive layer 134b can be formed to have a single-layer structure or a stacked structure of two or more layers and, for example, a structure in which a titanium layer, an aluminum layer or an aluminum alloy layer over the titanium layer, and a titanium layer over the aluminum layer or the aluminum alloy layer are sequentially stacked can be employed. By forming a titanium nitride layer between the titanium layer and the aluminum layer or the aluminum alloy layer, diffusion of aluminum or the like can be prevented.

In the above-described manner, an n-channel transistor 140a and a p-channel transistor 140b are formed. The transistor 140a includes the single crystal semiconductor layer 120a in which a channel is formed. The transistor 140b includes the single crystal semiconductor layer 120b in which a channel is formed. Therefore, high carrier mobility can be obtained, and the transistors can operate at high speed. In addition, since the single crystal semiconductor has almost uniform crystal orientation, variation in characteristics of the transistors can be reduced compared to the case of using a polycrystalline semiconductor. Further, in the present invention, in order to obtain the single crystal semiconductor layers 120a and 120b having superior characteristics, laser beam irradiation is performed in manufacture of the semiconductor substrate so as to re-single-crystallize the single crystal semiconductor layer. Furthermore, by performing heat treatment after patterning the single crystal semiconductor layer and forming the impurity regions serving as source regions and drain regions, the lifetime of the single crystal semiconductor layers in which channels are formed can be improved. Therefore, high-performance transistors can be provided with high yield.

Before patterning the single crystal semiconductor layer of the semiconductor substrate by selective etching, a p-type impurity element or an n-type impurity element may be added into the single crystal semiconductor layer in accordance with a formation region of an n-channel transistor or a p-channel transistor. For example, a p-type impurity element is added to a formation region of an n-channel transistor and an n-type impurity element is added to a formation region of a p-channel transistor, whereby so-called “well regions” are formed. The impurity element may be added at a dose of approximately 1×10¹² ions/cm² to 1×10¹⁴ ions/cm². As the p-type impurity element, boron, aluminum, gallium, or the like may be added, and as the n-type impurity element, phosphorus, arsenic, or the like may be added.

Before forming the gate electrodes over the single crystal semiconductor layers, an impurity element may be added into a channel formation region for the purpose of controlling the threshold voltage of the transistor. For example, a p-type impurity element may be added in the case of forming an n-channel transistor, and an n-type impurity element may be added in the case of forming a p-channel transistor. Such addition of an impurity element into a channel formation region is referred to as “channel doping.” In the case of performing channel doping, a “well region” may be or may not be formed. After the channel doping, heat treatment is preferably performed to activate the impurity element added into the channel formation region. It is preferable that the heat treatment be performed at a process temperature which does not cause melting of the single crystal semiconductor layers and which is equal to or higher than 400° C. and equal to or lower than the strain point of the supporting substrate, because a micro crystal defect of the single crystal semiconductor layers in which channels are formed can be reduced. Note that the heat treatment may be performed after channel doping and before formation of gate electrodes or may be performed after formation of impurity regions serving as source regions and drain regions also as heat treatment for activation.

Although the semiconductor device in which the n-channel transistor and the p-channel transistor are manufactured at the same time has been described in this embodiment mode, the structure of transistors described in this embodiment mode is only an example and the present invention is not limited to the structure illustrated in the drawings.

Note that this embodiment mode can be implemented in combination with any of other embodiment modes described in this specification as appropriate.

### Embodiment Mode 2

In Embodiment Mode 2, a semiconductor substrate having another structure, which can be used for manufacture of a semiconductor device according to the present invention, will be described.

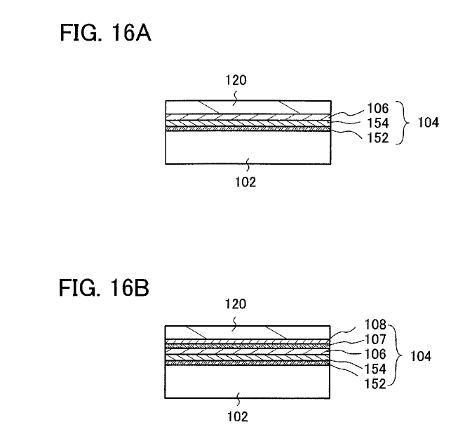

FIG. 16A illustrates an example in which the buffer layer 104 is formed on the supporting substrate 102. Between the single crystal semiconductor layer 120 and the supporting substrate 102, the insulating layer 106, an insulating layer 154, and an insulating layer 152 are formed from the single crystal semiconductor layer 120, and the stacked structure of these layers forms the buffer layer 104.

The insulating layer 152 may be an insulating layer similar to the insulating layer 107 and preferably includes at least one layer of insulating layer containing nitrogen. For example, at least one layer of insulating layer containing nitrogen as its composition such as a silicon nitride layer, a silicon nitride oxide layer, or an aluminum nitride layer is formed. When the insulating layer 152 is formed, a metal impurity can be prevented from diffusing into the single crystal semiconductor layer 120 from the supporting substrate 102.

As the insulating layer 154, an insulating layer similar to the insulating layer 106 may be formed, and an insulating layer which has smoothness and can form a hydrophilic surface is preferably formed. When the insulating layer 154 is provided on the supporting substrate 102 and bonding is performed between the insulating layer 154 and the insulating layer 106, bonding strength between the single crystal semiconductor layer 120 and the supporting substrate 102 can be increased. Note that an insulating layer containing nitrogen may serve as both a layer which blocks diffusion of a metal impurity and a bonding layer.

The thicknesses of the insulating layer 152 and the insulating layer 154 may be set as appropriate. The thickness of the insulating layer 152 is preferably 10 nm to 500 nm, and the thickness of the insulating layer 154 is preferably about 0.2 nm to 500 nm (in the case of forming the insulating layer 154 by a CVD method, about 10 nm to 500 nm).

FIG. 16B illustrates an example in which the insulating layer 108, the insulating layer 107, and the insulating layer 106 are formed on the single crystal semiconductor layer 120, and the insulating layer 152 and the insulating layer 154 are formed on the supporting substrate 102. Between the single crystal semiconductor layer 120 and the supporting substrate 102, the insulating layer 108, the insulating layer 107, the insulating layer 106, the insulating layer 154, and the insulating layer 152 are formed from the single crystal semiconductor layer 120 side, and the stacked structure of these layers forms the buffer layer 104.

The semiconductor substrate for manufacturing a semiconductor device according to the present invention can also have either of the structures illustrated in FIG. 16A and FIG. 16B. The single crystal semiconductor layer 120 is a semiconductor layer part of which is re-single-crystallized through melting by laser beam irradiation treatment. Using the semiconductor substrate described in this embodiment mode, various semiconductor devices can be manufactured.

Note that this embodiment mode can be implemented in combination with any of other embodiment modes described in this specification as appropriate.

### Embodiment Mode 3

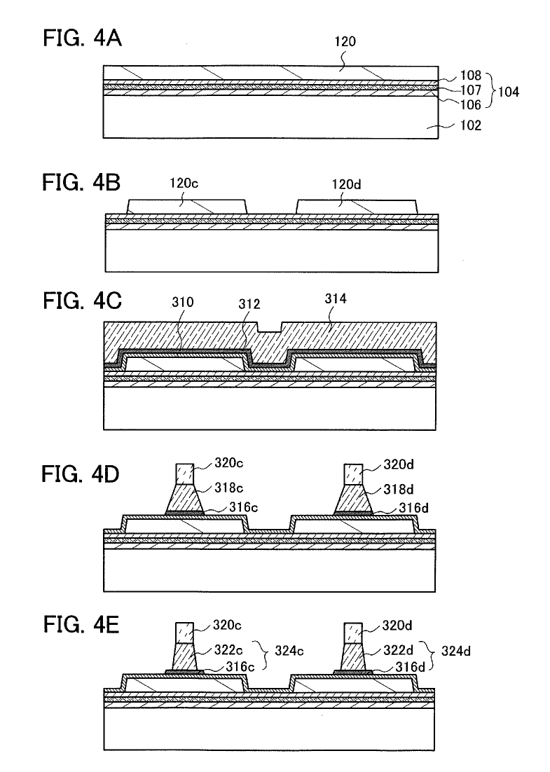

In Embodiment Mode 3, transistors having a different structure from the above embodiment mode and a manufacturing method thereof will be described. Hereinafter, description is made with reference to the cross sectional views of FIGS. 4A to 4E, FIGS. 5A to 5D, and FIGS. 6A to 6C. Note that a method of manufacturing an n-channel transistor and a p-channel transistor at the same time will be described in this embodiment mode.

First, as illustrated in FIG. 4A, a semiconductor substrate is prepared. In this embodiment mode, the semiconductor substrate manufactured through the steps of FIGS. 1A to 1E in Embodiment Mode 1 is used. In other words, the semiconductor substrate in which the single crystal semiconductor layer 120 is fixed over the supporting substrate 102 with the buffer layer 104 interposed therebetween is used. The single crystal semiconductor layer 120 is a semiconductor layer part of which is re-single-crystallized through melting by laser beam irradiation. Note that the semiconductor substrate used in this embodiment mode is not limited to the semiconductor substrate having the structure illustrated in FIG. 4A, and a semiconductor substrate according to the present invention can be employed.

A p-type impurity element such as boron, aluminum, or gallium and an n-type impurity element such as phosphorus or arsenic are preferably added into the single crystal semiconductor layer 120 in accordance with formation regions of an n-channel field-effect transistor and a p-channel field-effect transistor. In other words, a p-type impurity element is added into a formation region of an n-channel field-effect transistor and an n-type impurity element is added into a formation region of a p-channel field-effect transistor, whereby so-called well regions are formed. The dose of impurity ions may be approximately equal to or greater than 1×10¹² ions/cm² and equal to or less than 1×10¹⁴ ions/cm². Furthermore, in the case of controlling the threshold voltage of the field-effect transistor, a p-type or n-type impurity element may be added into the well region.

Then, as illustrated in FIG. 4B, the single crystal semiconductor layer 120 is etched to form a single crystal semiconductor layer 120c and a single crystal semiconductor layer 120d which are isolated in island shapes from each other in accordance with arrangement of semiconductor elements. In this embodiment mode, an n-channel transistor is formed using the single crystal semiconductor layer 120c, and a p-channel transistor is formed using the single crystal semiconductor layer 120d.

Next, as illustrated in FIG. 4C, a gate insulating layer 310, a conductive layer 312 for forming gate electrodes, and a conductive layer 314 are formed in order over the single crystal semiconductor layer 120c and the single crystal semiconductor layer 120d.

The gate insulating layer 310 is formed to have a single-layer structure or a stacked structure using an insulating layer such as a silicon oxide layer, a silicon oxynitride layer, a silicon nitride layer, or a silicon nitride oxide layer by a CVD method, a sputtering method, an ALE method, or the like.

Alternatively, the gate insulating layer 310 may be formed as follows: plasma treatment is performed on the single crystal semiconductor layers 120c and 120d to oxidize or nitride the surfaces thereof. The plasma treatment in this case includes plasma treatment with plasma excited using microwaves (typically, with a frequency of 2.45 GHz). For example, treatment with plasma that is excited by microwaves and has an electron density of 1×10¹¹/cm³ to 1×10¹³/cm³ inclusive and an electron temperature of 0.5 eV to 1.5 eV inclusive is also included. Oxidation treatment or nitridation treatment of the surface of the semiconductor layer with such plasma treatment makes it possible to form a thin and dense film. In addition, because the surface of the semiconductor layer is directly oxidized, an insulating film with good interface characteristics can be obtained. Further alternatively, the gate insulating layer 310 may be formed by performing plasma treatment with microwaves on an insulating film formed by a CVD method, a sputtering method, or an ALE method.

Since the gate insulating layer 310 forms the interface with the single crystal semiconductor layers at which channels are formed, a silicon oxide layer or a silicon oxynitride layer is preferably used for the gate insulating layer 310. This is because, in the case where an insulating film in which the amount of nitrogen is higher than that of oxygen such as a silicon nitride layer or a silicon nitride oxide layer is formed, trap levels might be generated in the interface and the interface characteristics might be degraded.

The conductive layer for forming gate electrodes is formed as a single-layer film or a stacked-layer film using an element selected from tantalum, tantalum nitride, tungsten, titanium, molybdenum, aluminum, copper, chromium, or niobium, an alloy material or a compound material containing the element as its main component, or a semiconductor material typified by polycrystalline silicon doped with an impurity element such as phosphorus, by a CVD method or a sputtering method. In the case where the conductive layer has a stacked structure, the stacked layers can be formed using various conductive materials or one conductive material. In this embodiment mode, an example in which the conductive layer for forming gate electrodes is formed to have a two-layer structure of the conductive layer 312 and the conductive layer 314, is described.

If the conductive layer for forming gate electrodes has a two-layer structure of the conductive layer 312 and the conductive layer 314, a stacked film of a tantalum nitride layer and a tungsten layer, a tungsten nitride layer and a tungsten layer, or a molybdenum nitride layer and a molybdenum layer can be formed, for example. A stacked film of a tantalum nitride layer and a tungsten layer is preferable for the stacked film because the difference of etching rate between the tantalum nitride layer and the tungsten layer is large and high selectively etching can be performed. Note that in the two-layer films which are exemplified, the first mentioned layer is preferably formed over the gate insulating layer 310. Here, the conductive layer 312 is formed with a thickness of 20 nm to 100 nm inclusive. The conductive layer 314 is formed with a thickness of 100 nm to 400 nm inclusive. The gate electrode can also have a stacked structure of three or more layers; in that case, a stacked structure of a molybdenum layer, an aluminum layer, and a molybdenum layer may be employed.

Next, a resist mask 320c and a resist mask 320d are selectively formed over the conductive layer 314. Then, first etching treatment and second etching treatment are performed using the resist masks 320c and 320d, respectively.

First, by using the first etching treatment using the resist masks 320c and 320d, the conductive layers 312 and 314 are selectively etched, and thus a conductive layer 316c and a conductive layer 318c are formed over the single crystal semiconductor layer 120c, and a conductive layer 316d and a conductive layer 318d are formed over the single crystal semiconductor layer 120d (see FIG. 4D).

Next, by the second etching treatment using the resist masks 320c and 320d, end portions of the conductive layers 318c and 318d are etched, and thus a conductive layer 322c and a conductive layer 322d are formed (see FIG. 4E). The conductive layers 322c and 322d are formed so as to have smaller widths (lengths parallel to a direction in which carriers flow through channel formation regions (a direction in which a source region and a drain region are connected)) than those of the conductive layers 316c and 316d. In this manner, a gate electrode 324c having a two-layer structure of the conductive layers 316c and 322c and a gate electrode 324d having a two-layer structure of the conductive layers 316d and 322d are formed.

An etching method employed for the first etching treatment and the second etching treatment may be selected as appropriate. In order to increase etching rate, it is preferable to use a dry etching apparatus using a high-density plasma source such as an electron cyclotron resonance (ECR) source or an inductively coupled plasma (ICP) source. With appropriate control of the etching conditions (power applied to a coiled electrode, power applied to an electrode on the substrate side, the temperature of the electrode on the substrate side, and the like) of the first etching treatment and the second etching treatment, side surfaces of the conductive layers 316c and 316d and the conductive layers 322c and 322d can each have a desired tapered shape. The resist masks 320c and 320d may be removed after the desired gate electrodes 324c and 324d are formed.

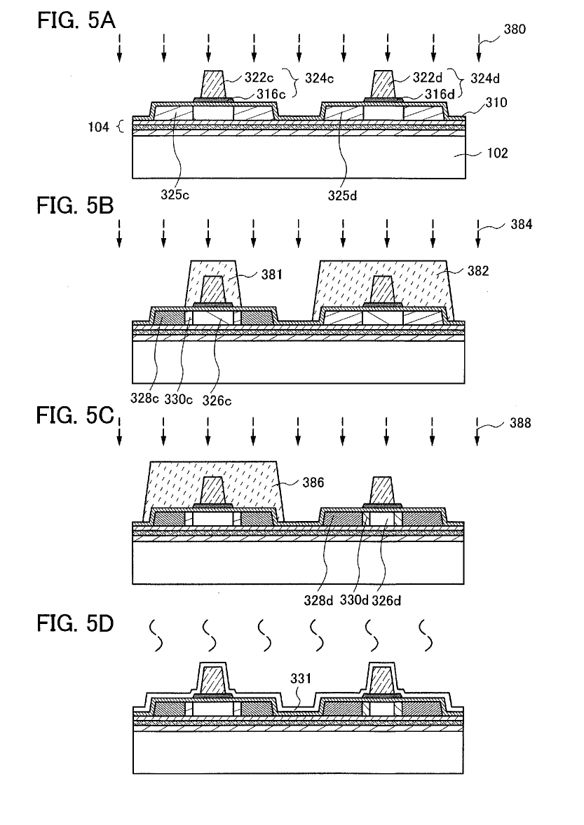

Next, an impurity element 380 is added into the single crystal semiconductor layers 120c and 120d using the gate electrodes 324c and 324d as masks. In the single crystal semiconductor layer 120c, a pair of first impurity regions 325c are formed in a self-aligning manner using the conductive layer 316c and the conductive layer 322c as masks. In the single crystal semiconductor layer 120d, a pair of first impurity regions 325d are formed in a self-aligning manner using the conductive layer 316d and the conductive layer 322d as masks (see FIG 5A).

As the impurity element 380, a p-type impurity element such as boron, aluminum, or gallium or an n-type impurity element such as phosphorus or arsenic is added. Here, in order to form a high-resistant region serving as an LDD region of the n-channel transistor, phosphorus which is an n-type impurity element is added as the impurity element 380. In addition, phosphorus is added so that it is contained in the first impurity regions 325c at a concentration of about 1×10¹⁷ atoms/cm³ to 5×10¹⁸ atoms/cm³.

Then, in order to form impurity regions which serve as source and drain regions of the n-channel transistor, a resist mask 381 is formed to partially cover the single crystal semiconductor layer 120c, and a resist mask 382 is selectively formed to cover the single crystal semiconductor layer 120d. Then, an impurity element 384 is added into the single crystal semiconductor layer 120c using the resist masks 381 and 382 as masks to form a pair of second impurity regions 328c, a pair of third impurity regions 330c, and a channel formation region 326c in the single crystal semiconductor layer 120c (see FIG. 5B).

As the impurity element 384, phosphorus which is an n-type impurity element is added into the single crystal semiconductor layer 120c so that phosphorus is added at a concentration of 5×10¹⁹ atoms/cm³ to 5×10²⁰ atoms/cm³. The second impurity regions 328c serve as a source region and a drain region. The second impurity regions 328c are formed in regions that overlap with neither the conductive layer 316c nor the conductive layer 322c.

The third impurity regions 330c in the single crystal semiconductor layer 120c are part of the first impurity regions 325c to which the impurity element 384 is not added. The third impurity regions 330c have a lower impurity concentration than the second impurity regions 328c and function as high-resistant regions or LDD regions. In a region of the single crystal semiconductor layer 120c which overlaps with both the conductive layer 316c and the conductive layer 322c, the channel formation region 326c is formed.

An LDD region means a region to which an impurity element is added at a low concentration and which is formed between a channel formation region and a source or drain region that is formed by adding the impurity element at a high concentration. Formation of an LDD region has an effect of suppressing an electric field near a drain region, thereby preventing deterioration due to hot carrier injection. Further, a structure in which an LDD region overlaps with a gate electrode with a gate insulating layer interposed therebetween (also called a “Gate OverLapped Drain (GOLD) structure”) may also be employed in order to prevent reduction of an on-current value due to hot carrier.

Next, after the resist masks 381 and 382 are removed, a resist mask 386 is formed to cover the single crystal semiconductor layer 120c in order to form a source region and a drain region of a p-channel transistor. An impurity element 388 is added using the resist mask 386, the conductive layer 316d, and the conductive layer 322d as masks, whereby a pair of second impurity regions 328d, a pair of third impurity regions 330d, and a channel formation region 326d are formed in the single crystal semiconductor layer 120d (see FIG. 5C).

As the impurity element 388, a p-type impurity element such as boron, aluminum, or gallium is used. Here, boron that is a p-type impurity element is added to the second impurity regions 328d at a concentration of about 1×10²⁰ atoms/cm³ to 5×10²¹ atoms/cm³ inclusive.

In the single crystal semiconductor layer 120d, the second impurity regions 328d are formed in regions that overlap with neither the conductive layer 316d nor the conductive layer 322d, and function as a source region and a drain region.

The third impurity regions 330d are formed in regions which overlap with the conductive layer 316d and do not overlap with the conductive layer 322d, and the third impurity regions 330d are regions formed by adding the impurity element 388 into the first impurity regions 325d through the conductive layer 316d. Since the first impurity regions 325d have n-type conductivity, the impurity element 388 is added so that the third impurity regions 330d have p-type conductivity. By control of the concentration of the impurity element 388 contained in the third impurity regions 330d, the third impurity regions 330d can each be made to serve as a source region or a drain region or to serve as an LDD region.

In a region of the single crystal semiconductor layer 120d which overlaps with both the conductive layer 316d and the conductive layer 322d, the channel formation region 326d is formed.

Next, after removing the resist mask 386, heat treatment is performed at a process temperature which does not cause melting of the single crystal semiconductor layer 120c and the single crystal semiconductor layer 120d and which is equal to or higher than 400° C. and equal to or lower than the strain point of the supporting substrate 102 (see FIG. 5D).

By this heat treatment, a micro crystal defect of the channel formation region 326c formed in the single crystal semiconductor layer 120c is removed and, in addition, the second impurity regions 328c serving as a source region and a drain region are activated (reduced in resistance). Furthermore, by this heat treatment, the third impurity regions 330c each serving as an LDD region are activated (reduced in resistance). At the same time, a micro crystal defect of the channel formation region 326d formed in the single crystal semiconductor layer 120d is removed and, in addition, the second impurity regions 328d serving as a source region and a drain region and the third impurity regions 330d are activated (reduced in resistance). The process temperature of the heat treatment is preferably equal to or higher than 450° C. and equal to or lower than 650° C.

According to one feature of a manufacturing method of a semiconductor device of the present invention, a single crystal silicon layer is planarized by laser beam irradiation in manufacture of a semiconductor substrate. In addition, after isolating the single crystal silicon layer in accordance with arrangement of desired semiconductor elements and forming impurity regions serving as a source region and a drain region in each of the isolated single crystal silicon layers, heat treatment is performed at a process temperature which does not cause melting of the single crystal silicon layers and which is equal to or higher than 400° C. and equal to or lower than the strain point of the supporting substrate 102. By performing the heat treatment at a process temperature in the above-described range, carrier lifetime in channels of manufactured transistors can be improved compared to the case of not performing the heat treatment. Further, by performing the above-described beat treatment with such a process temperature after formation of the source regions and the drain regions, recovery of characteristics of channel formation regions and activation of the impurity regions serving as the source regions and the drain regions can be performed by the single heat treatment step. Accordingly, the process can be simplified, thereby improving throughput. Furthermore, by performing heat treatment after isolating and segmenting the single crystal semiconductor layer in accordance with arrangement of desired semiconductor elements, film stress can be relaxed and damage of the single crystal semiconductor layers due to film stress can be prevented. Thus, transistors having favorable electric characteristics can be manufactured with high yield and high productivity.

Heat treatment for activation of the third impurity regions 330c and the third impurity regions 330d serving as LDD regions may be performed in a different step. By such heat treatment, recovery of characteristics of channel formation regions and activation of the impurity regions serving as the LDD regions may be performed. For example, after addition of the impurity element 380 as illustrated in FIG. 5A in this embodiment mode, heat treatment may be performed at a process temperature which does not cause melting of the single crystal semiconductor layers and which is equal to or higher than 400° C. and equal to or lower than the strain point of the supporting substrate 102. In this case, after formation of the impurity regions serving as the source regions and the drain regions, the process temperature of heat treatment can be determined in consideration of only the activation of the source regions and the drain regions.

In this embodiment mode, after formation of an insulating layer 331 which covers the gate electrodes 324c and 324d, heat treatment is performed at a process temperature which does not cause melting of the single crystal semiconductor layers and which is equal to or higher than 400° C. and equal to or lower than the strain point of the supporting substrate 102. Performing heat treatment after formation of the insulating layer 331 is preferable since oxidation of the gate electrodes by the heat treatment can be prevented. As the insulating layer 331, a silicon oxide layer, a silicon oxynitride layer, a silicon nitride layer, a silicon nitride oxide layer, or the like may be formed by a CVD method or a sputtering method. For example, in this embodiment mode, a silicon oxynitride layer with a thickness of 50 nm is formed by a plasma CVD method as the insulating layer 331. Further, by controlling the atmosphere in the heat treatment, oxidation of the gate electrodes can be prevented. In such a case, the insulating layer 331 is not formed or may be formed after the heat treatment.

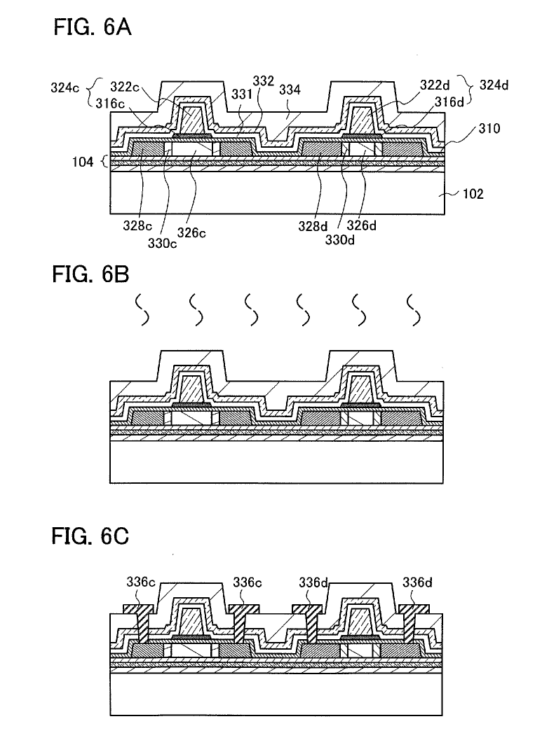

Next, an interlayer insulating layer is formed. The interlayer insulating layer can be formed to have a single-layer structure or a stacked structure. Here, the interlayer insulating layer has a two-layer structure of an insulating layer 332 and an insulating layer 334 (see FIG. 6A).

As the interlayer insulating layer, a silicon oxide layer, a silicon oxynitride layer, a silicon nitride layer, a silicon nitride oxide layer, or the like can be formed by a CVD method or a sputtering method. Further, the interlayer insulating layer can also be formed by an application method such as a spin coating method, using an organic material such as polyimide, polyamide, polyvinylphenol, benzocyclobutene, acrylic, or epoxy, a siloxane material such as a siloxane resin, an oxazole resin, or the like. It is to be noted that a siloxane material is a material including a Si—O—Si bond. Siloxane has a skeletal structure formed from a bond of silicon (Si) and oxygen (O). An organic group (e.g., an alkyl group or an aromatic hydrocarbon) or a fluoro group can be given as the substituent. The organic group may include a fluoro group.

It is preferable that at least one layer in the interlayer insulating layer be an insulating layer containing hydrogen, and dangling bonds existing in the single crystal semiconductor layers be terminated with the hydrogen by heat treatment (see FIG. 6B). The heat treatment temperature is preferably equal to or higher than 350° C. and equal to or lower than 450° C., and more preferably equal to or higher than 400° C. and equal to or lower than 430° C. When heat treatment at a process temperature of 350° C. or higher and 450° C. or lower, preferably 400° C. or higher and 430° C. or lower is performed after formation of the insulating layer containing hydrogen serving as the interlayer insulating layer, hydrogen contained in the insulating layer is thermally excited by the heat treatment and diffused; accordingly, the hydrogen passes through the insulating layers such as the interlayer insulating layer and the gate insulating layer and reaches the single crystal semiconductor layers. Then, dangling bonds in the single crystal semiconductor layers are terminated with the hydrogen. Since dangling bonds in a semiconductor layer, particularly in a channel formation region adversely affect electric characteristics of a manufactured transistor, hydrogen termination as in this embodiment mode is effective. Although micro crystal defects in the single crystal semiconductor layer 120c and the single crystal semiconductor layer 120d are reduced by heat treatment after formation of the second impurity regions 328c and 328d serving as the source regions and the drain regions, hydrogen termination can improve electric characteristics of manufactured transistors. In particular, hydrogen termination can improve interface characteristics between the gate insulating layer and the single crystal semiconductor layers.

The insulating layer containing hydrogen can be formed by a plasma CVD method using a process gas which contains hydrogen. Even when the insulating layer containing hydrogen is not formed, heat treatment performed in an atmosphere containing hydrogen enables termination of dangling bonds in the single crystal semiconductor layers with hydrogen. In this embodiment mode, an insulating layer containing hydrogen is formed as the insulating layer 332, an insulating layer 334 is formed thereover, and then heat treatment for hydrogen termination is performed. In this case, the insulating layer 334 is formed at a temperature which does not cause dehydrogenation of the insulating layer 332.

For example, in this embodiment mode, a silicon nitride oxide layer (thickness: 100 nm) as the insulating layer 332 and a silicon oxynitride layer (thickness: 600 nm) as the insulating layer 334 are sequentially formed by a plasma CVD method. As a process gas for forming the silicon nitride oxide layer, monosilane, ammonia, hydrogen, and nitrogen oxide are used. As a process gas for forming the silicon oxynitride layer, monosilane and nitrogen oxide are used. When the process temperature is approximately 200° C. to 300° C., the interlayer insulating layer can be formed without dehydrogenation of the silicon nitride oxide layer. Then, after formation of the interlayer insulating layer, heat treatment is performed at 410° C. in a nitrogen atmosphere for one hour, thereby terminating the single crystal semiconductor layers with hydrogen.

Next, contact holes are formed in the interlayer insulating layer (the insulating layer 334 and the insulating layer 332), the insulating layer 331, and the gate insulating layer 310. Then, a conductive layer 336c and a conductive layer 336d serving as source electrodes and drain electrodes are formed in the contact holes (see FIG. 6C).

The contact holes are selectively formed in the insulating layer 334, the insulating layer 332, the insulating layer 331, and the gate insulating layer 310 so as to reach the second impurity regions 328c that are formed in the single crystal semiconductor layer 120c and the second impurity regions 328d that are formed in the single crystal semiconductor layer 120d. The conductive layer 336c functions as a source electrode and a drain electrode and is electrically connected to the second impurity regions 328c that serve as the source region and the drain region through the contact holes formed in the insulating layers (here, the insulating layer 334, the insulating layer 332, the insulating layer 331, and the gate insulating layer 310). Similarly, the conductive layer 336b functions as a source electrode and a drain electrode and is electrically connected to the second impurity regions 328d that serve as the source region and the drain region through the contact holes formed in the insulating layers (here, the insulating layer 334, the insulating layer 332, the insulating layer 331, and the gate insulating layer 310).

The conductive layer 336c and the conductive layer 336d can be formed using an element selected from aluminum, tungsten, titanium, tantalum, molybdenum, nickel, neodymium, or the like, or an alloy material or compound material which contains any of these elements. As the alloy material containing any of the elements, an aluminum alloy containing titanium, an aluminum alloy containing neodymium, an aluminum alloy containing silicon (also referred to as aluminum silicon), or the like can be used for example. As the compound material containing any of the elements, a nitride such as tungsten nitride, titanium nitride, tantalum nitride, or the like can be given. The conductive layers 336c and 336d may be formed over the entire surface by using the aforementioned material by a sputtering method or a CVD method and then may be formed into a desired shape by selective etching. The conductive layers 336c and 336d can be formed to have a single-layer structure or a stacked structure of two or more layers and, for example, a structure in which a titanium layer, a titanium nitride layer, an aluminum layer, and a titanium layer are sequentially stacked can be employed. By forming an aluminum layer between titanium layers, heat resistance can be increased. Further, a titanium nitride layer between a titanium layer and an aluminum layer can function as a barrier layer.

In the above-described manner, an n-channel transistor and a p-channel transistor can be manufactured using a semiconductor substrate including a single crystal semiconductor layer.

Note that the conductive layer 336c and the conductive layer 336d can be electrically connected to each other so that the n-channel transistor and the p-channel transistor can be electrically connected to each other, thereby forming a CMOS transistor.

The example in which the LDD regions of the n-channel transistor do not overlap with the gate electrode has been described in this embodiment mode; however, the LDD regions of the n-channel transistor may also overlap with the gate electrode similarly to the p-channel transistor. Further, the LDD regions need not necessarily be formed in the n-channel transistor. The example in which the LDD regions of the p-channel transistor overlap with the gate electrode has been described; however, the structure in which the LDD regions of the p-channel transistor do not overlap with the gate electrode may also be employed. Further, the LDD regions need not necessarily be formed in the p-channel transistor.

By combining a plurality of transistors described in this embodiment mode, a semiconductor device with various functions can be manufactured. Note that the structure of the transistors described in this embodiment mode is one example, and the structure is not limited to the structure illustrated in the drawings.

The semiconductor layer included in the semiconductor substrate that is used in this embodiment mode is a thinned layer of a single crystal semiconductor substrate. By laser beam irradiation in manufacturing a semiconductor substrate, part of a single crystal semiconductor layer is melted so as to be re-single-crystallized. Then, in the present invention, a channel of a transistor included in a semiconductor device is formed in the re-single-crystallized semiconductor layer. Therefore, high carrier mobility of the transistor can be obtained, enabling high speed operation of the transistor. Furthermore, since the single crystal semiconductor has almost uniform crystal orientation, variation in characteristics of the transistor can be reduced compared to the case of using a polycrystalline semiconductor.

Furthermore, by performing heat treatment after isolating the single crystal semiconductor layer that is re-single-crystallized by laser beam irradiation and forming the impurity regions serving as source regions and drain regions, the lifetime of the single crystal semiconductor layers in which channels are formed can be improved and, in addition, the source regions and the drain regions can be activated. By performing heat treatment after patterning the semiconductor layer, damage to the semiconductor layer can be prevented and a crystal defect can be reduced effectively. Therefore, high-performance transistors can be provided with high yield.

Note that this embodiment mode can be implemented in combination with any of other embodiment modes described in this specification as appropriate.

### Embodiment Mode 4

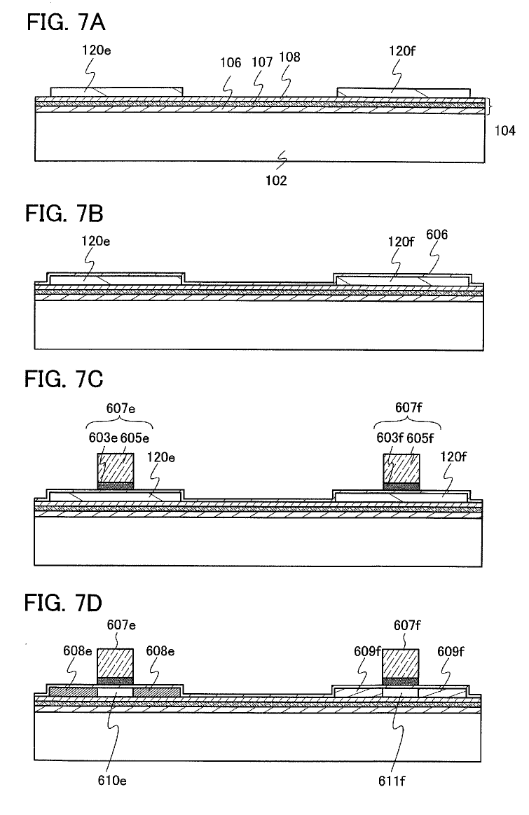

In Embodiment Mode 4, transistors having a different structure from the above embodiment modes and a manufacturing method thereof will be described. Hereinafter, description is made with reference to the cross-sectional views of FIGS. 7A to 7D, FIGS. 8A to 8C, and FIGS. 9A and 9B. Note that a method of manufacturing an n-channel transistor and a p-channel transistor at the same time will be described in this embodiment mode.

First, a semiconductor substrate in which the single crystal semiconductor layer is fixed over the supporting substrate 102 with the buffer layer 104 interposed therebetween is prepared. In this embodiment mode, an example using the semiconductor substrate manufactured through the steps of FIGS. 1A to 1E of Embodiment Mode 1 will be described. It is needless to say that a semiconductor substrate having another structure according to the present invention can be used. However, at least the substrate has to include a fixed single crystal semiconductor layer part of which is re-single-crystallized through melting by laser beam irradiation.

As illustrated in FIG. 7A, the single crystal semiconductor layer 120 over the supporting substrate 102 is processed (patterned) into a desired shape in accordance with arrangement of semiconductor elements by selective etching; accordingly, a single crystal semiconductor layer 120e and a single crystal semiconductor layer 120f are formed. A p-channel transistor is formed using the single crystal semiconductor layer 120e, and an n-channel transistor is formed using the single crystal semiconductor layer 120f.

In order to control threshold voltages, a p-type impurity element such as boron, aluminum, or gallium or an n-type impurity element such as phosphorus or arsenic may be added to the single crystal semiconductor layer 120e and the single crystal semiconductor layer 120f. For example, in the case of adding boron as a p-type impurity element, boron may be added at a concentration of equal to or greater than 5×10¹⁶ cm⁻³ and equal to or less than 1×10¹⁷ cm⁻¹. The addition of the impurity element for controlling the threshold voltages may be performed before formation of the single crystal semiconductor layer 120 or may be performed on the single crystal semiconductor layers 120e and 120f. Alternatively, the addition of the impurity element for controlling the threshold voltages may be performed to the single crystal semiconductor substrate 112 that is a base of the single crystal semiconductor layer 120. Further alternatively, the addition of the impurity element may be performed on the single crystal semiconductor substrate 112 for roughly adjusting the threshold voltage, and then the addition of the impurity element may be further performed on the single crystal semiconductor layer 120 before processing or on the single crystal semiconductor layers 120e and 120f for finely adjusting the threshold voltage.

Taking as an example the case of using a p-type single crystal silicon substrate with low concentration of an impurity element as the single crystal semiconductor substrate 112, an example of a method of adding an impurity element is described. Before etching the single crystal semiconductor layer 120, boron is added to the entire single crystal semiconductor layer 120. This addition of boron aims at adjusting the threshold voltage of a p-channel transistor. Using B₂H₆ as a source gas, boron is added at a concentration of 1×10¹⁶/cm³ to 1×10¹⁷/cm³. The concentration of boron is determined in consideration of the activation rate or the like. For example, the concentration of boron can be 6×10¹⁶/cm³. Next, the single crystal semiconductor layer 120 is etched to form the single crystal semiconductor layers 120e and 120f. Then, boron is added to only the single crystal semiconductor layer 120f. This second addition of boron aims at adjusting the threshold voltage of an n-channel transistor. Using B₂H₆ as a source gas, boron is added at a concentration of 1×10¹⁶/cm³ to 1×10¹⁷/cm³. For example, the concentration of boron can be 6×10¹⁶/cm³.

Note that in the case where a substrate having a conductivity type and resistance suitable for the threshold voltage of either the p-channel transistor or the n-channel transistor is used as the single crystal semiconductor substrate 112, adding an impurity element for controlling the threshold voltage can be finished by one time. In this case, an impurity element for controlling the threshold voltage may be added to one of the single crystal semiconductor layer 120e or the single crystal semiconductor layer 120f.

Next, as illustrated in FIG. 7B, a gate insulating layer 606 is formed to cover the single crystal semiconductor layers 120e and 120f. The gate insulating layer 606 is formed as a single layer or stacked layers of silicon oxide, silicon nitride oxide, silicon nitride, hafnium oxide, aluminum oxide, or tantalum oxide by a plasma CVD method, a sputtering method, or the like. In this embodiment mode, the gate insulating layer 606 can be formed with a thin film thickness of, for example, 20 nm to cover surfaces of the single crystal semiconductor layers 120e and 120f by a plasma CVD method. Alternatively, the gate insulating layer 606 may be formed by oxidizing or nitriding the surfaces of the single crystal semiconductor layers 120e and 120f by high-density plasma treatment. High-density plasma treatment is performed by using, for example, a mixed gas of a rare gas such as He, Ar, Kr, or Xe; and oxygen, nitrogen oxide, ammonia, nitrogen, or hydrogen. In this case, when excitation of plasma is performed by a microwave, plasma with a low electron temperature and a high density can be generated. The surfaces of the semiconductor layers are oxidized or nitrized by oxygen radicals (OH radicals may be included) or nitrogen radicals (NH radicals may be included) which are generated by such high-density plasma, whereby insulating layers are formed with a thickness of 1 nm to 50 nm, desirably 5 nm to 30 nm so as to be in contact with the semiconductor layers. Laser beam irradiation is performed in manufacture of the semiconductor substrate in order to planarize the surface of the single crystal semiconductor layer; therefore, even when an insulating layer having a thickness of 20 nm is used as the gate insulating layer 606, sufficient withstand voltage can be obtained.

Alternatively, the gate insulating layer 606 may be formed by thermally oxidizing the single crystal semiconductor layers 120e and 120f.

After formation of the gate insulating layer 606 containing hydrogen, heat treatment may be performed at a temperature equal to or higher than 350° C. and equal to or lower than 450° C. and preferably equal to or higher than 400° C. and equal to or lower than 430° C., so that hydrogen contained in the gate insulating layer 606 may be diffused into the single crystal semiconductor layers 120e and 120f. In this case, the gate insulating layer 606 can be formed by depositing silicon nitride or silicon nitride oxide by a plasma CVD method at a process temperature of equal to or lower than 350° C. By supplying hydrogen to the single crystal semiconductor layers 120e and 120f, dangling bonds in the single crystal semiconductor layers 120e and 120f or at an interface between the gate insulating layer 606 and the single crystal semiconductor layers 120e and 120f can be reduced (terminated with hydrogen).

Next, after forming a conductive layer over the gate insulating layer 606, the conductive layer is processed (patterned) into a predetermined shape, thereby forming an electrode 607e and an electrode 607f over the single crystal semiconductor layer 120e and the single crystal semiconductor layer 120f respectively, as illustrated in FIG. 7C. The conductive layer can be formed by a sputtering method, a CVD method, or the like. For the conductive layer, tantalum, tungsten, titanium, molybdenum, aluminum, copper, chromium, niobium, or the like may be used. Alternatively, an alloy material containing the above-described element or a compound material containing the above-described element may be used. Further alternatively, the conductive layer may be formed using a semiconductor such as polycrystalline silicon which is formed by addition of an impurity element such as phosphorus, to a semiconductor layer.

In this embodiment mode, the gate electrode 607e has a two-layer structure of a conductive layer 603e and a conductive layer 605e. Similarly, the gate electrode 607f has a two-layer structure of a conductive layer 603f and a conductive layer 605f. As a combination of two conductive layers for forming the gate electrode, tantalum nitride or tantalum can be used for a first layer, and tungsten can be used for a second layer. Besides the above-described example, tungsten nitride and tungsten; molybdenum nitride and molybdenum; aluminum and tantalum; aluminum and titanium; and the like can be given. Since tungsten and tantalum nitride have high heat resistance, heat treatment for activation or the like can be performed at a higher process temperature in a step after formation of the two conductive layers. Alternatively, as a combination of the two conductive layers, for example, silicon doped with an n-type impurity element and nickel silicide, silicon doped with an n-type impurity element and tungsten silicide, or the like can be used.

Although in this embodiment mode, the gate electrode 607e and the gate electrode 607f each have a stacked structure including two conductive layers, the present invention is not limited to this structure. Each of the gate electrode 607e and the gate electrode 607f may be a single conductive layer or may have a stacked structure including three or more conductive layers. In such a case, a stacked structure of a molybdenum layer, an aluminum layer, and a molybdenum layer may be employed.

For a mask which is used to form the gate electrodes 607e and 607f, silicon oxide, silicon nitride oxide, or the like may be used instead of a resist mask. In this case, an additional step of etching silicon oxide, silicon nitride oxide, or the like is needed; however, reduction in film thickness of the mask due to etching is less than that in the case of using a resist mask; accordingly, the electrodes 607e and 607f each having a desired width can be formed easily. Alternatively, the gate electrodes 607e and 607f may be selectively formed by a droplet discharge method without using a mask.

Note that a droplet discharge method means a method of forming a predetermined pattern by discharging or ejecting a droplet containing a predetermined composition from a small nozzle. An inkjet method is given as one example.

After forming a conductive layer for forming the gate electrodes over the entire surface, the conductive layer can be etched by an ICP dry etching apparatus to have a desired shape with appropriate control of the etching conditions (power applied to a coiled electrode, power applied to an electrode on the substrate, the temperature of the electrode on the substrate, and the like). Further, an angle and the like of the taper shape can also be controlled by the shape of the mask. Note that as an etching gas, a chlorine-based gas such as chlorine, boron chloride, silicon chloride or carbon tetrachloride; or a fluorine-based gas such as carbon tetrafluoride, sulfur fluoride, or nitrogen fluoride can be used as appropriate. Further, oxygen can also be added as an assistant gas.

Next, an n-type impurity element or a p-type impurity element is added into the single crystal semiconductor layer 120e and the single crystal semiconductor layer 120f using the gate electrode 607e and the gate electrode 607f as masks. In this embodiment mode, a p-type impurity element (e.g., boron) is added into the single crystal semiconductor layer 120e, and an n-type impurity element (e.g., phosphorus or arsenic) is added into the single crystal semiconductor layer 120f. Then, impurity regions 608e serving as a source region and a drain region are formed in the single crystal semiconductor layer 120e, and impurity regions 609f serving as high-resistant regions (LDD regions) are formed in the single crystal semiconductor layer 120f (see FIG. 7D).

When the p-type impurity element is added into the single crystal semiconductor layer 120e, the single crystal semiconductor layer 120f is covered with a mask or the like so that the p-type impurity element is not added into the single crystal semiconductor layer 120f. On the other hand, when the n-type impurity element is added into the single crystal semiconductor layer 120f, the single crystal semiconductor layer 120e is covered with a mask or the like so that the n-type impurity element is not added into the single crystal semiconductor layer 120e. Alternatively, after one of a p-type impurity element and an n-type impurity element is added into the single crystal semiconductor layers 120e and 120f, the other of the p-type impurity element and the n-type impurity element may be selectively added into one of the semiconductor layers at a higher concentration than that of the previously added impurity element. By such addition of impurity elements, p-type high-concentration impurity regions 608e are formed in the single crystal semiconductor layer 120e, and n-type low-concentration impurity regions 609f are formed in the single crystal semiconductor layer 120f. The regions overlapping with the electrodes 607e and 607f in the single crystal semiconductor layers 120e and 120f are a channel formation region 610e and a channel formation region 611f, respectively.

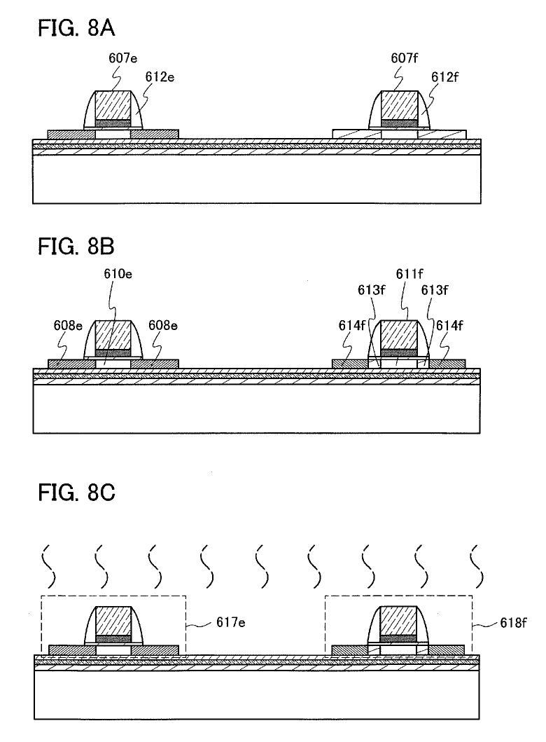

Next, as illustrated in FIG. 8A, sidewalls 612e are formed on side surfaces of the gate electrode 607e, and sidewalls 612f are formed on side surfaces of the gate electrode 607f. The sidewalls 612e and 612f can be formed in such a manner that an insulating layer is newly formed so as to cover the gate insulating layer 606 and the gate electrodes 607e and 607f, and the newly-formed insulating layer is partially etched by anisotropic etching in which etching is performed mainly in a perpendicular direction. The newly-formed insulating layer is partially etched by the anisotropic etching, whereby the sidewalls 612e are formed on the side surfaces of the gate electrode 607f and the sidewalls 612f are formed on the side surfaces of the gate electrode 607f. Note that the gate insulating layer 606 is also partially etched by this anisotropic etching. The insulating layer for forming the sidewalls 612e and 612f can be formed as a single layer or stacked layers of two or more layers including a layer that contains an organic material such as an organic resin or a layer of silicon, silicon oxide, or silicon nitride oxide by a plasma CVD method, a sputtering method, or the like. In this embodiment mode, the insulating layer is formed of a silicon oxide layer with a thickness of 100 nm by a plasma CVD method. In addition, as an etching gas of the silicon oxide layer, a mixed gas of CHF₃ and helium can be used. It is to be noted that the steps for forming the sidewalls 612e and 612f are not limited to the steps given here.

Then, as illustrated in FIG. 8B, an n-type impurity element is added into the single crystal semiconductor layer 120f by using the gate electrode 607e, the sidewalls 612e, the gate electrode 607f, and the sidewalls 612f as masks. By this addition of the impurity element, impurity regions serving as a source region and a drain region are formed in the single crystal semiconductor layer 120f. In this step, the n-type impurity element is added into the single crystal semiconductor layer 120f while the single crystal semiconductor layer 120e is covered with a mask or the like.

In the above-described addition of the impurity element, the gate electrode 607e, the sidewalls 612e, the gate electrode 607f, and the sidewalls 612f serve as masks; accordingly, a pair of n-type high-concentration impurity regions 614f and a pair of n-type low-concentration impurity regions 613f are formed in the single crystal semiconductor layer 120f in a self-aligning manner. The low-concentration impurity regions 613f are regions of the impurity regions 609f to which the impurity element is not added. The low-concentration impurity regions 613f have a lower impurity concentration than the high-concentration impurity regions 614f and function as high-resistance regions or LDD regions. The LDD regions suppress an electric field in the vicinity of the drain, preventing reduction in the ON current value due to hot carriers.

Next, after removing the mask, heat treatment is performed at a process temperature which does not cause melting of the single crystal semiconductor layer 120e and the single crystal semiconductor layer 120f and which is equal to or higher than 400° C. and equal to or lower than the strain point of the supporting substrate 102 (see FIG. 8C).

By this heat treatment, a micro crystal defect of the channel formation region 610e formed in the single crystal semiconductor layer 120e is reduced and, in addition, the impurity regions 608e serving as a source region and a drain region are activated (reduced in resistance). At the same time, a micro crystal defect of the channel formation region 611f formed in the single crystal semiconductor layer 120f is reduced and, in addition, the high-concentration impurity regions 614f serving as a source region and a drain region and the low-concentration impurity regions 613f serving as the LDD regions are activated (reduced in resistance). The process temperature of the heat treatment is preferably equal to or higher than 450° C. and equal to or lower than 650° C.

According to one feature of a manufacturing method of a semiconductor device of the present invention, in addition to irradiation of a single crystal silicon layer with a laser beam to planarize the layer and reduce a crystal defect in manufacture of a semiconductor substrate, after isolating the single crystal silicon layer in accordance with arrangement of desired semiconductor elements and forming impurity regions serving as a source region and a drain region in each of the isolated single crystal silicon layers, heat treatment is performed at a process temperature which does not cause melting of the single crystal silicon layers and which is equal to or higher than 400° C. and equal to or lower than the strain point of the supporting substrate 102. By performing the heat treatment at a process temperature in the above-described range, the carrier lifetime in channels of manufactured transistors can be improved compared to the case of not performing the heat treatment. Further, by performing the above-describe heat treatment with such a process temperature after formation of the source regions and the drain regions, recovery of characteristics of channel formation regions and activation of the impurity regions serving as the source regions and the drain regions can be performed by the single heat treatment step. Accordingly, the process can be simplified, thereby improving throughput. Furthermore, by performing heat treatment after isolating and patterning the single crystal semiconductor layer in accordance with arrangement of desired semiconductor elements, film stress can be relaxed and damage of the single crystal semiconductor layers due to film stress can be prevented. Thus, transistors having favorable electric characteristics can be manufactured with high yield and high productivity.

Heat treatment for activation of the impurity regions serving as LDD regions may be performed in a different step. By such heat treatment, recovery of characteristics of channel formation regions and activation of the impurity regions serving as the LDD regions may be performed. For example, after formation of the impurity regions 609f as illustrated in FIG. 7D in this embodiment mode, heat treatment may be performed at a process temperature which does not cause melting of the single crystal semiconductor layers and which is equal to or higher than 400° C. and equal to or lower than the strain point of the supporting substrate 102. In this case, after formation of the impurity regions serving as the source regions and the drain regions, the process temperature of heat treatment can be determined in consideration of only activation of the source regions and the drain regions.

In order to reduce the resistance of the impurity regions serving as the source regions and the drain regions, silicide layers may be formed by siliciding the high-concentration impurity regions 608e in the single crystal semiconductor layer 120e and the high-concentration impurity regions 614f in the single crystal semiconductor layer 120f. The silicidation can be performed by forming a metal layer in contact with the single crystal semiconductor layers 120e and 120f and causing reaction between the metal and silicon in the single crystal semiconductor layers through heat treatment; in this manner, a silicide compound is produced. As the metal used for silicidation, cobalt or nickel is preferable, or the following can be used: titanium, tungsten, molybdenum, zirconium, hafnium, tantalum, vanadium, neodymium, chromium, platinum, palladium, or the like. In the case where the single crystal semiconductor layers 120e and 120f are thin, the silicide reaction may be advanced to the bottoms of the single crystal semiconductor layers 120e and 120f. As the heat treatment for silicidation, a resistance heating furnace, an RTA apparatus, a microwave heating apparatus, or a laser beam irradiation apparatus can be used.

Through a series of the steps illustrated in FIGS. 7A to 7D and FIGS. 8A to 8C, a p-channel transistor 617e and an n-channel transistor 618f are formed.

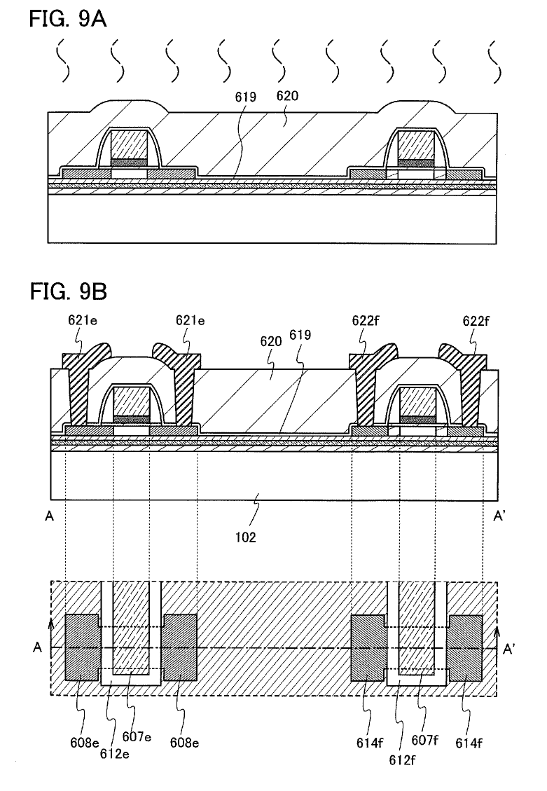

Next, as illustrated in FIG. 9A, an insulating layer 619 is formed to cover the transistors 617e and 618f. As the insulating layer 619, an insulating layer containing hydrogen is formed. In this embodiment mode, a silicon nitride oxide layer with a thickness of approximately 100 nm is formed by a plasma CVD method using a process gas containing monosilane, ammonia, nitrogen oxide, and hydrogen. The insulating layer 619 is formed to contain hydrogen because hydrogen diffuses from the insulating layer 619 so that dangling bonds in the single crystal semiconductor layers 120e and 120f are terminated with hydrogen. The formation of the insulating layer 619 can prevent impurities such as an alkali metal and an alkaline earth metal from entering the transistors 617e and 618f. Specifically, silicon nitride, silicon nitride oxide, aluminum nitride, aluminum oxide, silicon oxide, or the like is used for the insulating layer 619.

Next, as illustrated in FIG. 9A, an insulating layer 620 is formed over the insulating layer 619 so as to cover the transistors 617e and 618f. An organic material having heat resistance, such as polyimide, acrylic, benzocyclobutene, polyamide, or epoxy can be used for the insulating layer 620. In addition to such organic materials, it is also possible to use a low-dielectric constant material (a low-k material), a siloxane resin, silicon oxide, silicon oxynitride, silicon nitride, silicon nitride oxide, PSG (phosphosilicate glass), BPSG (borophosphosilicate glass), alumina, or the like. A siloxane-based resin corresponds to a resin including a Si—O—Si bond, which is formed using a siloxane-based material as a starting material. A siloxane-based resin may include as a substituent at least one of fluorine, an alkyl group, and an aryl group, as well as hydrogen. Alternatively, the insulating layer 620 may be formed by stacking plural insulating layers formed of these materials.

For the formation of the insulating layer 620, the following method can be used depending on the material of the insulating layer 620: a CVD method, a sputtering method, an SOG method, a spin coating method, a dip coating method, a spray coating method, a droplet discharge method (e.g., an inkjet method, screen printing, or offset printing), a doctor knife, a roll coater, a curtain coater, a knife coater, or the like.

Next, heat treatment at about 350° C. or higher and 450° C. or lower, preferably 400° C. or higher and 430° C. or lower (e.g., 410° C.) is performed in a nitrogen atmosphere for about one hour, so that hydrogen is diffused from the insulating layer 619 and dangling bonds in the single crystal semiconductor layers 120e and 120f are terminated with hydrogen. The single crystal semiconductor layers 120e and 120f have a much lower defect density than a polycrystalline silicon layer which is formed by crystallizing an amorphous silicon layer.

Next, as illustrated in FIG. 9B, contact holes are formed in the insulating layer 619 and the insulating layer 620 so that the single crystal semiconductor layer 120e is partially exposed. At the same time, contact holes are formed in the insulating layer 619 and the insulating layer 620 so that the single crystal semiconductor layer 120f is partially exposed. The contact holes can be formed by a dry etching method using CHF₃ and He as an etching gas; however, the present invention is not limited to this. Then, a conductive layer 621e which is electrically connected to the single crystal semiconductor layer 120e through the contact holes and a conductive layer 622f which is in contact with the single crystal semiconductor layer 120f are formed. The conductive layer 621e is electrically connected to the high-concentration impurity regions 608e of the p-channel transistor 617e. The conductive layer 622f is connected to the high-concentration impurity regions 614f of the n-channel transistor 618f.

The conductive layers 621e and 622f can be formed by a sputtering method, a CVD method, or the like. Specifically, the conductive layers 621e and 622f can be formed using aluminum, tungsten, titanium, tantalum, molybdenum, nickel, platinum, copper, gold, silver, manganese, neodymium, carbon, silicon, or the like. Alternatively, the conductive layers may be formed using an alloy containing the above-mentioned element or a compound containing the above-mentioned element. The conductive layers 621e and 622f can be formed to have a single layer structure or a stacked structure using the above-mentioned material.

As examples of an alloy containing aluminum, an alloy containing aluminum as its main component and also containing nickel or an alloy containing aluminum as its main component and also containing silicon can be given. Further, an alloy which contains aluminum as its main component and contains nickel and one or both of carbon and silicon can also be given as an example. Aluminum and aluminum silicon have low resistance and are inexpensive. Instead of silicon, copper may be mixed into aluminum at about 0.5 wt %.

Since an aluminum or an aluminum alloy (e.g., aluminum silicon) has a low resistance value and is inexpensive, aluminum or an aluminum alloy is suitable for the conductive material; however, use of an aluminum or an aluminum alloy has problems of heat resistance and easy generation of hillocks. Accordingly, a structure in which the aluminum layer or the aluminum alloy layer is sandwiched between barrier layers is preferable. For example, the conductive layers 621e and 622f preferably have a stacked structure including a barrier layer, an aluminum layer or an aluminum alloy layer, and a barrier layer. For the barrier layer, titanium, titanium nitride, molybdenum, molybdenum nitride, or the like is used. When an aluminum layer or an aluminum alloy layer is sandwiched between barrier layers, generation of hillocks can be prevented. Moreover, when the barrier layer is formed using titanium that is a highly reducible element, even if a thin oxide film is formed over the single crystal semiconductor layers 120e and 120f, the oxide film is reduced by titanium contained in the barrier layer. Thus, preferable contact between the conductive layers 621e and 622f and the single crystal semiconductor layers 120e and 120f can be obtained. Further, a plurality of barrier layers may be stacked. In such a case, for example, the conductive layers 621e and 622f may each have a stacked structure in which a titanium layer, a titanium nitride layer, an aluminum layer, and a titanium layer are stacked in this order from the lowest layer (from the side in contact with the single crystal semiconductor layers).

For the conductive layers 621e and 622f, tungsten silicide formed by a CVD method using a WF₆ gas and a SiH₄ gas may be used. Alternatively, tungsten formed by hydrogen reduction of WF₆ may be used for the conductive layers 621e and 622f.

FIG. 9B illustrates a top view of the p-channel transistor 617e and the n-channel transistor 618f and a cross-sectional view taken along a line A-A′ of the top view. Note that the conductive layers 621e and 622f, the insulating layer 619, and the insulating layer 620 are omitted in the top view of FIG. 9B.

Note that the conductive layer 621e and the conductive layer 622f can be electrically connected to each other so that the n-channel transistor and the p-channel transistor can electrically connected to each other, thereby forming a CMOS transistor.

Although the case where the p-channel transistor 617e and the n-channel transistor 618f have one gate electrode 607e and one gate electrode 607f functioning as a gate respectively is described in this embodiment mode, the present invention is not limited to this structure. The transistor manufactured in the present invention can have a multi-gate structure in which a plurality of electrodes functioning as gates are included and electrically connected to one another. Moreover, the transistor may have a gate planar structure.

The example in which LDD regions are not formed in the p-channel transistor has been described in this embodiment mode; however, LDD regions may be formed in the p-channel transistor similarly to the n-channel transistor. Further, the LDD regions need not necessarily be formed in the n-channel transistor.

By combining a plurality of transistors described in this embodiment mode, a semiconductor device with various functions can be manufactured. Note that the structure of the transistors described in this embodiment mode is one example, and the structure is not limited to the structure illustrated in the drawings.

The semiconductor layer included in the semiconductor substrate that is used in this embodiment mode is a thinned layer of a single crystal semiconductor substrate. By laser beam irradiation in manufacture of a semiconductor substrate, part of a single crystal semiconductor layer is melted so as to be re-single-crystallized. Then, a channel of a transistor included in a semiconductor device according to the present invention is formed using the re-single-crystallized semiconductor layer. Therefore, high carrier mobility of the transistor can be obtained, enabling high speed operation of the transistor. Furthermore, since the single crystal semiconductor has almost uniform crystal orientation, variation in characteristics of the transistor can be reduced compared to the case of using a polycrystalline semiconductor.

Furthermore, by performing heat treatment after isolating the semiconductor layer that is re-single-crystallized by laser beam irradiation and forming the impurity regions serving as source regions and drain regions, the carrier lifetime of the single crystal semiconductor layers in which channels are formed can be improved and, in addition, the source regions and the drain regions can be activated. By performing heat treatment after patterning the semiconductor layer, damage to the semiconductor layer can be prevented and a crystal defect can be reduced effectively. Therefore, high-performance transistors can be provided with high yield.

Note that this embodiment mode can be implemented in combination with any of other embodiment modes described in this specification as appropriate.

### Embodiment Mode 5

The above embodiment modes explain the manufacturing method of transistors as examples of a manufacturing method of a semiconductor device. Meanwhile, a semiconductor device can be manufactured so as to have high added value by forming a variety of semiconductor elements such as a capacitor and a resistor together with the transistors. In Embodiment Mode 5, specific modes of a semiconductor device according to the present invention will be described with reference to the drawings.

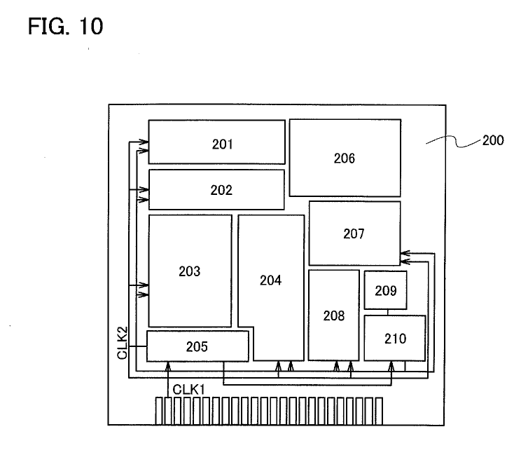

First, as an example of a semiconductor device, a microprocessor is described. FIG. 10 is a block diagram illustrating an example of a structure of a microprocessor 200. This microprocessor 200 includes an arithmetic logic unit (also referred to as an ALU) 201; an ALU controller 202, an instruction decoder 203, an interrupt controller 204, a timing controller 205, a register 206, a register controller 207, a bus interface (Bus I/F) 208, a read-only memory 209, and a ROM interface (ROM I/F) 210.

An instruction input to the microprocessor 200 through the bus interface 208 is input to the instruction decoder 203, decoded therein, and then input to the ALU controller 202, the interrupt controller 204, the register controller 207, and the timing controller 205. The ALU controller 202, the interrupt controller 204, the register controller 207, and the timing controller 205 conduct various controls based on the decoded instruction. Specifically, the ALU controller 202 generates signals for controlling operation of the ALU 201. While the microprocessor 200 is executing a program, the interrupt controller 204 processes an interrupt request from an external input/output device or a peripheral circuit based on its priority or a mask state. The register controller 207 generates an address of the register 206, and reads and writes data from and to the register 206 in accordance with the state of the microprocessor 200. The timing controller 205 generates signals for controlling timing of operation of the ALU 201, the ALU controller 202, the instruction decoder 203, the interrupt controller 204, and the register controller 207. For example, the timing controller 205 is provided with an internal clock generator for generating an internal clock signal CLK2 based on a reference clock signal CLK1, and supplies the clock signal CLK2 to the various above-mentioned circuits. The microprocessor 200 illustrated in FIG. 10 is only an example in which the configuration is simplified, and an actual microprocessor may have various configurations depending on the uses.

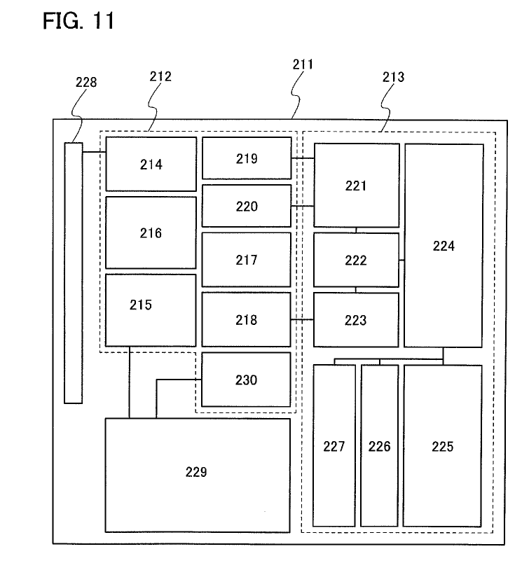

Next, an example of a semiconductor device having an arithmetic function that is capable of contactless data transmission and reception will be described with reference to FIG. 11. In FIG. 11, as a semiconductor device, an example of a computer that operates to transmit and receive signals to and from an external device by wireless communication (such a computer is hereinafter referred to as an “RFCPU”) is illustrated. An RFCPU 211 has an analog circuit portion 212 and a digital circuit portion 213. The analog circuit portion 212 includes a resonance circuit 214 with a resonance capacitor, a rectifier circuit 215, a constant voltage circuit 216, a reset circuit 217, an oscillation circuit 218, a demodulation circuit 219, and a modulation circuit 220. The digital circuit portion 213 includes an RF interface 221, a control register 222, a clock controller 223, an interface 224, a central processing unit 225, a random-access memory 226, and a read-only memory 227.

The operation of the RFCPU 211 having such a configuration is roughly as follows. The resonance circuit 214 generates an induced electromotive force based on a signal received by an antenna 228. The induced electromotive force is stored in a capacitor portion 229 through the rectifier circuit 215. This capacitor portion 229 is preferably formed using a capacitor such as a ceramic capacitor or an electric double layer capacitor. The capacitor portion 229 does not need to be integrated with the RFCPU 211 and it is acceptable as long as the capacitor portion 229 is mounted as a different component on a substrate having an insulating surface which is included in the RFCPU 211.

The reset circuit 217 generates a signal for resetting and initializing the digital circuit portion 213. For example, the reset circuit generates, as a reset signal, a signal which rises after rise in the supply voltage with delay. The oscillation circuit 218 changes the frequency and the duty ratio of a clock signal in accordance with a control signal generated by the constant voltage circuit 216. The demodulation circuit 219 formed using a low-pass filter binarizes the amplitude of, for example, a received amplitude-modulated (ASK) signal. The modulation circuit 220 varies the amplitude of an amplitude-modulated (ASK) transmission signal and transmits the data. The modulation circuit 220 changes the amplitude of a communication signal by changing a resonance point of the resonance circuit 214. The clock controller 223 generates a control signal for changing the frequency and duty ratio of a clock signal in accordance with the power supply voltage or a consumption current of the central processing unit 225. The power supply voltage is managed by a power management circuit 230.

A signal input from the antenna 228 to the RFCPU 211 is demodulated by the demodulation circuit 219 and then decomposed into a control command, data, and the like by the RF interface 221. The control command is stored in the control register 222. The control command includes reading of data stored in the read-only memory 227, writing of data to the random-access memory 226, an arithmetic instruction to the central processing unit 225, and the like. The central processing unit 225 accesses the read-only memory 227, the random-access memory 226, and the control register 222 via the interface 224. The CPU interface 224 has a function of generating an access signal for any of the read-only memory 227, the random-access memory 226, and the control register 222 based on an address the central processing unit 225 requests.

As an arithmetic method of the central processing unit 225, a method can be employed in which the read-only memory 227 stores an operating system (OS) and a program is read and executed at the time of starting operation. Alternatively, a method in which a circuit dedicated to arithmetic is formed and an arithmetic process is conducted using hardware can be employed. In a method in which both hardware and software are used, part of processing is conducted by a dedicated arithmetic circuit and the other part of the arithmetic processing is conducted by the central processing unit 225 using a program.

Semiconductor devices such as the microprocessor 200 and the RFCPU 211 can be manufactured using a circuit having various functions which is formed by combining plural transistors according to the present invention. In the present invention, transistors are manufactured using a semiconductor substrate which includes a single crystal semiconductor layer. Since characteristics of the single crystal semiconductor layer are improved, transistors having superior electric characteristics can be provided. In addition, a semiconductor substrate which includes a single crystal semiconductor layer over an inexpensive substrate such as a glass substrate can be utilized, thereby reducing cost. Accordingly, when an integrated circuit is manufactured by combining such transistors, higher performance, higher processing speed, lower cost, and the like of semiconductor devices such as a microprocessor and an RFCPU can be realized. Although FIG. 11 illustrates a mode of the RFCPU, a device such as an IC tag is also possible as long as it has a communication function, an arithmetic processing function, and a memory function.

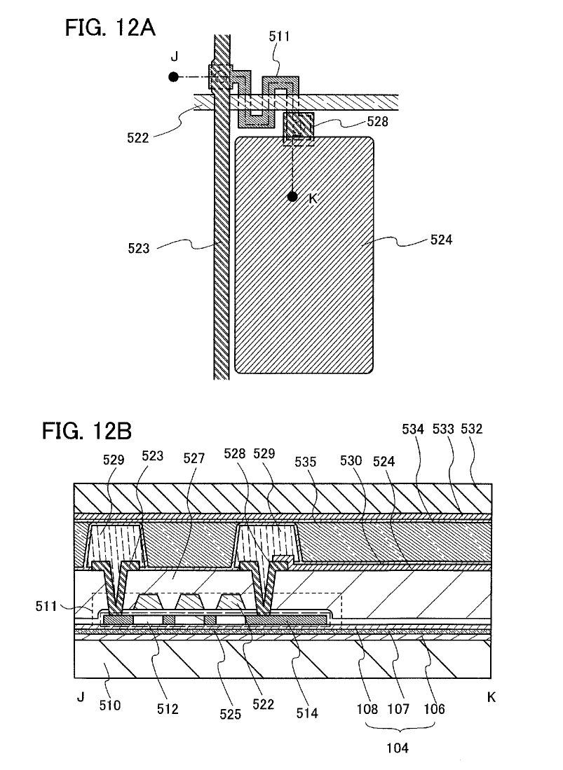

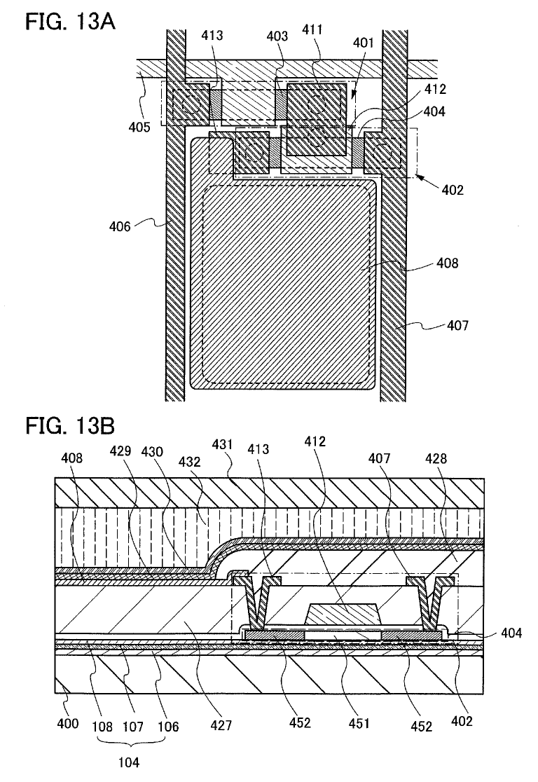

Next, display devices will be described as structural examples of a semiconductor device with reference to FIGS. 12A and 12B and FIGS. 13A and 13B.

FIGS. 12A and 12B illustrate a structural example of a liquid crystal display device. FIG. 12A is a plan view of a pixel of the liquid crystal display device, and FIG. 12B is a cross-sectional view taken along a line J-K in FIG. 12A. In FIG. 12A, a single crystal semiconductor layer 511 forms a transistor 525 of a pixel. The pixel includes the single crystal semiconductor layer 511; a scan line 522 that crosses the single crystal semiconductor layer 511; a signal line 523 that crosses the scan line 522; a pixel electrode 524; and an electrode 528 which electrically connects the pixel electrode 524 to the single crystal semiconductor layer 511. The single crystal semiconductor layer 511 is a layer formed from a single crystal semiconductor layer included in a semiconductor substrate according to the present invention, and part of the single crystal semiconductor layer 511 is re-single-crystallized through melting by laser beam irradiation treatment, for planarization and reduction in a crystal defect. In this embodiment mode, an example of manufacturing a liquid crystal display device using the semiconductor substrate manufactured through the steps of FIGS. 1A to 1E will be described.

As illustrated in FIG. 12B, the buffer layer 104 including the insulating layer 108, the insulating layer 107, and the insulating layer 106, and the single crystal semiconductor layer 511 are stacked over a substrate 510. The substrate 510 corresponds to the supporting substrate 102 or a divided part of the supporting substrate 102. The single crystal semiconductor layer 511 is a layer formed by isolation of the single crystal semiconductor layer 120 by etching. In the single crystal semiconductor layer 511, a channel formation region 512 and an n-type impurity region 514 are formed. A gate electrode of the transistor 525 is included in the scanning line 522, and one of a source electrode and a drain electrode is included in the signal line 523. By performing heat treatment after addition of an n-type impurity element to form the impurity region 514, a crystal defect of the channel formation region 512 formed in the single crystal semiconductor layer 511 according to the present invention is reduced to improve the carrier lifetime and, in addition, the impurity region 514 is activated.

Over an interlayer insulating layer 527, the signal line 523, the pixel electrode 524, and the electrode 528 are provided. Columnar spacers 529 are formed over the interlayer insulating layer 527, and an orientation film 530 is formed covering the signal line 523, the pixel electrode 524, the electrode 528, and the columnar spacers 529. An opposed substrate 532 is provided with an opposed electrode 533 and an orientation film 534 which covers the opposed electrode 533. The columnar spacers 529 are formed to keep the space between the substrate 510 and the opposed substrate 532. A liquid crystal layer 535 is formed in the space kept by the columnar spacers 529, which is between the orientation film 534 on the counter substrate 532 and the orientation film 530 on the substrate 510. At connection portions of the signal line 523 and the electrode 528 with the impurity region 514, there are steps in the interlayer insulating layer 527 due to formation of contact holes; accordingly, orientation of liquid crystals in the liquid crystal layer 535 in these connection portions becomes disordered easily. Therefore, the columnar spacers 529 are formed at the step portions to prevent the disorder of the liquid crystal orientation.

Next, an electroluminescent display device (hereinafter also referred to as an EL display device) will be described. FIG. 13A is a plan view of a pixel of the EL display device, and FIG. 13B is a cross-sectional view of the pixel. As illustrated in FIG. 13A, the pixel includes a switching transistor 401 and a display control transistor 402 which are transistors, a scanning line 405, a signal line 406, a current supply line 407, and a pixel electrode 408. Each pixel is provided with a light-emitting element having a structure in which an electroluminescent material (this layer is also referred to as an EL layer) is sandwiched between a pair of electrodes. One electrode of the light emitting element is the pixel electrode 408.

A semiconductor layer 403 included in the switching transistor 401 and a semiconductor layer 404 included in the display control transistor are layers each formed from a single crystal semiconductor layer included in a semiconductor substrate according to the present invention, and part of the single crystal semiconductor layer is re-single-crystallized through melting by laser beam irradiation treatment, for planarization and reduction in a crystal defect. Here, an example of manufacturing an EL display device using the semiconductor substrate manufactured through the steps of FIGS. 1A to 1E will be described.

In the selection transistor 401, a gate electrode is included in the scanning line 405, one of a source electrode and a drain electrode is included in the signal line 406, and the other thereof is formed as an electrode 411. In the display control transistor 402, a gate electrode 412 is electrically connected to the electrode 411, one of a source electrode and a drain electrode is formed as an electrode 413 which is electrically connected to the pixel electrode 408, and the other thereof is included in the current supply line 407.

The display control transistor 402 is a p-channel transistor. As illustrated in FIG. 13B, a channel formation region 451 and p-type impurity regions 452 are formed in the semiconductor layer 404. An interlayer insulating layer 427 is formed to cover the gate electrode 412 of the display control transistor 402. Over the interlayer insulating layer 427, the signal line 406, the current supply line 407, the electrode 411, the electrode 413, and the like are formed. Over the interlayer insulating layer 427, the pixel electrode 408 which is electrically connected to the electrode 413 is formed. A peripheral portion of the pixel electrode 408 is surrounded by a partition wall layer 428 having an insulating property. The EL layer 429 is formed over the pixel electrode 408, and an opposed electrode 430 is formed over the EL layer 429. An opposed substrate 431 is provided as a reinforcing plate and is fixed to a substrate 400 with a resin layer 432. The substrate 400 is the supporting substrate 102 or a divided part of the supporting substrate 102. By performing heat treatment after addition of a p-type impurity element to form the impurity regions 452, a crystal defect of the channel formation region 451 formed in the semiconductor layer 404 according to the present invention is reduced to improve the lifetime of the channel and, in addition, the impurity regions 452 are activated.

By using high-performance transistors according to the present invention, the liquid crystal display device illustrated in FIGS. 12A and 12B and the EL display device illustrated in FIGS. 13A and 13B can be provided with high image quality.

Various electric devices can be manufactured using a semiconductor substrate or a semiconductor device according to the present invention. The electric devices include, in their categories, cameras such as video cameras and digital cameras, navigation systems, audio reproducing devices (such as car audios and audio components), computers, game machines, portable information terminals (such as mobile computers, cellular phones, portable game machines, and e-book readers), image reproducing devices provided with a recording medium (specifically, devices equipped with a display device capable of displaying image data such as a content of a digital versatile disk (DVD)), and the like.

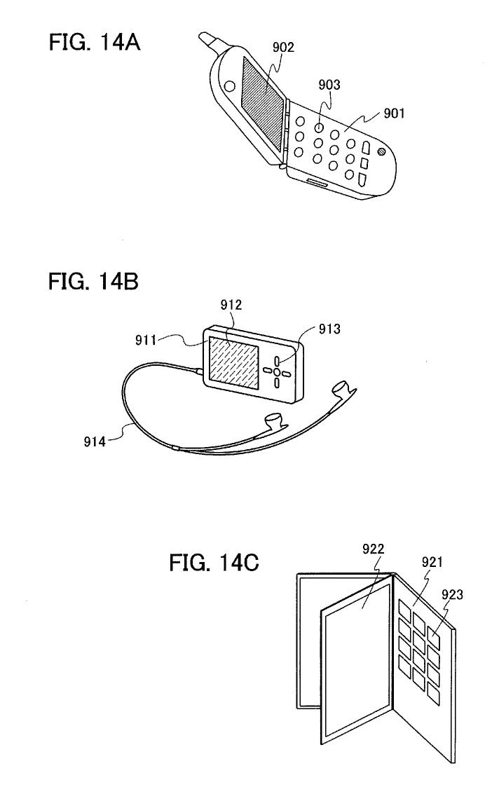

Specific modes of the electric devices will be described with reference to FIGS. 14A to 14C. FIG. 14A is an external view illustrating an example of a cellular phone 901. This cellular phone 901 includes a display portion 902, operation switches 903, and the like. When the liquid crystal display device illustrated in FIGS. 12A and 12B or the EL display device illustrated in FIGS. 13A and 13B is applied to the display portion 902, the display portion 902 can have high image quality.

FIG. 14B is an external view illustrating a structural example of a digital player 911. The digital player 911 includes a display portion 912, an operation portion 913, an earphone 914, and the like. Instead of the earphone 914, a headphone or a wireless earphone can be used. By applying the liquid crystal display device described illustrated in FIGS. 12A and 12B or the EL display device illustrated in FIGS. 13A and 13B to the display portion 912, even in the case where the screen size is about 0.3 inches to 2 inches, an image with high precision and a large amount of text information can be displayed.

Further, FIG. 14C is an external view of an electronic book 921. This electronic book 921 includes a display portion 922 and operation switches 923. The electronic book 921 may incorporate a modem or may incorporate the semiconductor device illustrated in FIG. 11 so that information can be transmitted and received wirelessly. By applying the liquid crystal display device illustrated in FIGS. 12A and 12B or the EL display device illustrated in FIGS. 13A and 13B to the display portion 922, an image with high image quality can be displayed.

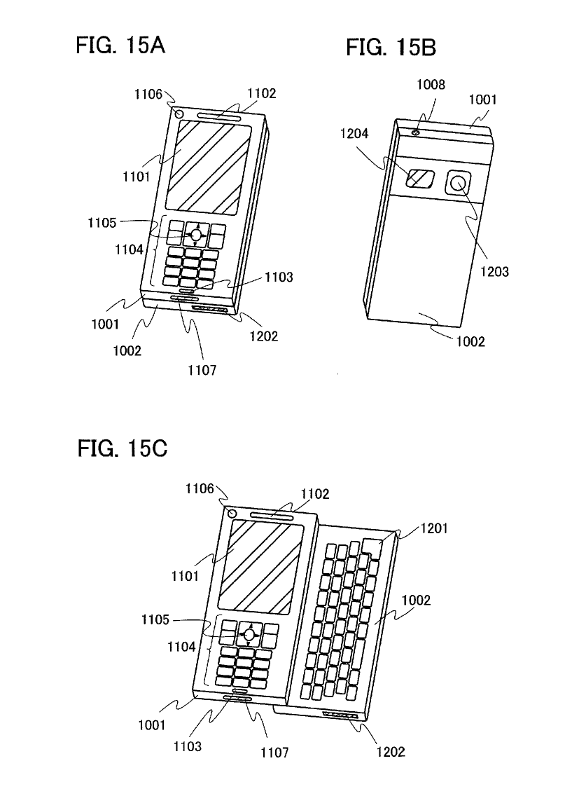

FIGS. 15A to 15C illustrate an example of a cellular phone which has a different structure from the structure illustrated in FIG. 14A. FIG. 15A is a front view of the cellular phone, FIG. 15B is a rear view, and FIG. 15C is a development view. The cellular phone in FIGS. 15A to 15C is a so-called smartphone which has both functions of a cellular phone and a portable information terminal; incorporates a computer, and conducts a variety of data processing in addition to voice calls.

The cellular phone in FIGS. 15A to 15C has two housings 1001 and 1002. The housing 1001 includes a display portion 1101, a speaker 1102, a microphone 1103, operation keys 1104, a pointing device 1105, a camera lens 1106, an external connection terminal 1107, an earphone terminal 1108, and the like, while the housing 1002 includes a keyboard 1201, an external memory slot 1202, a camera lens 1203, a light 1204, and the like. In addition, an antenna is incorporated in the housing 1001.

Further, in addition to the above-described structure, the cellular phone may incorporate a non-contact IC chip, a small size memory device, or the like.

The display portion 1101 can incorporate a semiconductor device described in this specification. As a result, display with high image quality can be achieved. The display portion 1101 changes the direction of display as appropriate depending on a usage mode.

Because the camera lens 1106 is provided in the same plane as the display portion 1101, the cellular phone illustrated in FIGS. 15A to 15C can be used as a videophone. Further, a still image and a moving image can be taken with the camera lens 1203 and the light 1204 by using the display portion 1101 as a viewfinder. The speaker 1102 and the microphone 1103 can be used for video calling, recording and playing sound, and the like without being limited to voice calls. With the use of the operation keys 1104, making and receiving calls, inputting simple information of e-mails or the like, scrolling of the screen, moving the cursor and the like are possible.

Furthermore, the housing 1001 and the housing 1002 which are overlapped with each other as illustrated in FIG. 15A are slid to expose the housing 1002 as illustrated in FIG. 15C, and the cellular phone can be used as a portable information terminal. At this time, smooth operation can be conducted using the keyboard 1201 and the pointing device 1105. The external connection terminal 1107 can be connected to an AC adaptor and various types of cables such as a USB cable, and charging and data communication with a personal computer or the like are possible. Furthermore, a large amount of data can be stored and moved by inserting a recording medium into the external memory slot 1202.

In addition to the above described functions, the cellular phone may have an infrared communication function, a television receiving function, and the like.

Note that this embodiment mode can be implemented in combination with any of other embodiment modes described in this specification as appropriate.

### Embodiment 1

In Embodiment 1, evaluation results of characteristics of a semiconductor substrate manufactured according to the present invention will be described.

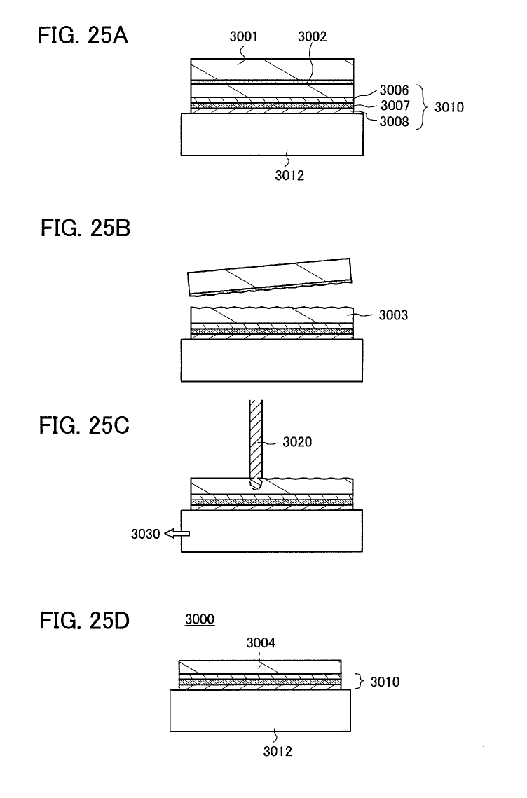

First, the structure of a semiconductor substrate which is an evaluation sample of this embodiment will be described. FIG. 25D is a cross-sectional view illustrating a structure of a semiconductor substrate 3000 evaluated in this embodiment. The semiconductor substrate 3000 illustrated in FIG. 25D is manufactured through the steps of FIGS. 1A to 1E of Embodiment Mode 1 and has a structure in which a single crystal silicon layer 3004 is fixed over a glass substrate 3012 with a buffer layer 3010 interposed therebetween. Hereinafter, a manufacturing method of the semiconductor substrate 3000 will be described briefly.

First, a single crystal silicon substrate 3001 which is a base of the single crystal silicon layer 3004 was prepared (see FIG. 25A). In this embodiment, a p-type silicon wafer of which main surface is oriented along the (100) plane was used. As the glass substrate 3012, a non-alkali glass substrate (product name: AN100) having a thickness of 0.7 mm was prepared. Note that the glass substrate 3012 corresponds to the supporting substrate 102 of Embodiment Mode 1.

Over a surface of the single crystal silicon substrate 3001, a silicon oxynitride layer 3006 with a thickness of 50 nm and a silicon nitride oxide layer with a thickness of 50 nm were sequentially formed as a first insulating layer and a second insulating layer, respectively, by a plasma CVD method (see FIG. 25A). A process gas for forming the silicon oxynitride layer 3006 that is the first insulating layer was SiH₄ and N₂O, and the flow ratio (sccm) was set as follows: SiH₄/N₂O=4/800. The substrate temperature in the step was 400° C. A process gas for forming the silicon nitride oxide layer 3007 that is the second insulating layer was SiH₄, NH₃, N₂O, and H₂, and the flow ratio (sccm) was set as follows: SiH₄/NH₃/N₂O/H₂=10/100/20/400. The substrate temperature in the step was 350° C.

The single crystal silicon substrate 3001 was irradiated with ions with an ion doping apparatus, so that a separation layer 3002 was formed in the single crystal silicon substrate 3001 (see FIG. 25A). In formation of the separation layer 3002, a 100% hydrogen gas was used as a source gas, and the single crystal silicon substrate was irradiated with ions in plasma that was generated by excitation of the hydrogen gas and accelerated by a voltage without any mass separation. The irradiation with ions was performed from the surface of the single crystal silicon substrate on which the silicon oxynitride layer 3006 and the silicon nitride oxide layer 3007 were formed. The doping conditions at this time were set as follows: the power supply output was 100 W; the accelerating voltage, 40 kV; and the dose, 2.2×10¹⁶ ions/cm².

In the ion doping apparatus, when the hydrogen gas is excited, three kinds of ion species, H⁺ ions, H₂⁺ ions, and H₃⁺ ions, are generated. In this embodiment, the all kinds of ion species generated by excitation of the hydrogen gas were accelerated by a voltage, and the single crystal silicon substrate 3001 was irradiated with the ion species. At this moment, it was confirmed that about 80% of the ion species that were generated from the hydrogen gas was H₃⁺ ions.

A silicon oxide layer 3008 with a thickness of 50 nm was formed as a third insulating layer over the silicon nitride oxide layer 3007 that was the second insulating layer by a plasma CVD method (see FIG. 25A). A process gas for forming the silicon oxide layer 3008 that was the third insulating layer was TEOS and O₂, and the flow ratio (sccm) was set as follows: TEOS/O₂=15/750. The substrate temperature in the step was 300° C.

After the glass substrate 3012 and the single crystal silicon substrate 3001 provided with the buffer layer 3010 that includes the first insulating layer (silicon oxynitride layer 3006), the second insulating layer (silicon nitride oxide layer 3007), and the third insulating layer (silicon oxide layer 3008) were subjected to ultrasonic cleaning in pure water and were then cleaned with ozone-containing pure water, the glass substrate 3012 and the single crystal silicon substrate 3001 were attached with the buffer layer 3010 interposed therebetween so as to be bonded to each other (see FIG. 25A). In other words, a surface of the glass substrate 3012 and a surface (a surface which is not in contact with the second insulating layer) of the silicon oxide layer 3008, which is the third insulating layer formed over the single crystal silicon substrate 3001, served as bonding planes and were made in contact with each other so as to be bonded.

A substrate in which the glass substrate 3012 and the single crystal silicon substrate 3001 were bonded to each other was subjected to heat treatment at 600° C. in a vertical furnace with resistance heating, whereby a single crystal silicon layer 3003 was separated by using the separation layer 3002 formed in the single crystal silicon substrate 3001 as a separation plane (see FIG. 25B). In the above-described manner, the glass substrate 3012 to which the single crystal silicon layer 3003 was bonded with the buffer layer 3010 interposed therebetween was obtained.

The depth in a thickness direction of the separation layer 3002 was controlled so that the separated single crystal silicon layer 3003 has a thickness of 120 nm or 100 nm.

Next, the single crystal silicon layer 3003 was irradiated with a laser beam 3020; accordingly, part of the single crystal silicon layer 3003 was melted (see FIG. 25C) and then re-single-crystallized to form the single crystal silicon layer 3004 (see FIG. 25D).

The irradiation with the laser beam 3020 will be described. As shown by an arrow 3030, a stage is moved to move the glass substrate 3012; thus, the laser beam 3020 scans the single crystal silicon layer 3003. Accordingly, the separation plane of the single crystal silicon layer 3003 is irradiated with the laser beam 3020.

As the laser beam 3020, a linear laser beam with a beam width of 350 μm and a length of 126 mm was used. The linear laser beam was produced by forming a beam obtained with a XeCl excimer laser having a wavelength of 308 nm, a pulse width of 25 nsec, and a repetition rate of 30 Hz into a linear shape by an optical system. Then, irradiation was performed in such a manner that the glass substrate 3012 was moved at a movement speed of 1.0 mm/sec in a direction parallel to a short axis direction of the linear laser beam 3020. The glass substrate 3012 was moved by moving the stage. In irradiation with the laser beam 3020, the atmosphere in the chamber was a nitrogen atmosphere, or a nitrogen gas was sprayed on the irradiation region of the laser beam 3020 and the vicinity thereof.

In the above-described manner, the semiconductor substrate 3000 in which the re-single-crystallized single crystal silicon layer 3004 was fixed over the glass substrate 3012 was obtained.

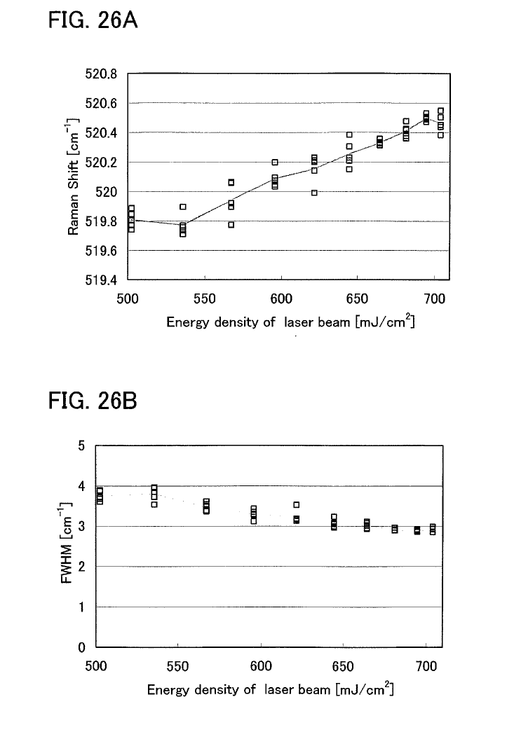

Next, measurement results of the Raman spectroscopy of the single crystal silicon layer 3004 which is irradiated with a laser beam will be described. FIG. 26A shows change in peak wavenumber of Raman shift with respect to energy density of a laser beam. FIG. 26B shows change in full width at half maximum (FWHM) of a Raman spectrum with respect to energy density of a laser beam. Note that the thickness of the single crystal silicon layer 3004 of the sample measured in FIGS. 26A and 26B was 100 nm.

The peak wavenumber of Raman shift shown in FIG. 26A is a value determined by a distance between crystal lattices and a spring constant between the crystal lattices, and is a unique value that depends on the kind of crystal. That is, the peak wavenumber of Raman shift of a single crystal of a given substance is a unique value. Thus, the closer the peak wavenumber of Raman shift of a measured object is to its unique value, the closer the crystal structure of the measured object is to that of the single crystal of the given substance. For example, the peak wavenumber of Raman shift of single crystal silicon without any internal stress is 520.6 cm⁻¹. The closer the peak wavenumber of Raman shift of a measured object is to 520.6 cm⁻¹, the closer the crystal structure of the measured object is to that of single crystal silicon. Thus, the peak wavenumber of Raman shift can be used as an index for evaluating crystallinity.

A smaller FWHM shown in FIG. 26B indicates that crystallinity is more uniform with less variation. The FWHM of a commercial single crystal silicon substrate is about 2.5 cm⁻¹ to 3.0 cm⁻¹, and a measured value of an object being closer to this value shows that the object has higher crystallinity than a single crystal silicon substrate has.

Note that when compressive stress is applied to single crystal, the distance between lattices is shortened; therefore, the peak wavenumber of Raman shift is shifted to a higher wavenumber side in proportion to the amount of compressive stress. Meanwhile, when tensile stress is applied, the peak wavenumber of Raman shift is shifted to a lower wavenumber side in proportion to the amount of tensile stress.

Therefore, it is not adequate to determine whether or not a silicon layer is a single crystal simply by the fact that the peak wavenumber of Raman shift is 520.6 cm⁻¹. The term “single crystal” means a crystal in which, when certain crystal axes are focused, the direction of the crystal axes is oriented in the same direction of the crystal axes in any portion of a sample and which has no crystal grain boundaries in the crystal. Therefore, it is determined by measurement of a crystal axis direction and presence of a crystal grain boundary whether the silicon layer has a single crystal structure or not. For example, such measurement includes electron back scatter diffraction pattern (EBSP). By obtaining an inverse pole figure (IPF) map from an EBSP image, it can be confirmed that crystal axes are uniformly oriented (crystal orientation is uniform) and there is no crystal grain boundary.

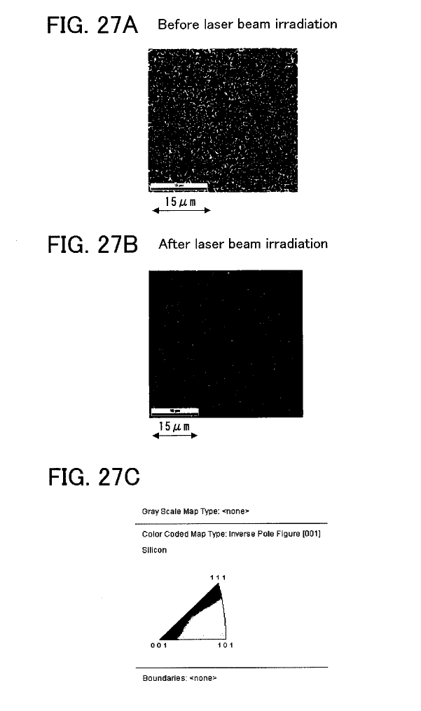

FIGS. 27A and 27B are IPF maps obtained from EBSP of the surfaces of the single crystal silicon layer 3003 and the single crystal silicon layer 3004 respectively. The IPF map of FIG. 27A shows EBSP of the single crystal silicon layer 3003 before laser beam irradiation. The IPF map of FIG. 27B shows EBSP of the single crystal silicon layer 3004 after laser beam irradiation. FIG. 27C is a color code map showing the relationship between colors of the IPF maps and crystal orientation, in which each crystal orientation is color-coded. Note that the thickness of the single crystal silicon layer of the sample measured in FIGS. 27A and 27B was about 120 nm.

According to the IPF maps of FIGS. 27A and 27B, crystal orientation of the single crystal silicon layer is not disordered either before or after laser beam irradiation, and the plane orientation of the surface of the single crystal silicon layer keeps (100), which is the same as the plane orientation of the used single crystal silicon substrate.

In addition, it can be seen that there are no crystal grain boundaries in the single crystal silicon layer either before or after laser beam irradiation. This is because it can be seen that crystals are oriented in (100) plane and there is no crystal grain boundaries, from the fact that the IPF maps of FIGS. 27A and 27B are a monochromatic square image of a color (red in the color image) representing the (100) plane in the color code map of FIG. 27C.

Note that dots that are present in the IPF maps of FIGS. 27A and 27B show portions having a low CI value. The CI value is an index value showing reliability and accuracy of data with which crystal orientation is determined. The CI value is decreased by the presence of crystal grain boundaries, crystal defects, and the like. In other words, it can be concluded that when the area with a low CI value is smaller, the crystallinity is higher. The number of portions having a low CI value is smaller in the IPF map after laser beam irradiation of FIG. 27B than in the IPF map before laser beam irradiation of FIG. 27A. Therefore, it is likely that crystal defects of the single crystal silicon layer, for example, crystal defects such as dangling bonds are recovered by laser beam irradiation.

Laser beam irradiation treatment was performed on the single crystal silicon layer of which EBSP was measured at an irradiation energy density of 648 mJ/cm², while a nitrogen gas was sprayed on the vicinity of the laser beam irradiation region. The number of shots of the laser beam with which the same region of the single crystal silicon layer 3003 was irradiated was calculated to be 10.5 in consideration of the beam width and the movement speed of the substrate.

From the EBSP data of FIGS. 27A and 27B, it can be seen that the crystallinity is improved by laser beam irradiation. In addition, it can be seen from FIGS. 26A and 26B that the crystallinity can be recovered by laser beam irradiation to be the same or substantially the same as that of a single crystal silicon substrate before processing (base single crystal silicon substrate). The irradiation energy density of the laser beam is preferably 550 mJ/cm² or higher; accordingly, the peak wavenumber of Raman shift can be about 520.0 cm⁻¹ to 520.6 cm⁻¹ and the FWHM can be about 3.0 cm⁻¹.

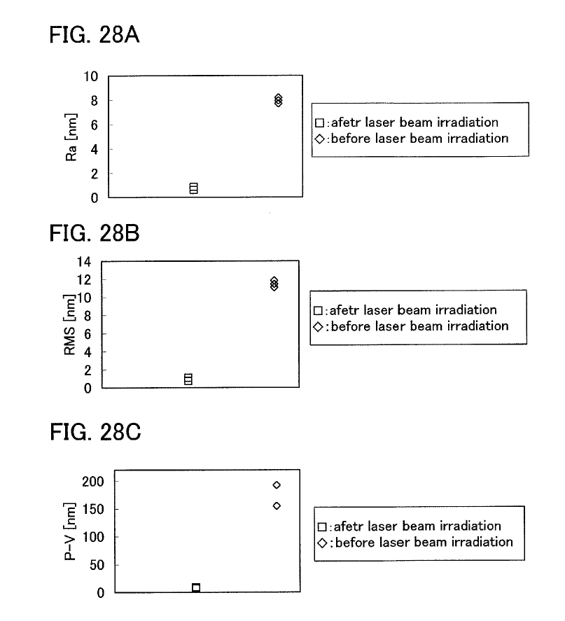

Next, the effect on planarization of the surface of the single crystal silicon layer by laser beam irradiation will be described. FIGS. 28A to 28C show measured values of surface roughness of the single crystal silicon layer, which are obtained by calculation based on images observed with an atomic force microscope (AFM) in a dynamic force mode (DFM) (such images are hereinafter referred to as DFM images). The measured values shown in FIGS. 28A to 28C are obtained from the DFM images each having an observed region of 5 μm square. Here, the surface roughness of the single crystal silicon layer was calculated by observation with AFM after the single crystal silicon was subjected to laser beam irradiation treatment at an irradiation energy density of 566.7 mJ/cm² with a nitrogen atmosphere in the chamber.

FIG. 28A shows average surface roughness, Ra (nm). FIG. 28B shows a root mean square roughness, Rms (nm). FIG. 28C shows the largest difference in height between peak and valley, P-V (nm). FIGS. 28A to 28C also show roughness data of the single crystal silicon layer before the laser beam irradiation. Specifically, in FIGS. 28A to 28C, the roughness data after the laser beam irradiation is shown by square data markers, and the roughness data before the laser beam irradiation is shown by diamond-shaped data markers.

From FIGS. 28A to 28C, it can be found that the values of Ra, RMS, P-V after the laser beam irradiation are each decreased from those before the laser beam irradiation. Accordingly, it was confirmed that planarity of the single crystal silicon layer can be improved by laser beam irradiation.

### Embodiment 2

In Embodiment 2, evaluation results of characteristics of a single crystal semiconductor layer using a semiconductor substrate manufactured according to the present invention will be described.

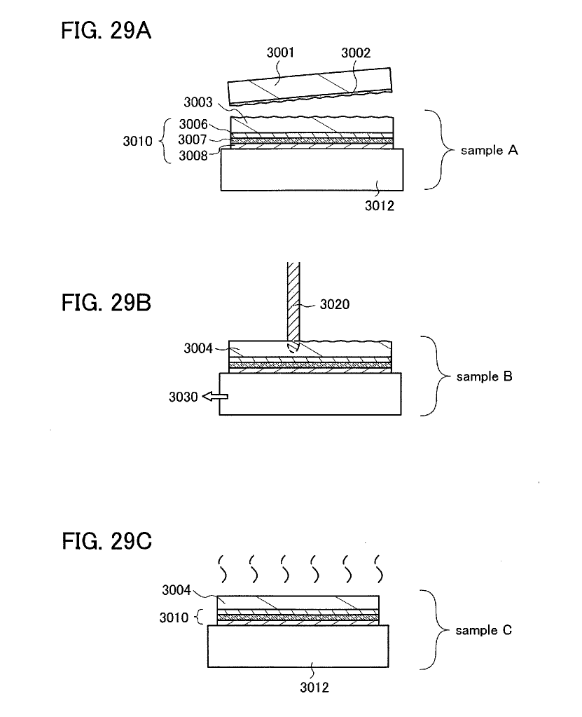

The structures of a sample A, a sample B, and a sample C which are evaluated in this embodiment will be described with reference to FIGS. 29A to 29C. A semiconductor substrate of FIG. 29A is formed through FIGS. 25A and 25B in Embodiment 1.

First, a p-type silicon wafer of which main surface is oriented along the (100) plane was prepared as a single crystal silicon substrate 3001. Then, a silicon oxynitride layer 3006 with a thickness of 50 nm and a silicon nitride oxide layer 3007 with a thickness of 50 nm were sequentially stacked over a surface of the single crystal silicon substrate 3001 by a plasma CVD method. The single crystal silicon substrate 3001 was irradiated with ions using an ion doping apparatus, from the surface on which the silicon oxynitride layer 3006 and the silicon nitride oxide layer 3007 were formed; accordingly, a separation layer 3002 was formed. At this time, a 100% hydrogen gas was used as a source gas, and the single crystal silicon substrate 3001 was irradiated with ions in plasma that was generated by excitation of the hydrogen gas and accelerated by a voltage without any mass separation. After forming the separation layer 3002, a silicon oxide layer 3008 with a thickness of 50 nm was formed over the silicon nitride oxide layer 3007 by a plasma CVD method using TEOS as a main process gas for film formation. The single crystal silicon substrate 3001 and a glass substrate 3012 were overlapped and bonded to each other with the silicon oxynitride layer 3006, the silicon nitride oxide layer 3007, and the silicon oxide layer 3008, which were sequentially stacked as a buffer layer 3010 over the surface of the single crystal silicon substrate 3001, interposed therebetween. As the glass substrate 3012, a non-alkali glass substrate (product name: AN100) having a thickness of 0.7 mm was used. Then, a substrate in which the glass substrate 3012 and the single crystal silicon substrate 3001 were bonded to each other was subjected to heat treatment, whereby a single crystal silicon layer 3003 was separated by using the separation layer 3002 formed in the single crystal silicon substrate 3001 as a separation plane. The glass substrate 3012 to which the single crystal silicon layer 3003 separated using the separation layer 3002 as a separation plane was bonded was referred to as the sample A. The depth in a thickness direction of the separation layer 3002 was controlled so that the single crystal silicon layer 3003 has a thickness of about 120 nm.

Next, the single crystal silicon layer 3003 was irradiated with a laser beam 3020 so that part of the single crystal silicon layer 3003 is melted; accordingly, a single crystal silicon layer 3004 was formed (see FIG. 29B). The glass substrate 3012 to which the single crystal silicon layer 3004 obtained by irradiation with the laser beam 3020 was bonded was referred to as the sample B.

As the laser beam 3020, a linear beam with a beam width of 350 μm and a length of 126 mm was used. The linear beam was produced by forming a beam obtained with a XeCl excimer laser having a wavelength of 308 nm, a pulse width of 25 nsec, and a repetition rate of 30 Hz into a linear shape by an optical system. Then, irradiation was performed in such a manner that the glass substrate 3012 was moved at a movement speed of 1.0 mm/sec in a direction parallel to a short axis direction of the linear laser beam 3020. The glass substrate 3012 was moved by moving the stage. The irradiation energy density of the laser beam 3020 was 660 mJ/cm².

Next, the glass substrate 3012 to which the single crystal silicon layer 3004 was bonded was subjected to heat treatment at 500° C. for one hour and heat treatment at 550° C. for four hours sequentially with a vertical furnace with resistance heating (see FIG. 29C). The glass substrate 3012 to which the single crystal silicon layer 3004 which was subjected to heat treatment after being irradiated with the laser beam 3020 was bonded was referred to as the sample C.

The lifetimes of carriers of the single crystal silicon layer 3003 or the single crystal silicon layer 3004 of the samples A to C were measured by a microwave photoconductivity decay method (μ-PCD method). The μ-PCD method is one of the measurement methods for evaluating lifetime in which excess carriers are generated by irradiating the semiconductor layer or the semiconductor wafer with pulsed laser beams and decayed by recombination, without contact. Generation of the carriers increases the conductivity of the semiconductor layer or the semiconductor wafer, and thus the reflectance of microwaves with which the semiconductor layer or the semiconductor wafer is irradiated changes in accordance with the excessive carrier density. The time of decrease in the reflectance of the microwaves is measured, whereby carrier lifetime can be measured.

In this embodiment, with the use of a crystallinity evaluation equipment using microwaves (produced by KOBELCO Research Institute, Inc.), the samples A to C were irradiated with microwaves with a frequency of 28 GHz and with third harmonics of a YLF laser with a wavelength of 349 nm, and the change of the reflection intensity of the microwaves over time, which changes according to formation of carriers, was measured. Then, the lifetimes of the samples A to C were compared with one another using the peak values of the reflection intensity of the microwaves. Note that the larger the peak value is, the longer the lifetime is.

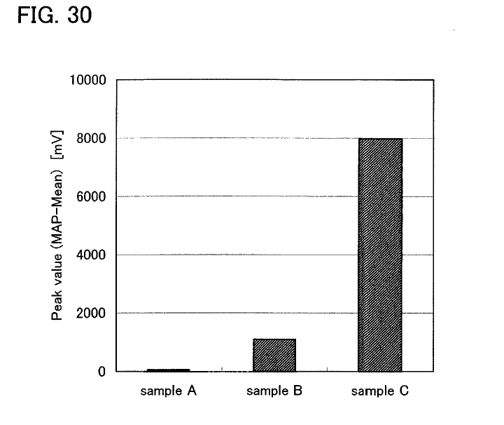

In FIG. 30, the descending order of the peak value is the samples C, B, and A. In other words, the single crystal silicon layer subjected to heat treatment after laser beam irradiation has a largest peak value. The peak value measured by the μ-PCD method is proportional to the lifetime. Accordingly, the lifetime of the sample C is the longest. Since the descending order of the peak value is the samples C, B, and A, it was found that the lifetime was improved by irradiation with a laser beam and that the lifetime was drastically improved by heat treatment after the laser beam irradiation.

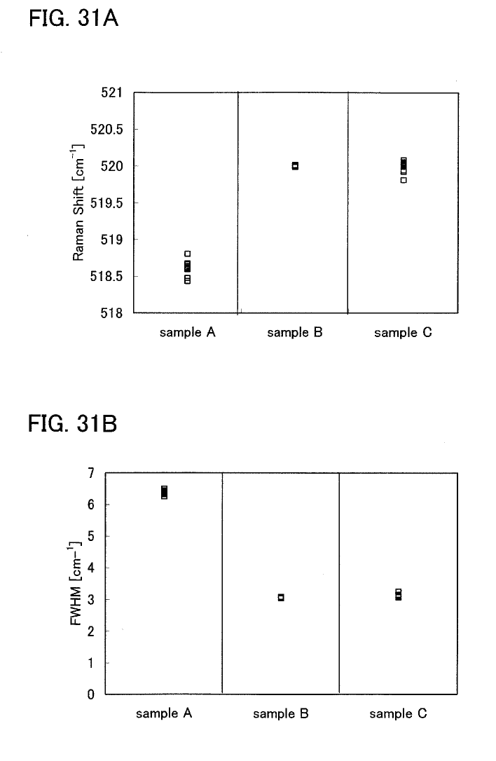

Further, the measurement results by Raman spectroscopy of the single crystal silicon layers of the samples A to C are shown. FIG. 31A shows the peak wavenumbers of Raman shift of the samples A to C. In addition, FIG. 31B shows the full widths at half maximum (FWHM) of Raman spectra of the samples A to C.

As described above, the peak wavenumber of Raman shift of single crystal silicon without any internal stress is 520.6 cm⁻¹. It can be found from FIGS. 31A and 31B that the peak wavenumbers of Raman shift of the samples B and C are approximately 520 cm⁻¹ and the FWHM thereof are approximately 3 cm⁻¹ and, therefore, that the crystallinity of the single crystal silicon layers of the samples B and C is recovered to be the same or substantially the same as that of the single crystal silicon substrate before processing. In addition, compared to the sample A, the samples B and C have wavenumbers that are closer to 520.6 cm⁻¹ and also have smaller FWHM. Thus, laser beam irradiation was found to be effective in recovering crystallinity. Furthermore, the peak wavenumbers of Raman shift of the samples B and C were substantially the same, which were approximately 520.6 cm⁻¹, and the FWHM thereof were also substantially the same, which were approximately 3 cm⁻¹. Accordingly, even when heat treatment is performed after laser beam irradiation, the lifetime can be improved without reducing the effect of recovering crystallinity that is obtained by the laser beam irradiation.

Therefore, it was confirmed that crystallinity is recovered by laser beam irradiation of a single crystal silicon layer which is obtained by separation after processing, and that the lifetime is improved by performing heat treatment after the laser beam irradiation.

This application is based on Japanese Patent Application serial no. 2007-285589 filed with Japan Patent Office on Nov. 1, 2007, the entire contents of which are hereby incorporated by reference.

What is claimed is:

1. A manufacturing method of a semiconductor device, comprising the steps of:
heating a single crystal semiconductor substrate which is bonded over a supporting substrate with a buffer layer interposed therebetween and in which a separation layer is formed, to separate the single crystal semiconductor substrate using the separation layer or a region near the separation layer as a separation plane, thereby forming a single crystal semiconductor layer over the supporting substrate;
irradiating the single crystal semiconductor layer with a laser beam to re-single-crystallize the single crystal semiconductor layer through melting;
selectively etching the re-single-crystallized single crystal semiconductor layer to separate the re-single crystallized single crystal semiconductor layer into an island shape;
selectively adding an impurity element into the single crystal semiconductor layer to form a pair of impurity regions and a channel formation region between the pair of impurity regions after selectively etching the re-single-crystallized single crystal semiconductor layer; and
heating the single crystal semiconductor layer at a process temperature which is equal to or higher than 400° C. and equal to or lower than a strain point of the supporting substrate and which does not cause melting of the single crystal semiconductor layer after selectively adding the impurity element into the single crystal semiconductor layer.

2. A manufacturing method of a semiconductor device, comprising the steps of:
heating a single crystal semiconductor substrate which is bonded over a supporting substrate with a buffer layer interposed therebetween and in which a separation layer is formed, to separate the single crystal semiconductor substrate using the separation layer or a region near the separation layer as a separation plane, thereby forming a single crystal semiconductor layer over the supporting substrate;
irradiating the single crystal semiconductor layer with a laser beam to re-single-crystallize the single crystal semiconductor layer through melting;
selectively etching the re-single-crystallized single crystal semiconductor layer to separate the re-single-crystallized single crystal semiconductor layer into an island shape;
forming a gate electrode over the single crystal semiconductor layer with a gate insulating layer interposed therebetween after selectively etching the re-single-crystallized single crystal semiconductor layer;
adding an impurity element using the gate electrode as a mask to form a pair of impurity regions and a channel formation region between the pair of impurity regions in the single crystal semiconductor layer; and
heating the single crystal semiconductor layer at a process temperature which is equal to or higher than 400° C. and equal to or lower than a strain point of the supporting substrate and which does not cause melting of the single crystal semiconductor layer after adding the impurity element.

3. A manufacturing method of a semiconductor device, comprising the steps of:
heating a single crystal semiconductor substrate which is bonded over a supporting substrate with a buffer layer interposed therebetween and in which a separation layer is formed, to separate the single crystal semiconductor substrate using the separation layer or a region near the separation layer as a separation plane, thereby forming a single crystal semiconductor layer over the supporting substrate;
irradiating the single crystal semiconductor layer with a laser beam to re-single-crystallize the single crystal semiconductor layer through melting;
adding a p-type impurity element or an n-type impurity element into the single crystal semiconductor layer to form a well region of an n-channel transistor or a p-channel transistor;
selectively etching the re-single-crystallized single crystal semiconductor layer to separate the re-single-crystallized single crystal semiconductor layer into an island shape;
forming a gate electrode over the single crystal semiconductor layer with a gate insulating layer interposed therebetween after selectively etching the re-single-crystallized single crystal semiconductor layer;
adding an impurity element using the gate electrode as a mask to form a pair of impurity regions and a channel formation region between the pair of impurity regions in the single crystal semiconductor layer; and
heating the single crystal semiconductor layer at a process temperature which is equal to or higher than 400° C. and equal to or lower than a strain point of the supporting substrate and which does not cause melting of the single crystal semiconductor layer after adding the impurity element.

4. The manufacturing method of a semiconductor device according to claim 1,
wherein the supporting substrate has the strain point of 650° C. or higher and 690° C. or lower.

5. The manufacturing method of a semiconductor device according to claim 2,
wherein the supporting substrate has the strain point of 650° C. or higher and 690° C. or lower.

6. The manufacturing method of a semiconductor device according to claim 3,
wherein the supporting substrate has the strain point of 650° C. or higher and 690° C. or lower.

7. The manufacturing method of a semiconductor device according to claim 1, wherein the process temperature is lower than 650° C.

8. The manufacturing method of a semiconductor device according to claim 2, wherein the process temperature is lower than 650° C.

9. The manufacturing method of a semiconductor device according to claim 3, wherein the process temperature is lower than 650° C.

10. The manufacturing method of a semiconductor device according to claim 1, wherein the separation layer is formed by irradiation with H₃⁺ ions, which are generated using a source gas containing hydrogen, with an ion doping apparatus.

11. The manufacturing method of a semiconductor device according to claim 2, wherein the separation layer is formed by irradiation with H₃⁺ ions, which are generated using a source gas containing hydrogen, with an ion doping apparatus.

12. The manufacturing method of a semiconductor device according to claim 3, wherein the separation layer is formed by irradiation with H₃⁺ ions, which are generated using a source gas containing hydrogen, with an ion doping apparatus.

13. The manufacturing method of a semiconductor device according to claim 2, wherein the gate insulating layer is formed by oxidize or nitride the surfaces of the single crystal semiconductor layer.

14. The manufacturing method of a semiconductor device according to claim 3, wherein the gate insulating layer is formed by oxidize or nitride the surfaces of the single crystal semiconductor layer.

15. The manufacturing method of a semiconductor device according to claim 1, wherein the single crystal semiconductor layer has a thickness of 60 nm or less.

16. The manufacturing method of a semiconductor device according to claim 2, wherein the single crystal semiconductor layer has a thickness of 60 nm or less.

17. The manufacturing method of a semiconductor device according to claim 3, wherein the single crystal semiconductor layer has a thickness of 60 nm or less.

18. The manufacturing method of a semiconductor device according to claim 1, wherein a surface of the buffer layer has smoothness and can form a hydrophilic surface.

19. The manufacturing method of a semiconductor device according to claim 2, wherein a surface of the buffer layer has smoothness and can form a hydrophilic surface.

20. The manufacturing method of a semiconductor device according to claim 3, wherein a surface of the buffer layer has smoothness and can form a hydrophilic surface.
